(19) United States
(12) Patent Application Publication
(10) Pub. No.: US 2024/0368464 A1
(43) Pub. Date: Nov. 7, 2024

(54) ORGANOMETALLIC IRIDIUM COMPOUND

(71) Applicant: GUANGDONG AGLAIA OPTOELECTRONIC MATERIALS CO., LTD., Foshan, Guangdong (CN)

(72) Inventors: Liangliang YAN, Foshan (CN); Shaofu CHEN, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/562,201

(22) PCT Filed: Jun. 15, 2022
(86) PCT No.: PCT/CN2022/098809

§ 371 Date: Nov. 17, 2023

(30) Foreign Application Priority Data
Jun. 24, 2021 (CN) 202110702678.4
Jun. 2, 2022 (CN) 202210619941.8

(51) Int. Cl. C09K 11/06; H10K 50/11; H10K 85/30

(52) U.S. Cl. CPC C09K 11/06; H10K 50/11; H10K 85/342; C09K 2211/185

(57) ABSTRACT

Disclosed are an organometallic iridium compound and application thereof. The organometallic iridium compound has a general formula of Ir(La)(Lb)(Lc), where La is a structure represented by Formula (1), and Lb is a structure represented by Formula (2). The compound provided by the present invention has the advantages of high optical and electrical stability, low sublimation temperature, small emission half-peak width, high color saturation, high luminous efficiency, long device life and the like, and can be used in organic electroluminescent devices. In particular, the compound has the potential for application in the AMOLED industry as a red light-emitting dopant.

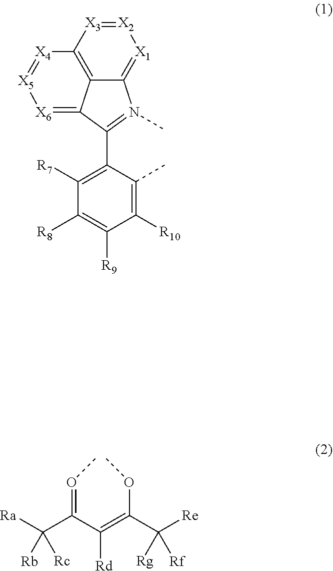

### TECHNICAL FIELD

The present invention relates to the technical field of organic electroluminescence, in particular to an organic light-emitting material applicable to organic electroluminescent devices, and specially relates to an organometallic iridium compound and application thereof in an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage and service life, of the OLED still need to be strengthened and improved.

In generally, the OLED includes various organic functional material films with different functions sandwiched between metal electrodes as a basic structure, which is similar to a sandwich structure. Under the driving of a current, holes and electrons are injected from a cathode and an anode, respectively. After moving to a certain distance, the holes and the electrons are compounded in a light-emitting layer, and then released in the form of light or heat to achieve luminescence of the OLED.

However, organic functional materials are core components of the OLED, and the thermal stability, photochemical stability, electrochemical stability, quantum yield, film forming stability, crystallinity, color saturation and the like of the materials are main factors affecting properties of the device.

Generally, the organic functional materials include fluorescent materials and phosphorescent materials. The fluorescent materials are usually organic small-molecule materials, which can only utilize 25% of a singlet state for luminescence, so that the luminous efficiency is relatively low. Meanwhile, due to an earth-spin orbit coupling effect caused by a heavy atom effect, the phosphorescent materials can utilize 25% of a singlet state and can also utilize 75% of the energy of triplet excitons, so that the luminous efficiency can be improved. However, compared with the fluorescent materials, the phosphorescent materials are developed later, and the thermal stability, service life, color saturation and the like of the materials need to be improved. Thus, the phosphorescent materials have become a challenging topic. Various organometallic iridium compounds have been developed to serve as the phosphorescent materials. For example, a patent document (US20050123798) discloses an iridium-based complex with indole as a ligand

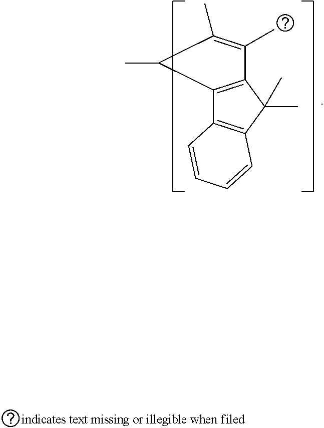

Although the material has a good red emission wavelength, the low device luminous efficiency and color saturation of the material need to be further improved, so as to meet display demands of DCIP3 or even BT2020. A patent document (CN107722062) discloses an iridium-platinum complex composed of acenaphthylene as a unit

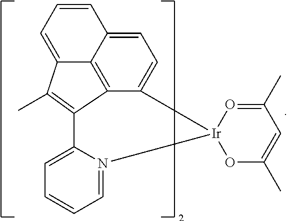

The material emits blue or green light. A patent document (CN110317231) discloses a metal complex composed of acenaphthylene as a unit

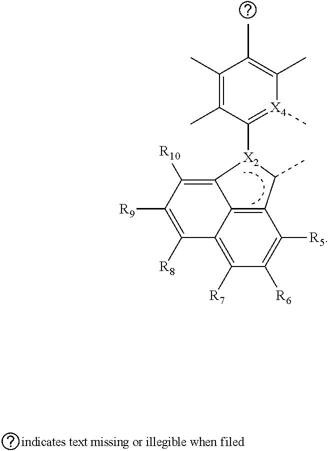

The material emits dark blue light. In order to meet the market demands for higher stability, longer service life, higher saturated color purity and higher luminous efficiency, more new materials need to be developed to meet increasing technical demands of the market.

### SUMMARY

In order to overcome the above disadvantages, the present invention provides an organic electroluminescent device with high properties and an organometallic iridium compound material capable of realizing the organic electroluminescent device.

An organometallic iridium compound of the present invention has a general formula of Ir(La)(Lb)(Lc), where La is a structure represented by Formula (1), and Lb is a structure represented by Formula (2). The iridium compound provided by the present invention has the advantages of high optical and electrical stability, low sublimation temperature, small emission half-peak width, high color saturation, high luminous efficiency, long device life and the like, and can be used in organic electroluminescent devices. In particular, the compound has the potential for application in the AMOLED industry as a red light-emitting dopant, especially in display, lighting and automobile taillights.

An organometallic iridium compound has a general formula of Ir(La)(Lb)(Lc), where La is a structure represented by Formula (1):

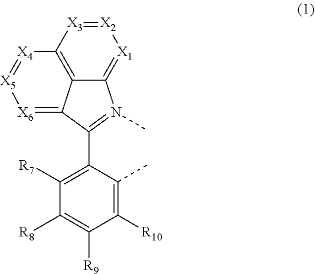

where dotted lines refer to positions connected to the metal Ir;
X₁ is N or CR₁, X₂ is N or CR₂, X₃ is N or CR₃, X₄ is N or CR₄, X₅ is N or CR₅, and X₆ is N or CR₆;
at most one of the X₁-X₆ is N, and when the X₁-X₆ are CR₁-CR₆, at least one of the R₁-R₆ is not H;
R₁-R₁₀ are independently selected from hydrogen, deuterium, halogen, cyano, hydroxyl, sulfhydryl, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₆ or R₇-R₁₀ may be connected to each other to form an aliphatic ring or an aromatic ring; and at least one of the R₇-R₁₀ is not hydrogen;
Lb is a structure represented by Formula (2):

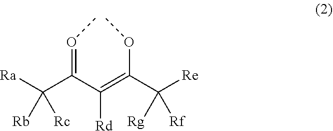

where dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl, or any two of the Ra, the Rb and the Rc are connected to form an aliphatic ring, and any two of the Re, the Rf and the Rg are connected to form an aliphatic ring;
the “substituted” refers to substitution with deuterium, F, Cl, Br, C₁-C₆ alkyl, C₁-C₆ alkoxyl, C₃-C₆ cycloalkyl, amino substituted with C₁-C₆ alkyl, cyano, isocyano, or phosphino, and the substitution ranges from a single substitution number to a maximum substitution number;
and the heteroalkyl, the heterocyclic alkyl and the heteroaryl at least contain one O, N or S heteroatom;
Lc is a monoanionic bidentate ligand, and the Lc is different from the Lb and is not an OO ligand;
the Lc and the La are the same or different, and the different indicates different parent nuclear structures, a same parent nuclear structure with different substituents, or a same parent nuclear structure with different substituent positions;
or any two or three of the La, the Lb and the Lc are connected to each other to form a polydentate ligand.

Optionally, the La is a structure represented by Formula (3):

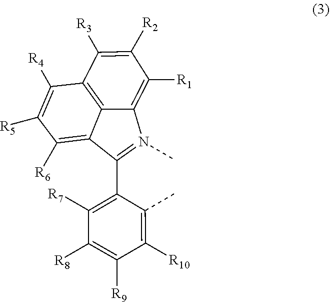

where dotted lines refer to positions connected to the metal Ir;
R₁-R₁₀ are independently selected from hydrogen, deuterium, halogen, cyano, hydroxyl, sulfhydryl, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₆ or R₇-R₁₀ are connected to each other to form an aliphatic ring or an aromatic ring;
at least one of the R₁-R₆ is not H, and at least one of the R₇-R₁₀ is not hydrogen;
the heteroalkyl and the heteroaryl at least contain one O, N or S heteroatom;
and the “substituted” refers to substitution with deuterium, F, Cl, Br, C₁-C₄ alkyl, C₃-C₆ cycloalkyl, amino substituted with C₁-C₄ alkyl, cyano, isocyano, or phosphino, and the substitution ranges from a single substitution number to a maximum substitution number.

In Formula (3), one of the R₁, R₃, R₄, R₅ is not H.

In Formula (3), the R₁, the R₃, the R₄ and the R₅ are independently selected from deuterium, halogen, substituted or unsubstituted C₁-C₁₀ alkyl, and substituted or unsubstituted C₃-C₂₀ cycloalkyl.

In Formula (3), at least two of the R₁-R₆ are not H.

In Formula (3), the R₂ and the R₆ are hydrogen.

Optionally, in Formula (3), the R₈ and/or the R₁₀ is not hydrogen.

In Formula (3), the R₈ and the R₁₀ are not hydrogen, the R₈ and the R₁₀ are independently selected from deuterium, halogen, substituted or unsubstituted C₁-C₁₀ alkyl, and substituted or unsubstituted C₃-C₂₀ cycloalkyl, and the R₇ and the R₉ are hydrogen.

The R₇ and the R₈, the R₈ and the R₉, or the R₉ and the R₁₀ are connected to each other to form a structure represented by Formula (4):

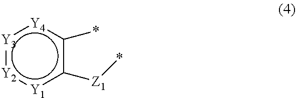

where * refers to a connecting position;
Y₁-Y₄ are independently CR₀ or N;
Z1 is selected from O and S;
R₀ is independently hydrogen, deuterium, halogen, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃₀ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl; and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

The R₇ and the R₈ are connected to each other to form a structure represented by Formula (4):

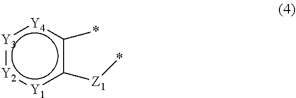

where * refers to a connecting position;
Y₁-Y₄ are independently CR₀;
and Z1 is selected from O.

The Lc and the La are the same.

The Lc and the La are different, and the Lc is a structure represented by Formula (5):

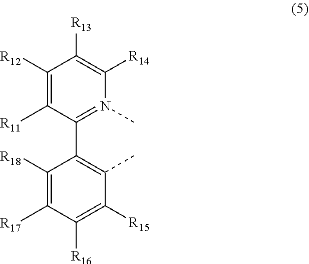

where dotted lines refer to positions connected to the metal Ir;
R₁₁-R₁₈ are independently selected from hydrogen, deuterium, halogen, cyano, hydroxyl, amino group, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl; at least two of the R₁₅-R₁₈ are not hydrogen; or at least two adjacent groups of the R₁₁-R₁₄ form an aromatic ring structure represented by Formula (6) below:

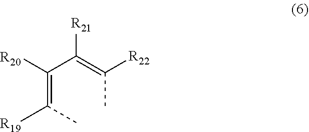

where dotted lines refer to positions connected to a pyridine ring;
R₁₉-R₂₂ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₉-R₂₂ are connected to each other to form an aliphatic ring or an aromatic ring;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

As a optional organometallic iridium compound, the La has one of the following structural formulas, or is partially or completely deuterated or fluorinated correspondingly,

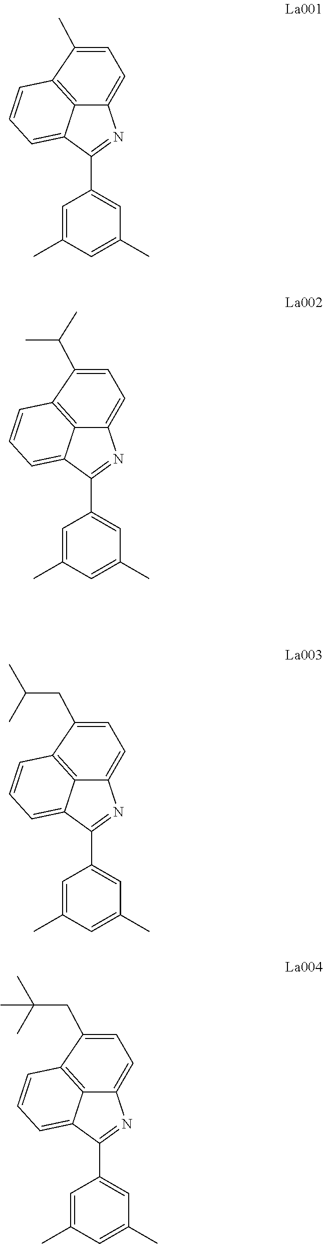

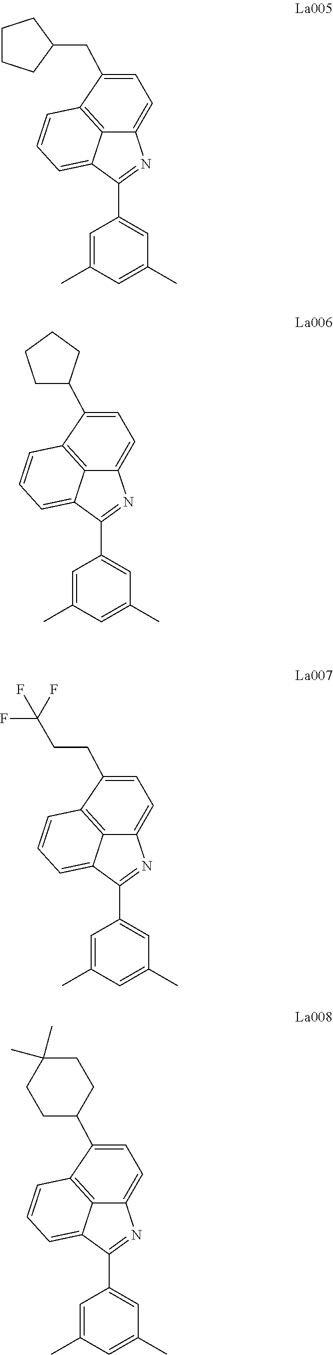

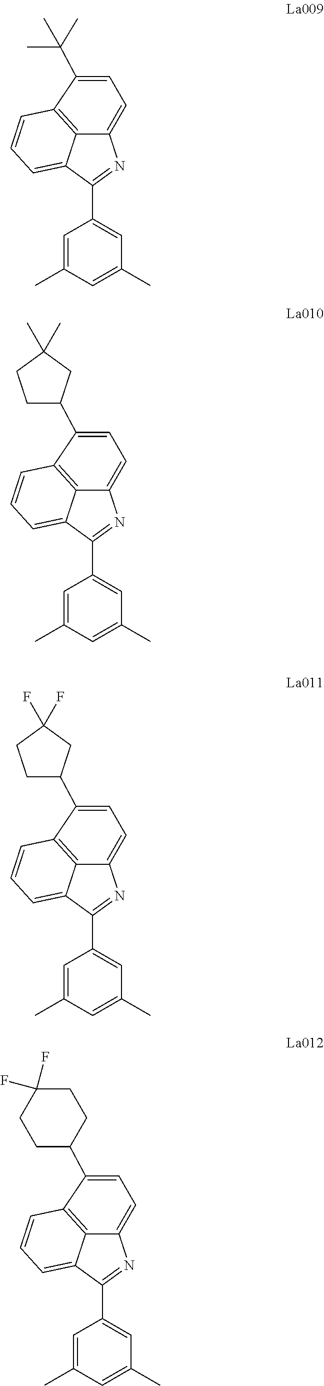

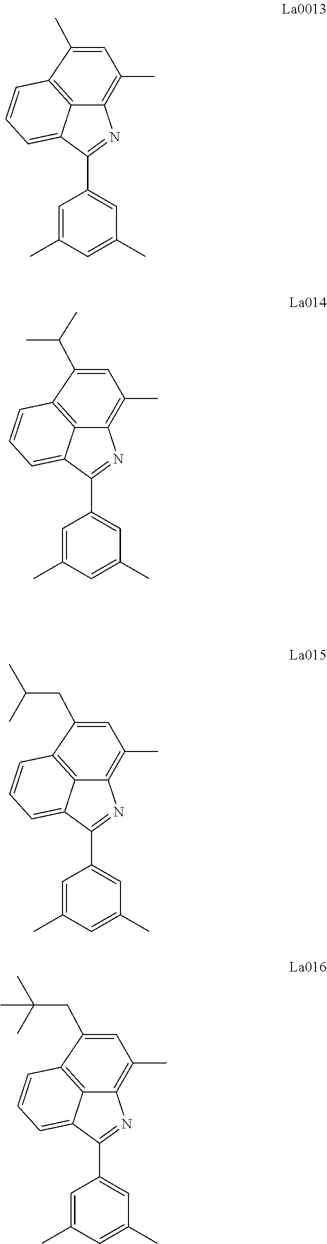

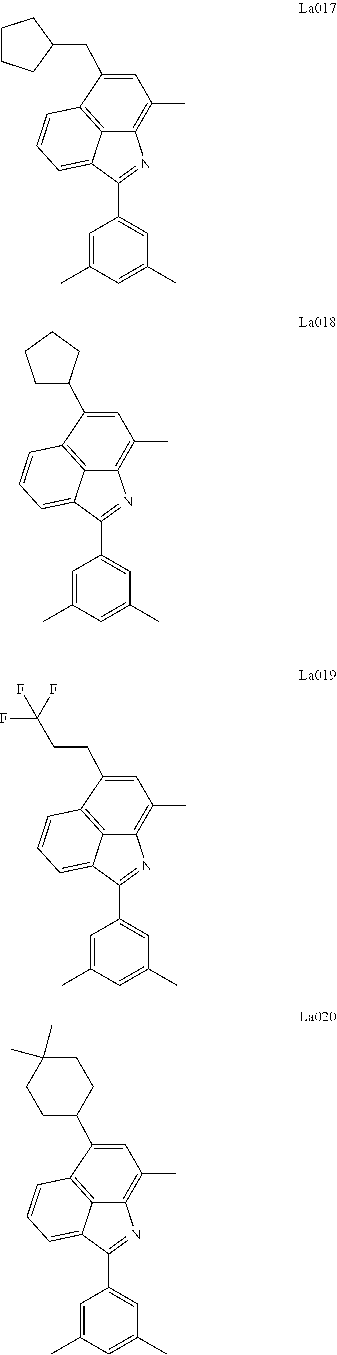

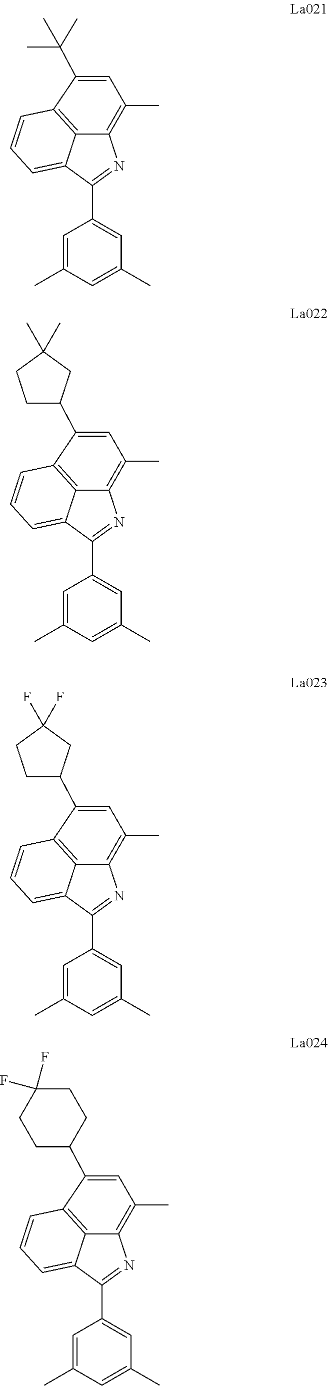

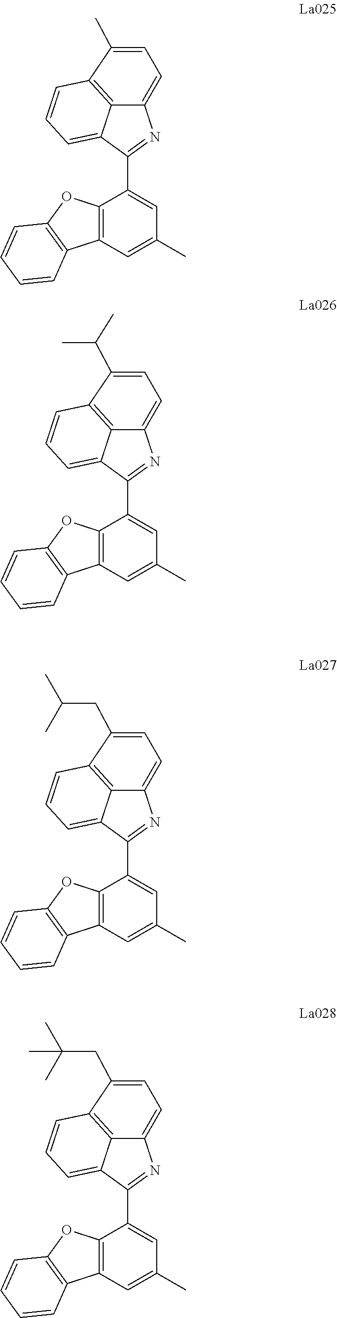 [SMILES: Cc1cc(C2=Nc3ccc(C)c4cccc2c34)c2oc3ccccc3c2c1 ; Cc1cc(C2=Nc3ccc(C(C)C)c4cccc2c34)c2oc3ccccc3c2c1 ; Cc1cc(C2=Nc3ccc(CC(C)C)c4cccc2c34)c2oc3ccccc3c2c1 ; Cc1cc(C2=Nc3ccc(CC(C)(C)C)c4cccc2c34)c2oc3ccccc3c2c1]

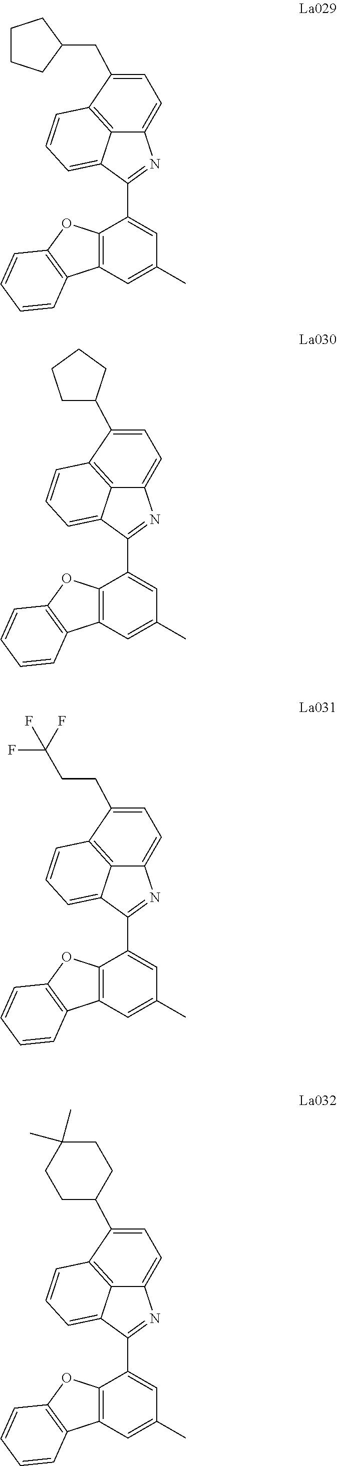 [SMILES: Cc1cc(C2=Nc3ccc(CC4CCCC4)c4cccc2c34)c2oc3ccccc3c2c1 ; Cc1cc(C2=Nc3ccc(C4CCCC4)c4cccc2c34)c2oc3ccccc3c2c1 ; Cc1cc(C2=Nc3ccc(CCC(F)(F)F)c4cccc2c34)c2oc3ccccc3c2c1 ; Cc1cc(C2=Nc3ccc(C4CCC(C)(C)CC4)c4cccc2c34)c2oc3ccccc3c2c1]

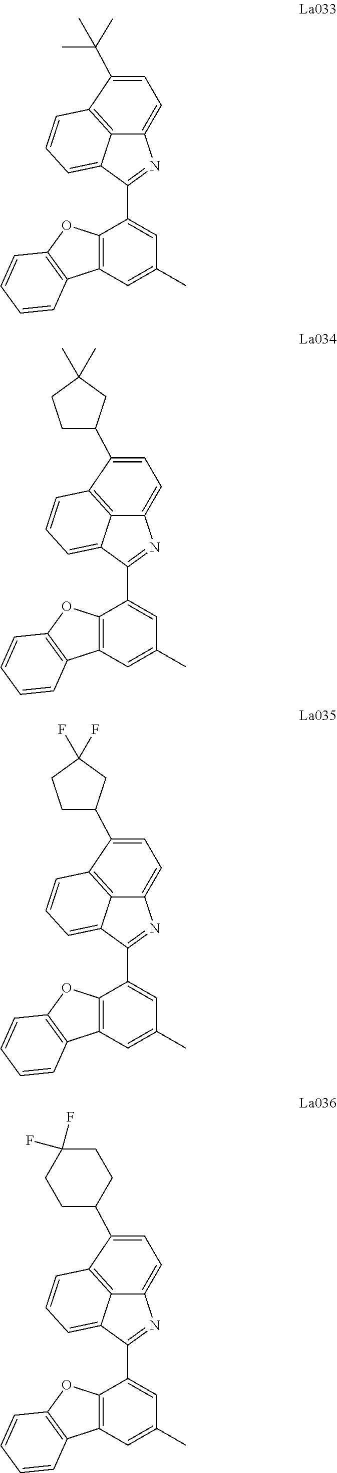

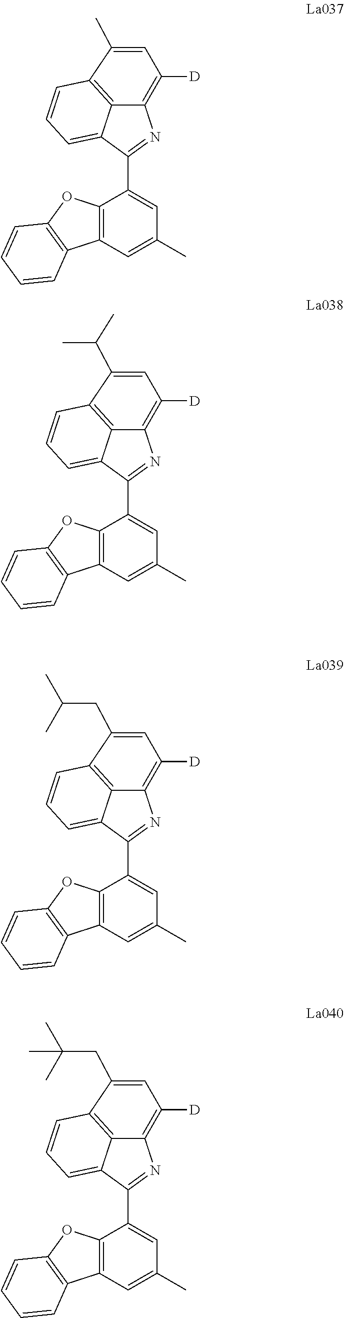 [SMILES: [2H]c1cc(C)c2cccc3c2c1N=C3c1cc(C)cc2c1oc1ccccc12 ; [2H]c1cc(C(C)C)c2cccc3c2c1N=C3c1cc(C)cc2c1oc1ccccc12 ; [2H]c1cc(CC(C)C)c2cccc3c2c1N=C3c1cc(C)cc2c1oc1ccccc12 ; [2H]c1cc(CC(C)(C)C)c2cccc3c2c1N=C3c1cc(C)cc2c1oc1ccccc12]

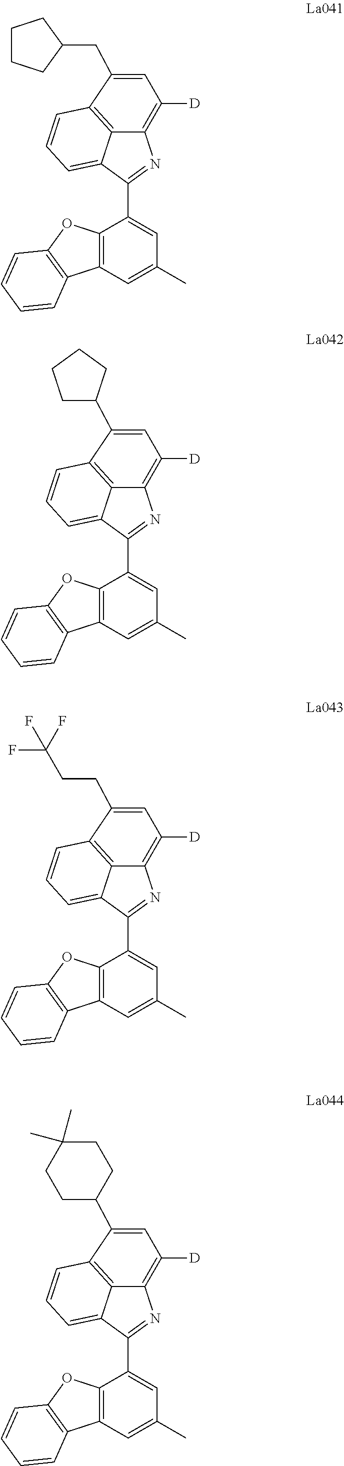 [SMILES: [2H]c1cc(CC2CCCC2)c2cccc3c2c1N=C3c1cc(C)cc2c1oc1ccccc12 ; [2H]c1cc(C2CCCC2)c2cccc3c2c1N=C3c1cc(C)cc2c1oc1ccccc12 ; [2H]c1cc(CCC(F)(F)F)c2cccc3c2c1N=C3c1cc(C)cc2c1oc1ccccc12 ; [2H]c1cc(C2CCC(C)(C)CC2)c2cccc3c2c1N=C3c1cc(C)cc2c1oc1ccccc12]

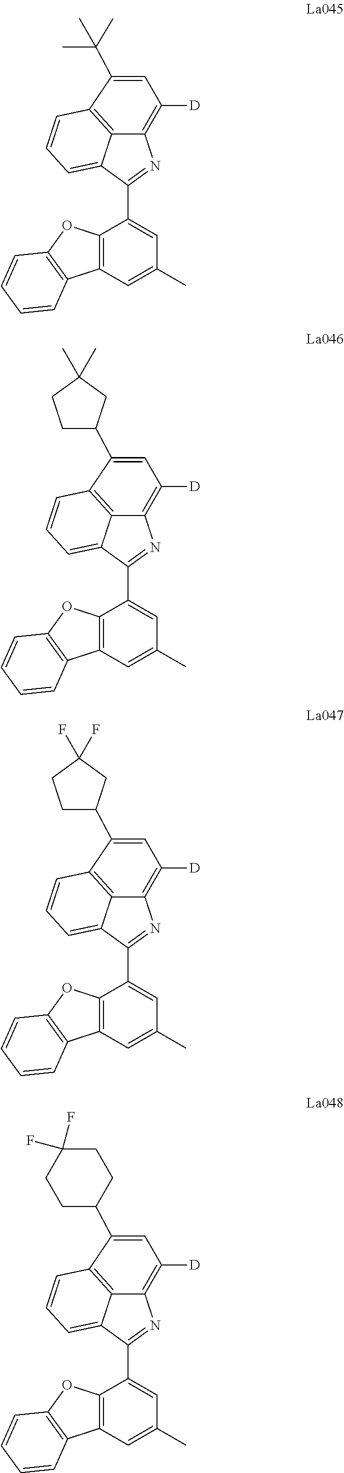

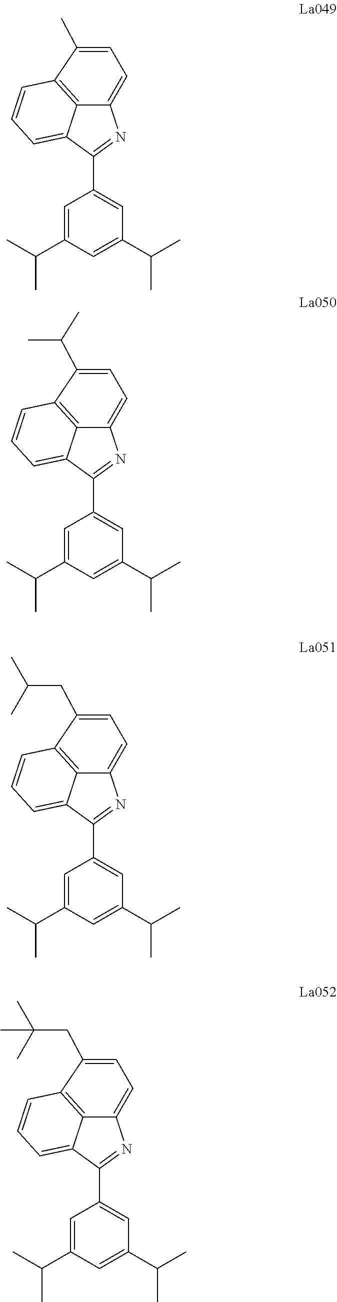

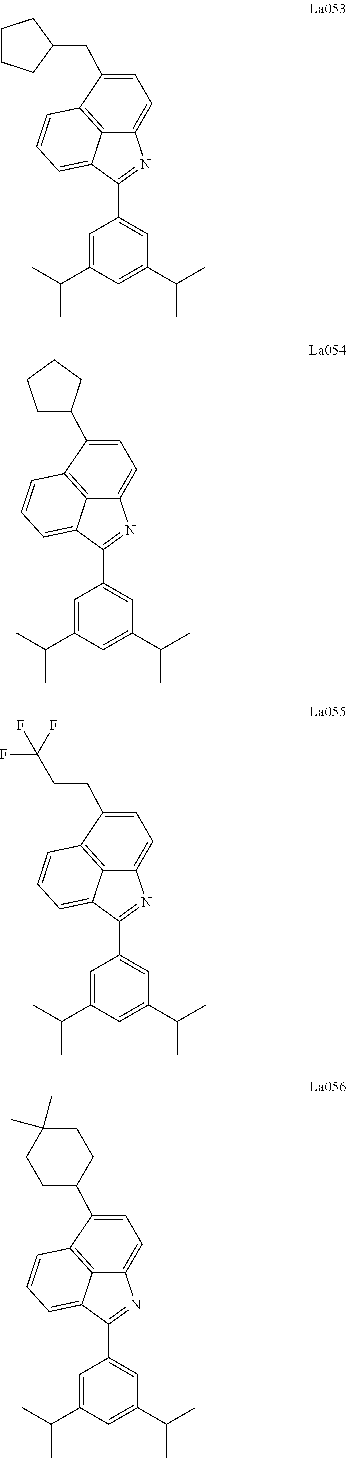

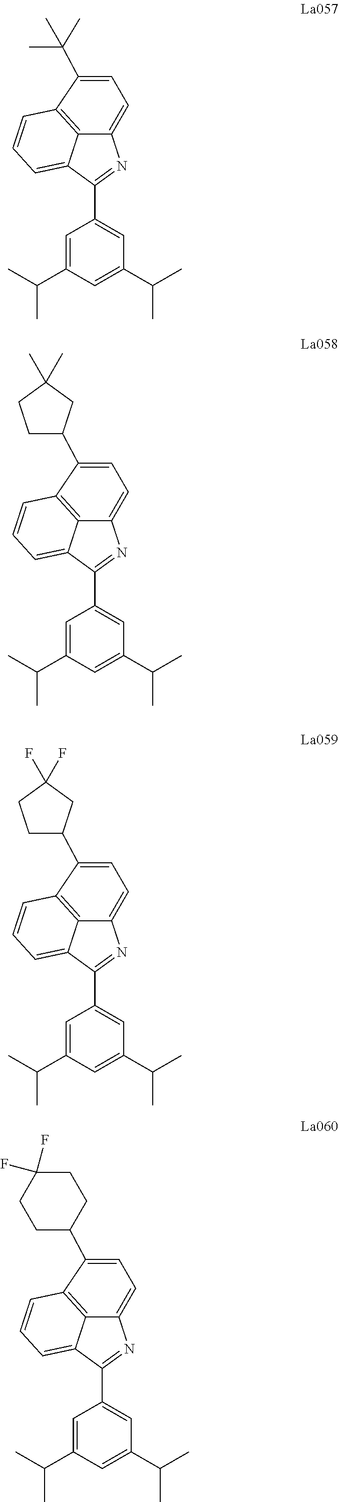

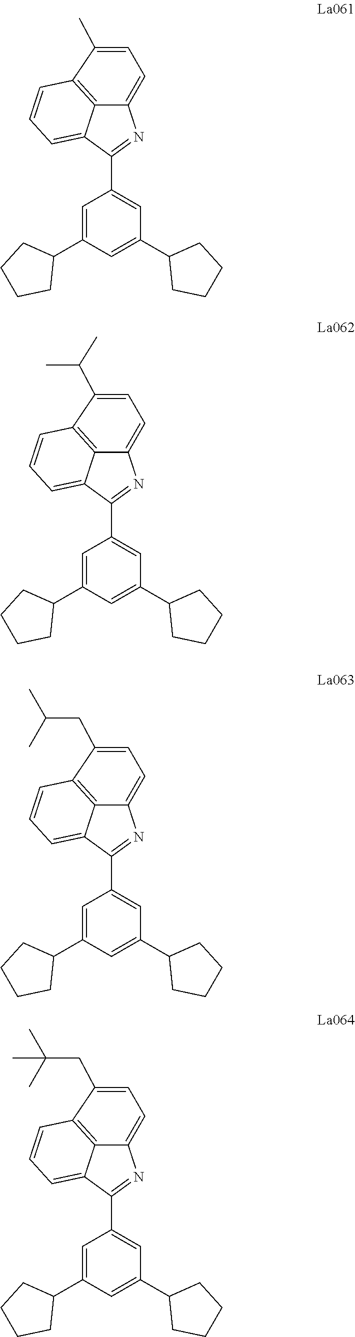

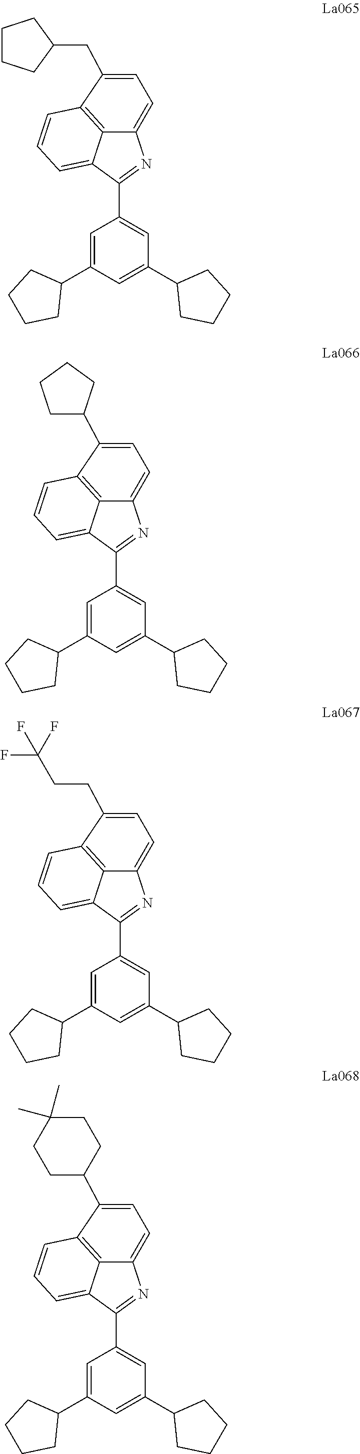

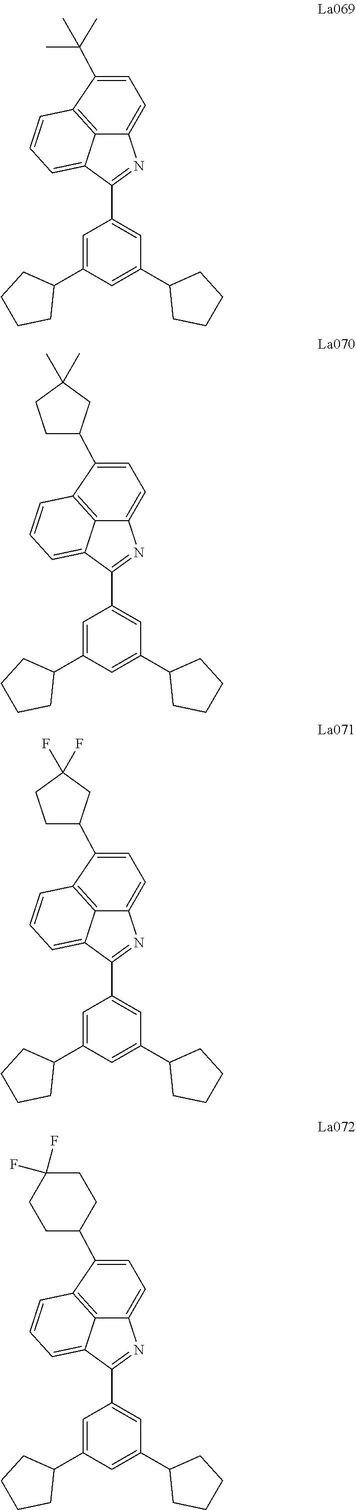

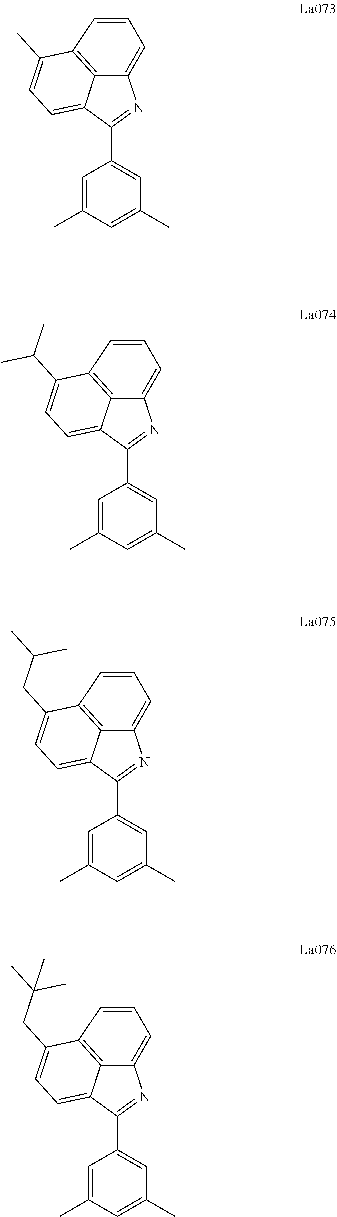

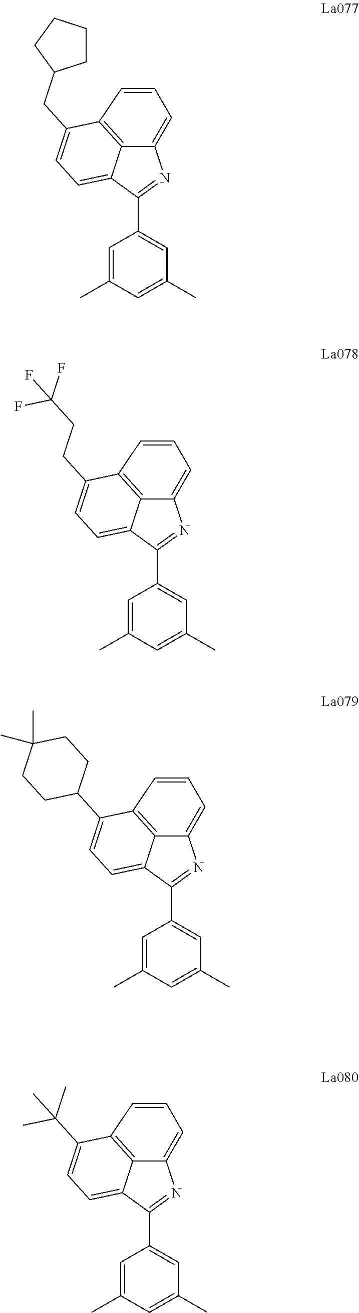

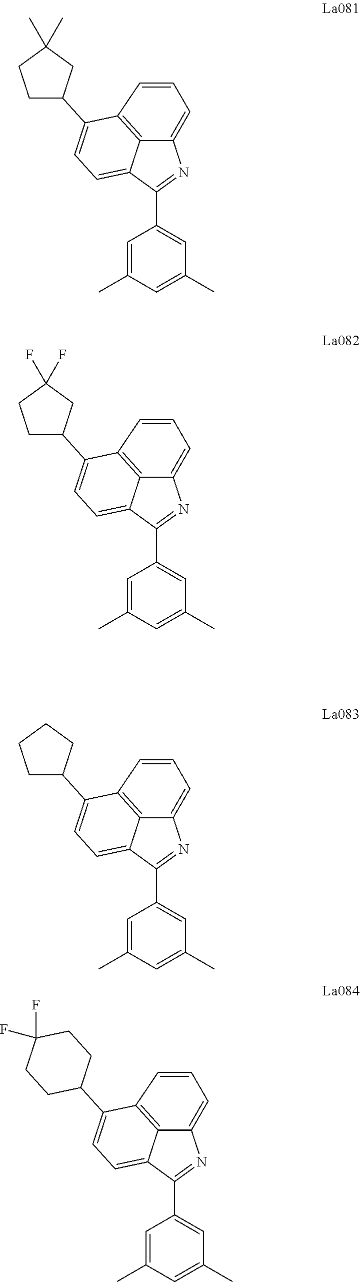 [SMILES: Cc1cc(C)cc(C2=Nc3cccc4c(C5CCC(C)(C)C5)ccc2c34)c1 ; Cc1cc(C)cc(C2=Nc3cccc4c(C5CCC(F)(F)C5)ccc2c34)c1 ; Cc1cc(C)cc(C2=Nc3cccc4c(C5CCCC5)ccc2c34)c1 ; Cc1cc(C)cc(C2=Nc3cccc4c(C5CCC(F)(F)CC5)ccc2c34)c1]

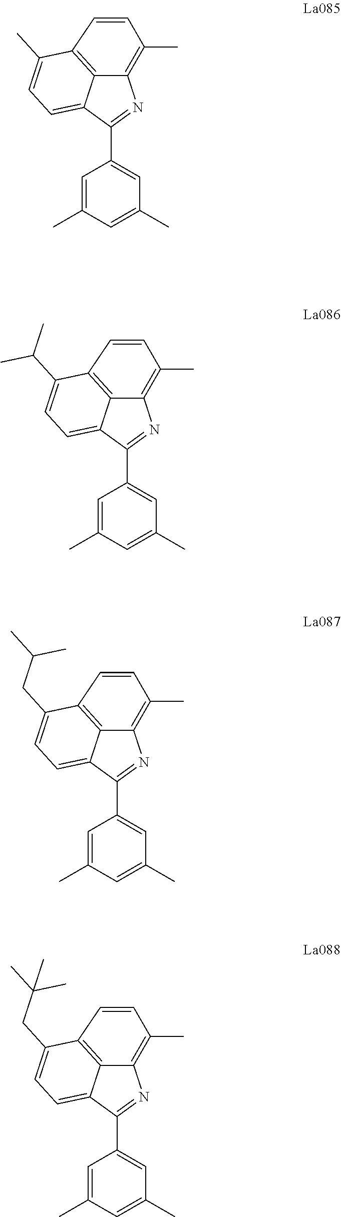

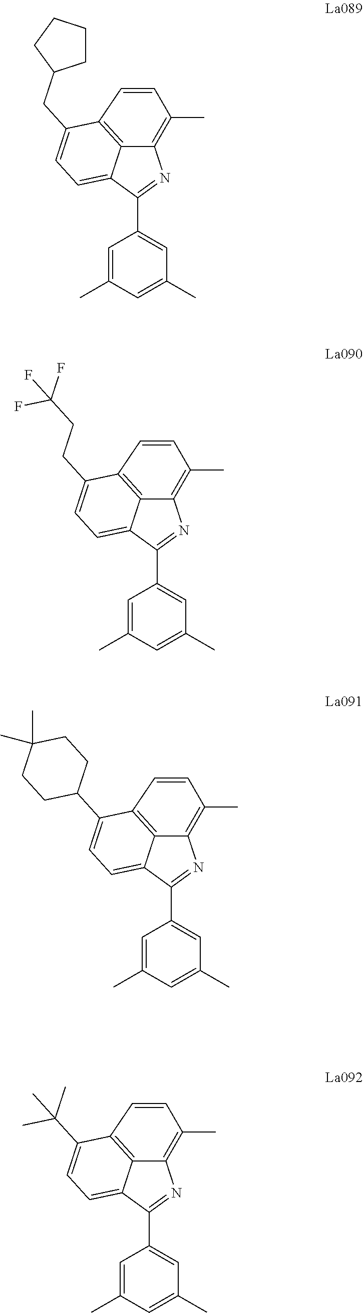

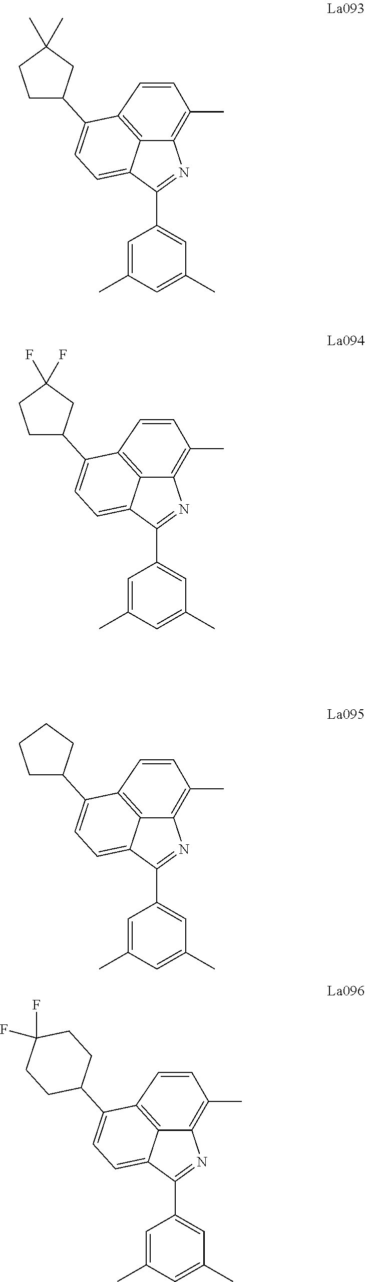 [SMILES: Cc1cc(C)cc(C2=Nc3c(C)ccc4c(C5CCC(C)(C)C5)ccc2c34)c1 ; Cc1cc(C)cc(C2=Nc3c(C)ccc4c(C5CCC(F)(F)C5)ccc2c34)c1 ; Cc1cc(C)cc(C2=Nc3c(C)ccc4c(C5CCCC5)ccc2c34)c1 ; Cc1cc(C)cc(C2=Nc3c(C)ccc4c(C5CCC(F)(F)CC5)ccc2c34)c1]

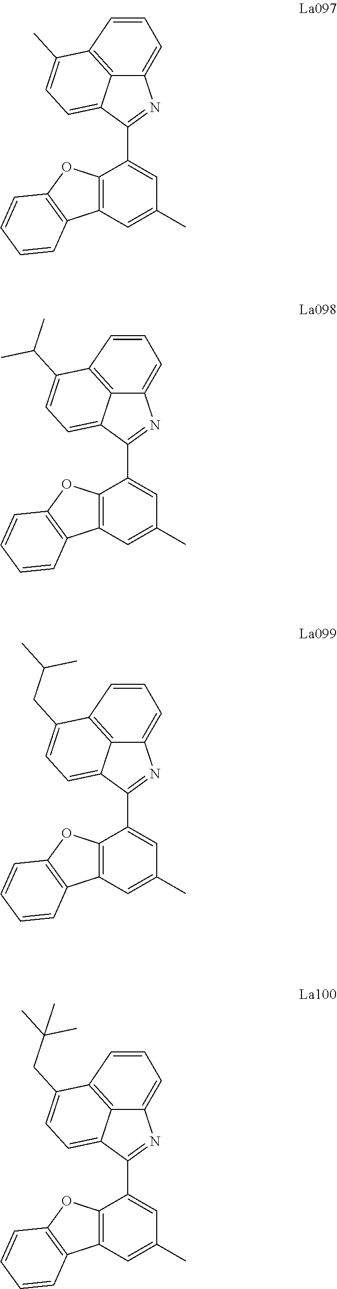 [SMILES: Cc1cc(C2=Nc3cccc4c(C)ccc2c34)c2oc3ccccc3c2c1 ; Cc1cc(C2=Nc3cccc4c(C(C)C)ccc2c34)c2oc3ccccc3c2c1 ; Cc1cc(C2=Nc3cccc4c(CC(C)C)ccc2c34)c2oc3ccccc3c2c1 ; Cc1cc(C2=Nc3cccc4c(CC(C)(C)C)ccc2c34)c2oc3ccccc3c2c1]

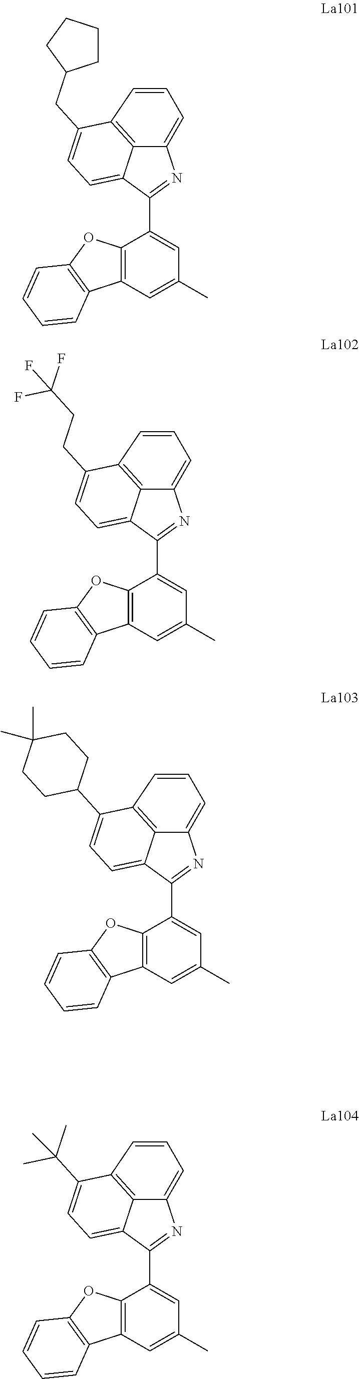

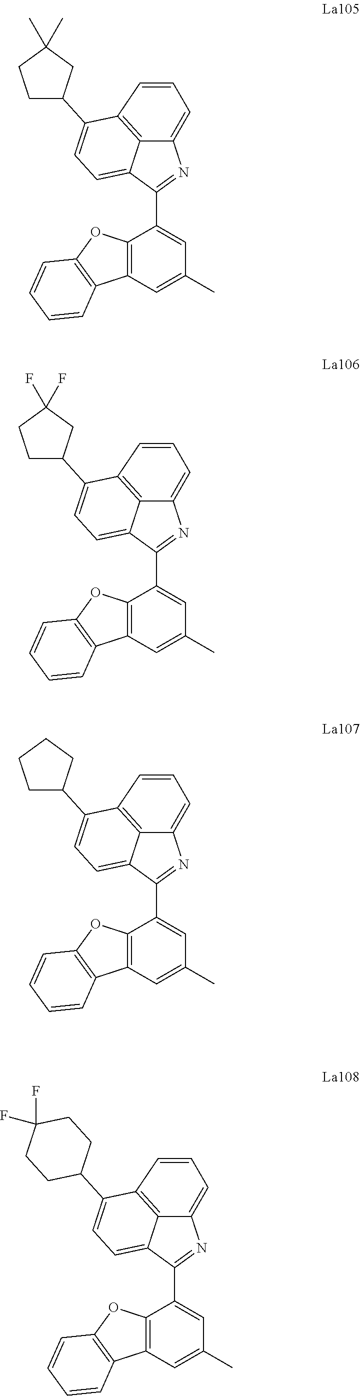 [SMILES: Cc1cc(C2=Nc3cccc4c(C5CCC(C)(C)C5)ccc2c34)c2oc3ccccc3c2c1 ; Cc1cc(C2=Nc3cccc4c(C5CCC(F)(F)C5)ccc2c34)c2oc3ccccc3c2c1 ; Cc1cc(C2=Nc3cccc4c(C5CCCC5)ccc2c34)c2oc3ccccc3c2c1 ; Cc1cc(C2=Nc3cccc4c(C5CCC(F)(F)CC5)ccc2c34)c2oc3ccccc3c2c1]

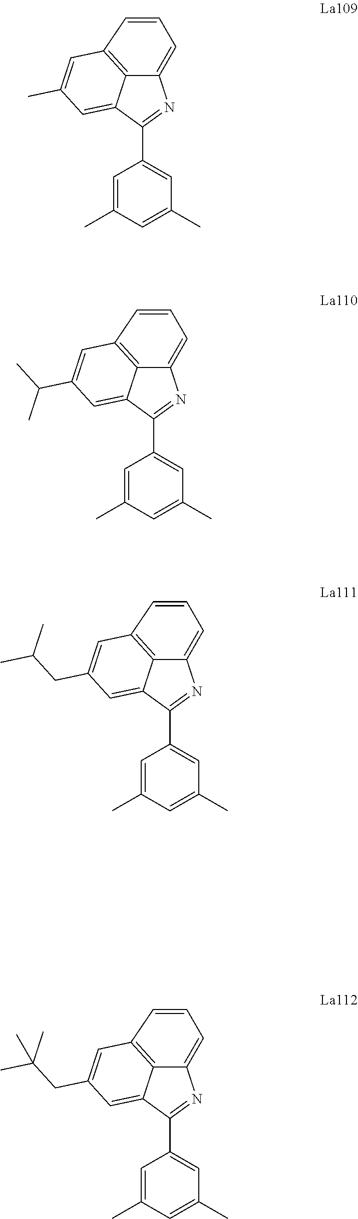

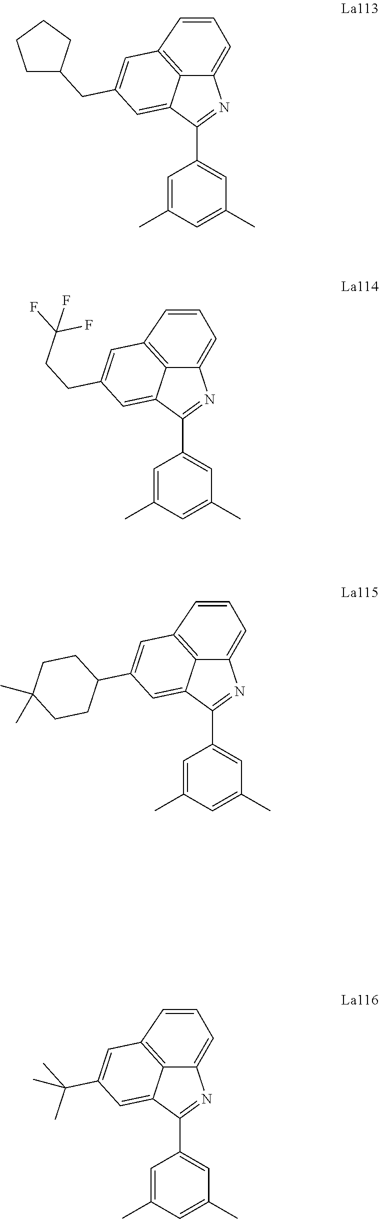

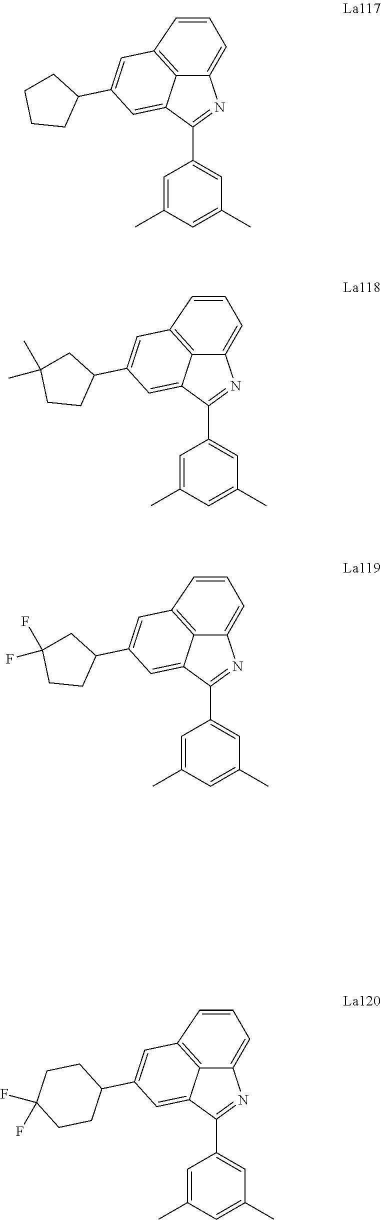

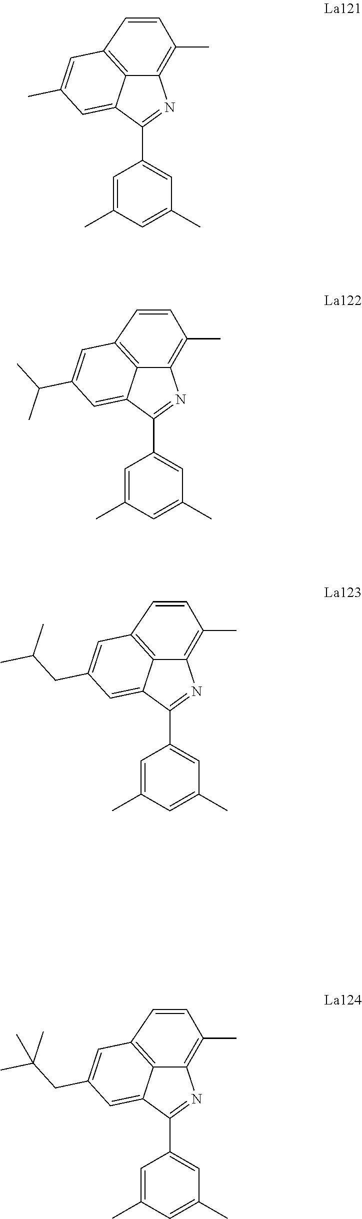

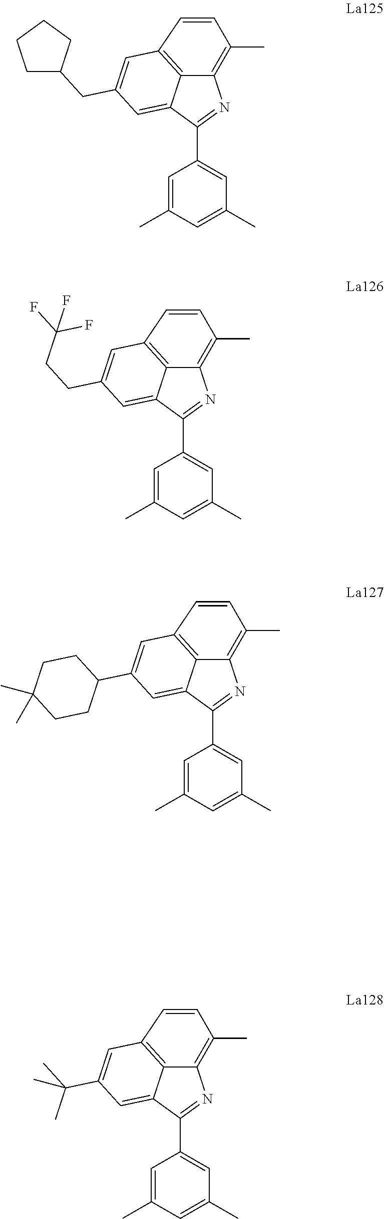

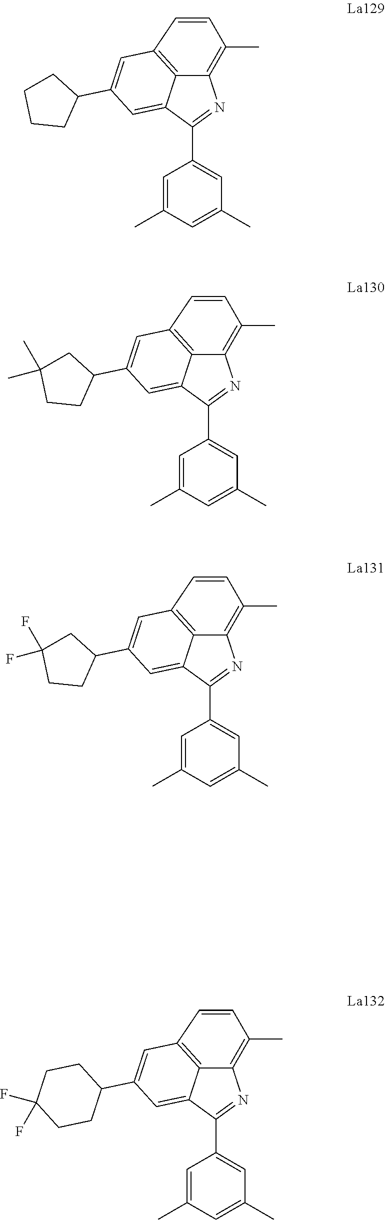

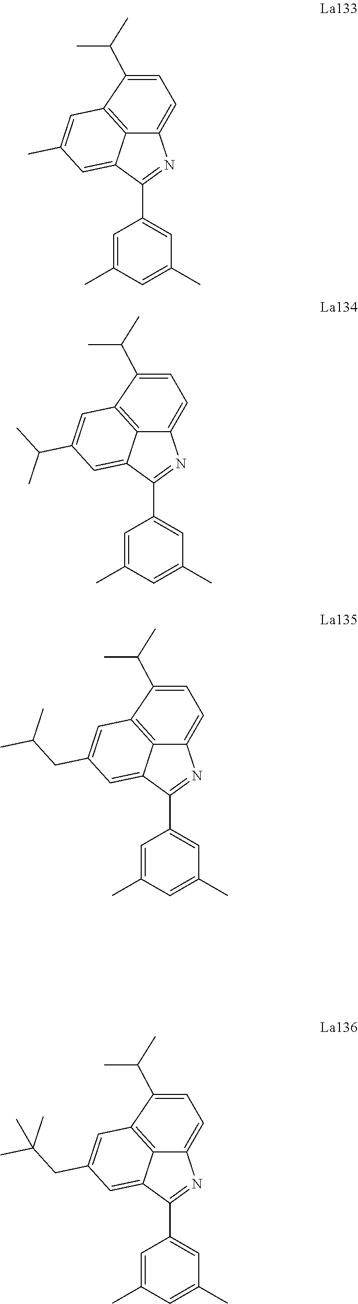

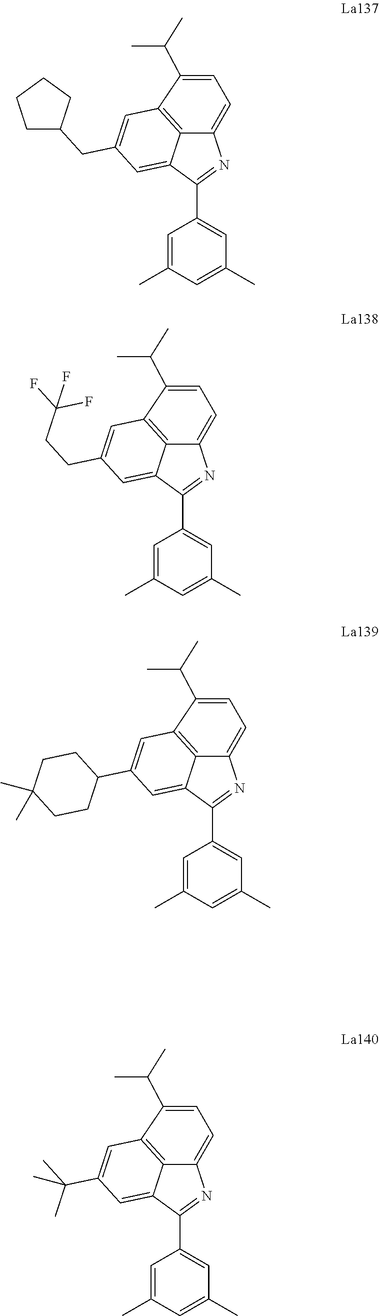

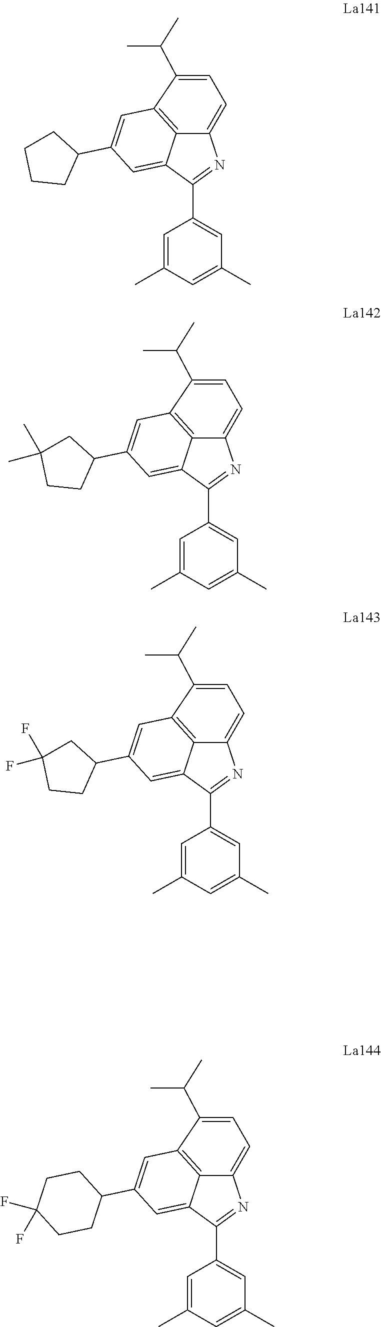

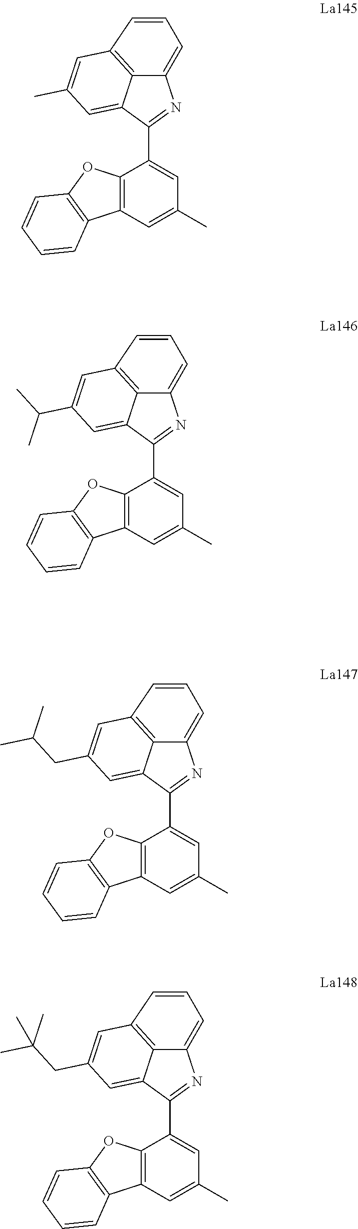

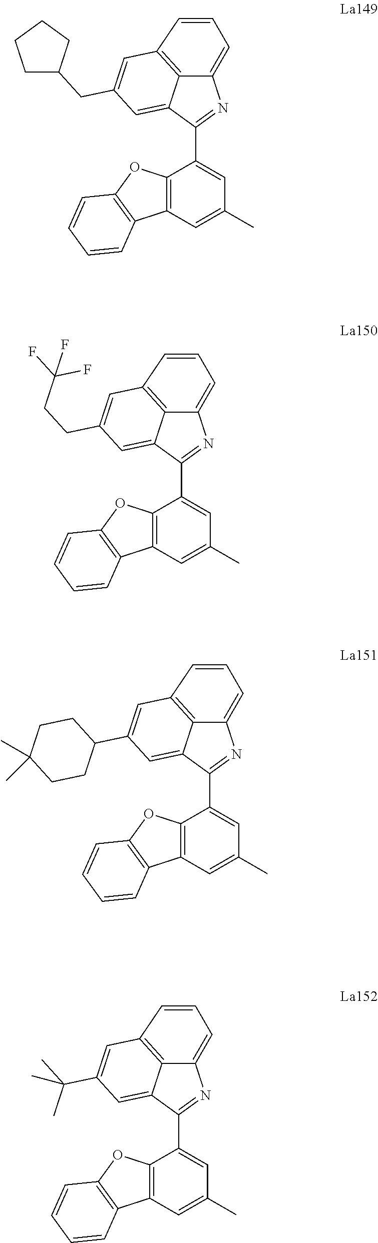

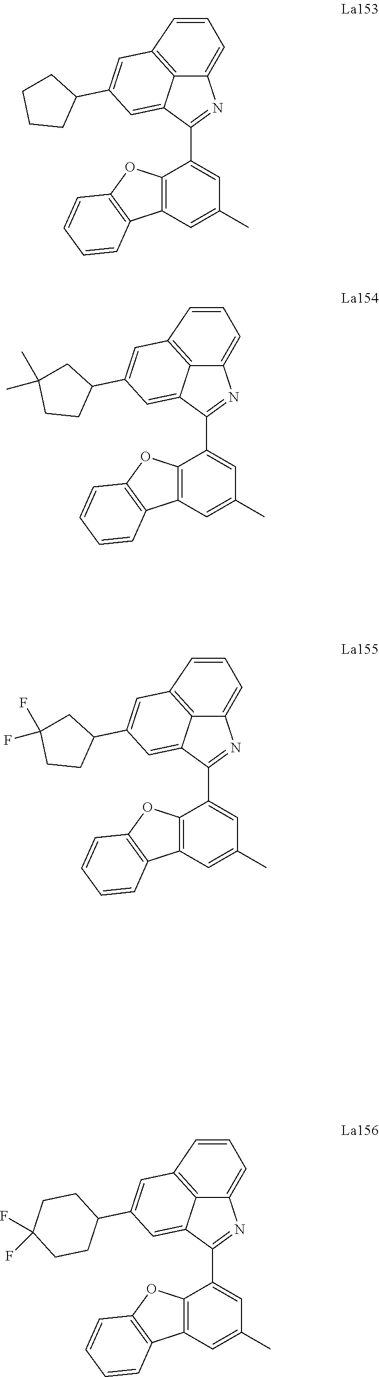

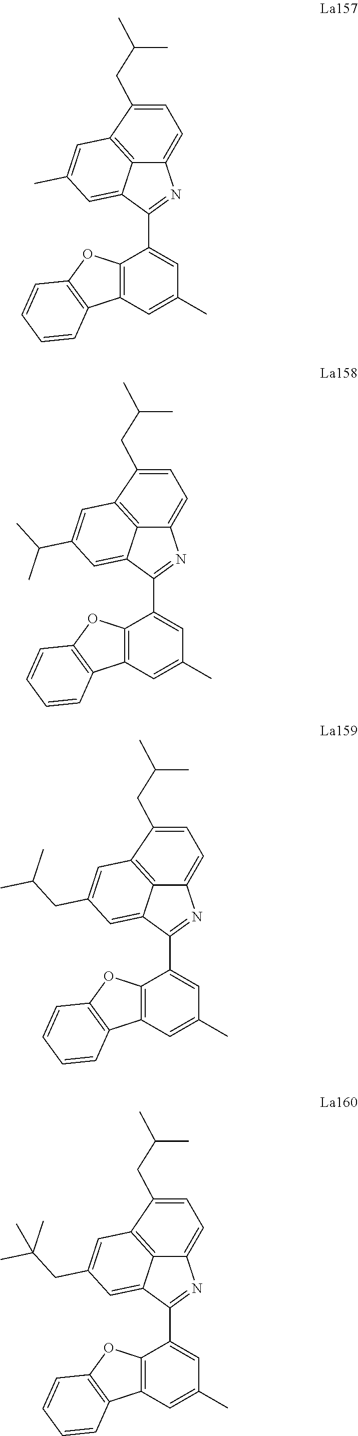

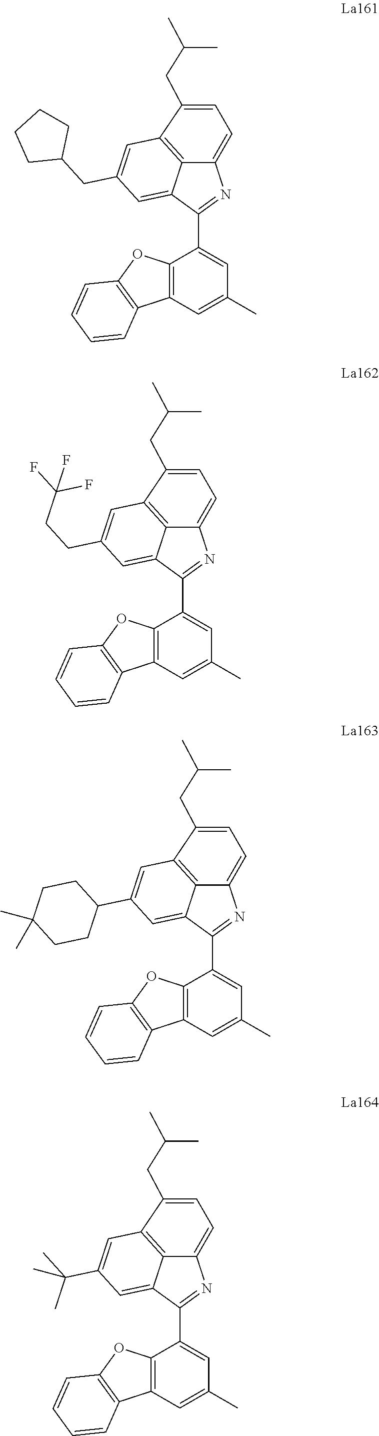

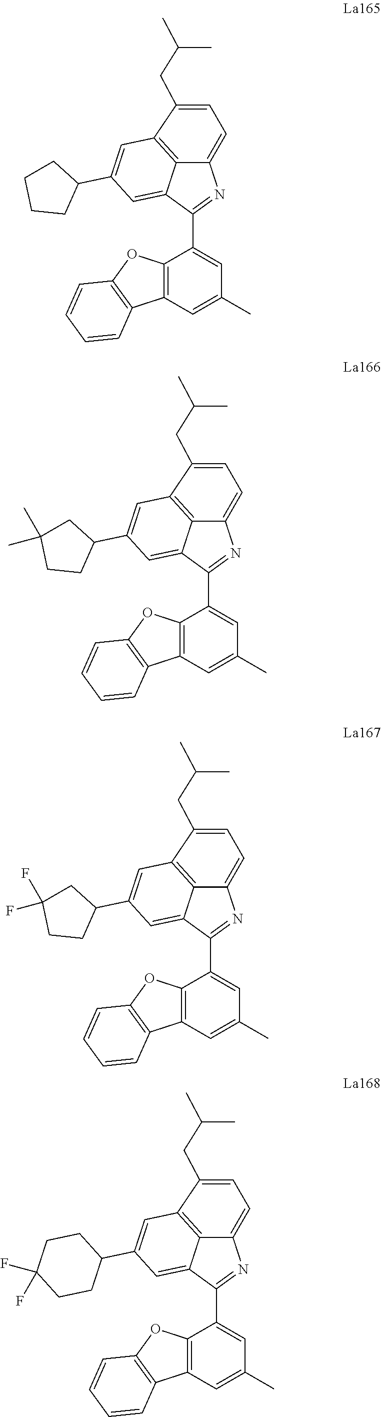

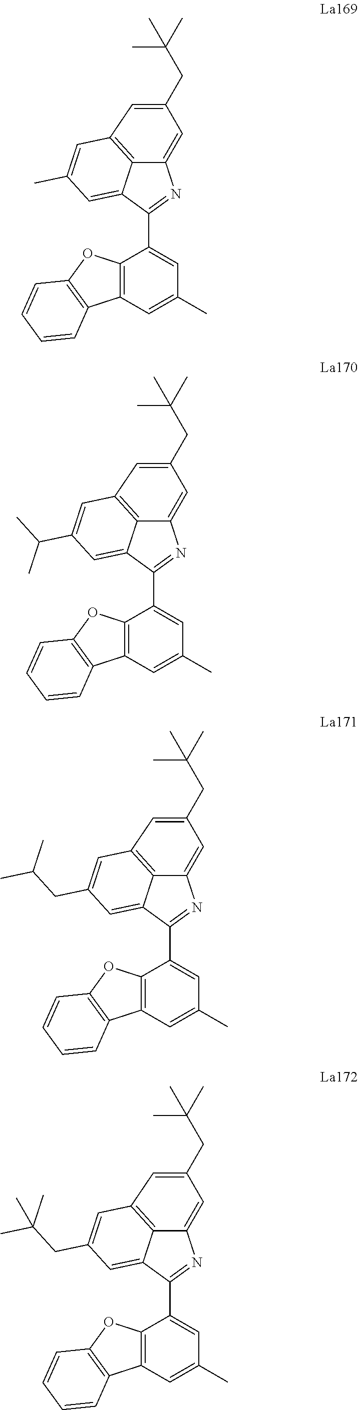

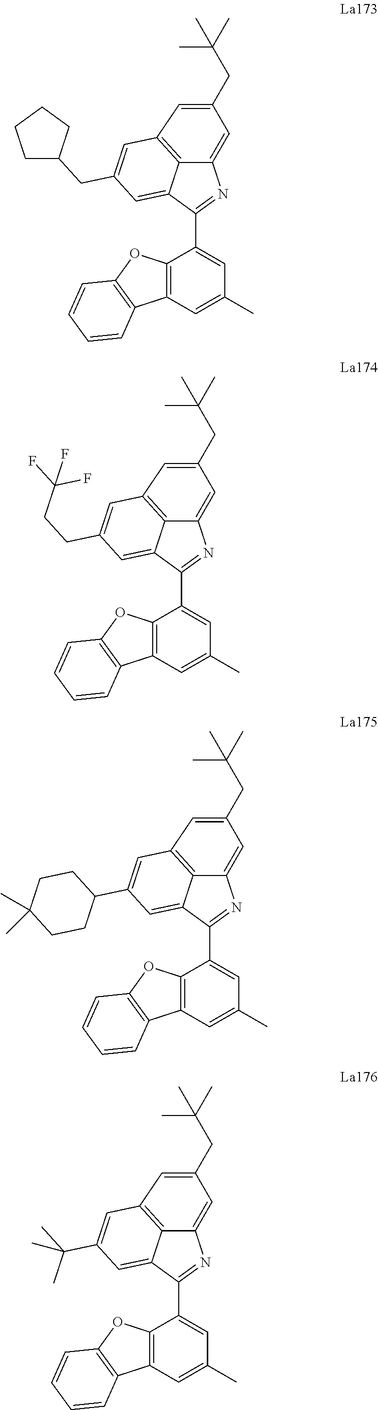

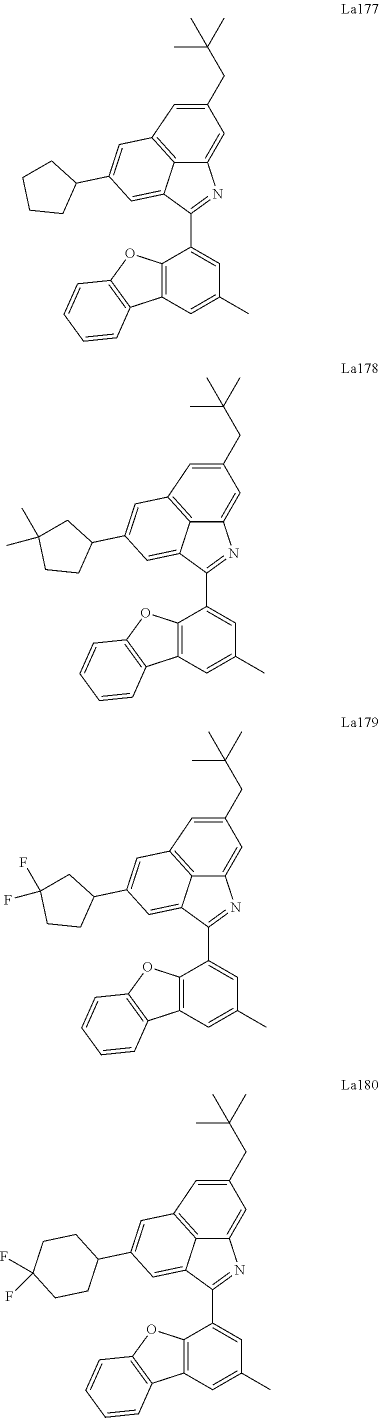

As a optional organometallic iridium compound, the Lc has one of the following structural formulas, or is partially or completely deuterated or fluorinated correspondingly,

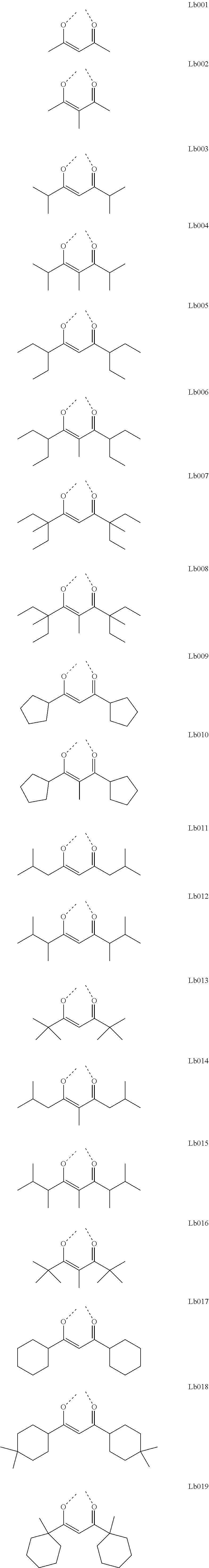

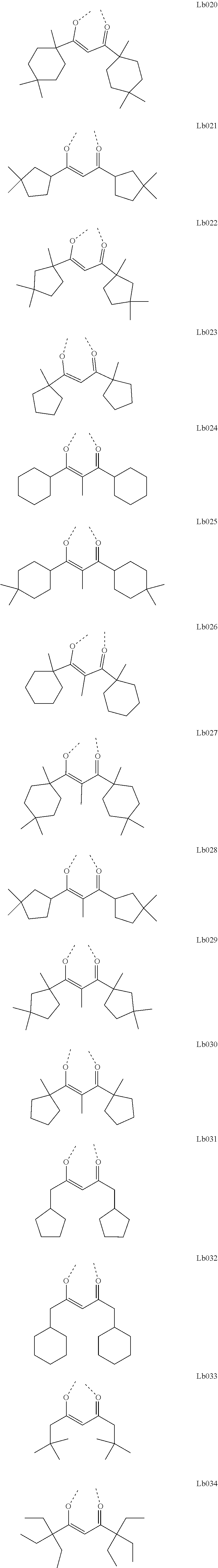

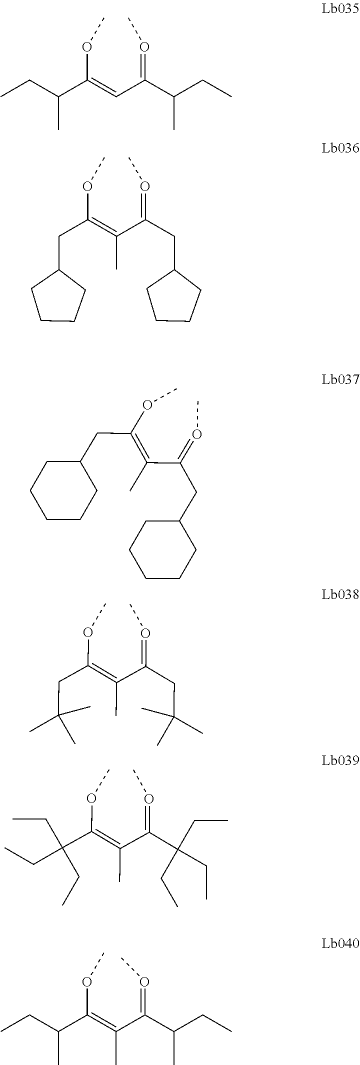

As a optional organometallic iridium compound, the Lc has one of the following structural formulas, or is partially or completely deuterated or fluorinated correspondingly,

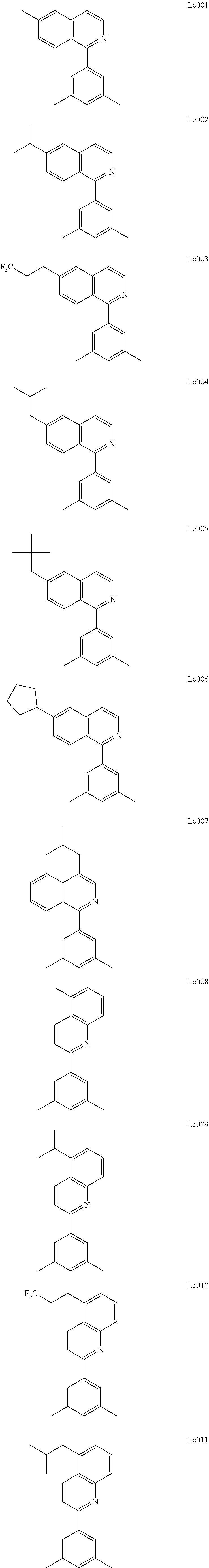

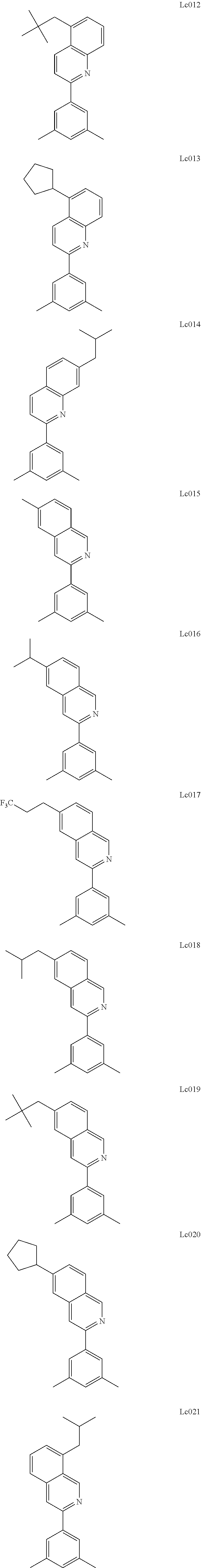

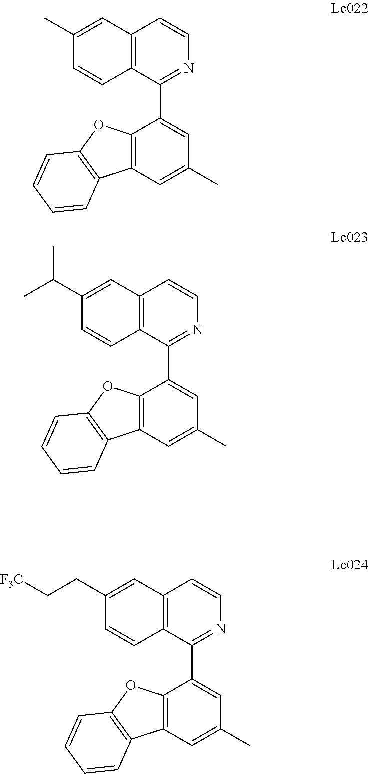

One of objectives of the present invention is to provide application of the organometallic iridium compound in an organic electroluminescent device.

One of objectives of the present invention is to provide use of the organometallic iridium compound as a red light-emitting doping material for a light-emitting layer in the organic electroluminescent device.

The material of the present invention has the advantages of high optical and electrical stability, low sublimation temperature, small emission half-peak width, high color saturation, high luminous efficiency, long device life and the like. As a phosphorescent material, the material of the present invention can convert a triplet excited state into light, thereby improving the luminous efficiency of organic electroluminescent devices and reducing energy consumption. In particular, the compound has the potential for application in the AMOLED industry as a red light-emitting dopant.

### DETAILED DESCRIPTION OF EMBODIMENTS

A compound of the present invention is an organometallic iridium compound having a general formula of Ir(La)(Lb)(Lc), where La is a structure represented by Formula (1):

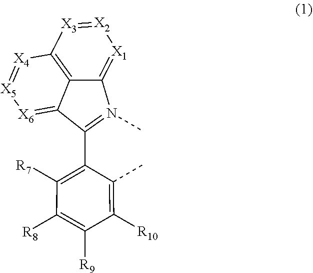

where dotted lines refer to positions connected to the metal Ir;
X₁ is N or CR₁, X₂ is N or CR₂, X₃ is N or CR₃, X₄ is N or CR₄, X₅ is N or CR₅, and X₆ is N or CR₆;
at most one of the X₁-X₆ is N, and when the X₁-X₆ are CR₁-CR₆, at least one of the R₁-R₆ is not H;
R₁-R₁₀ are independently selected from hydrogen, deuterium, halogen, cyano, hydroxyl, sulfhydryl, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₆ or R₇-R₁₀ may be connected to each other to form an aliphatic ring structure or an aromatic ring structure; at least one of the R₇-R₁₀ is not hydrogen; the “substituted” refers to substitution with deuterium, F, Cl, Br, C₁-C₆ alkyl, C₁-C₆ alkoxyl, C₃-C₆ cycloalkyl, amino substituted with C₁-C₆ alkyl, cyano, isocyano, or phosphino, and the substitution ranges from a single substitution number to a maximum substitution number;
and the heteroalkyl and the heteroaryl at least contain one O, N or S heteroatom;
Lb is a structure represented by Formula (2):

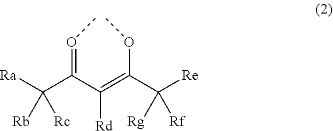

where dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl; any two of the Ra, the Rb and the Rc are connected to form an aliphatic ring structure, and any two of the Re, the Rf and the Rg are connected to form an aliphatic ring structure;
and the heteroalkyl and the heterocyclic alkyl at least contain one O, N or S heteroatom;
Lc is a monoanionic bidentate ligand, and the Lc is different from the Lb and is not an OO ligand;
the Lc and the La are the same or different, and the different indicates different parent nuclear structures, a same parent nuclear structure with different substituents, or a same parent nuclear structure with different substituent positions;
and any two or three of the La, the Lb and the Lc are connected to each other to form a polydentate ligand.

Examples of various groups of compounds represented by Formula (1) to Formula (5) are described below.

It is to be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, optionally includes methyl, ethyl, propyl, isopropyl, n-butyl, isobutyl, sec-butyl, and tert-butyl, and more optionally includes propyl, isopropyl, isobutyl, sec-butyl, and tert-butyl.

The C₃-C₂₀ cycloalkyl may include cyclopropyl, cyclobutyl, cyclopentyl, cyclohexyl, 1-adamantyl, 2-adamantyl, 1-norbornyl, and 2-norbornyl, and optionally includes cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, and optionally includes propenyl and allyl.

As a linear or branched alkyl or cycloalkyl consisting of atoms other than carbon and hydrogen, the C₁-C₁₀ heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, and optionally includes methoxymethyl and epoxy pentyl.

Specific examples of the aryl include phenyl, naphthyl, anthracyl, phenanthryl, tetracenyl, pyrenyl, chrysenyl, benzo[c]phenanthryl, benzo[g]chrysenyl, fluorenyl, benzofluorenyl, dibenzofluorenyl, biphenyl, triphenyl, tetraphenyl, and fluoranthracyl, and optionally include phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, and optionally include pyridyl, pyrimidinyl, triazinyl, dibenzofuryl, dibenzothienyl, azodibenzofuryl, azodibenzothienyl, diazodibenzofuryl, diazodibenzothienyl, carbazolyl, azocarbazolyl, and diazocarbazolyl.

The following embodiments are merely described to facilitate the understanding of the technical invention, and should not be considered as specific limitations of the present invention.

All raw materials, solvents and the like involved in the synthesis of compounds in the present invention are purchased from Alfa, Acros, and other suppliers known to persons skilled in the art.

### Synthesis of a Ligand La003

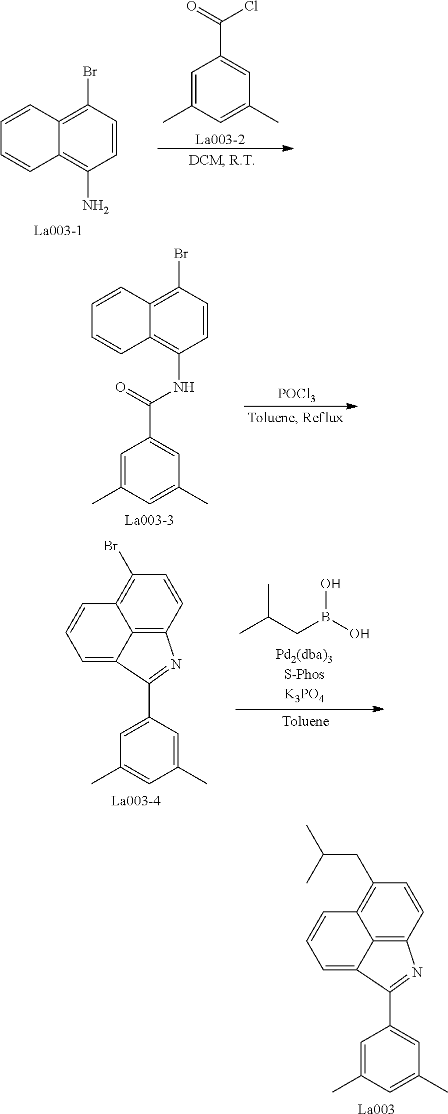

### Synthesis of a Compound La003-3

A compound La003-1 (30.00 g, 135.08 mmol), dichloromethane (300 ml) and triethylamine (15.03 g, 148.59 mmol) were added into a 1,000 ml three-necked round-bottomed flask, and vacuumization was performed for nitrogen replacement for 3 times. Under the protection of nitrogen, La003-2 (25.06 g, 148.59 mmol) was diluted with dichloromethane (125 ml) and completely added dropwise into the above reaction system within 15 minutes, and a resulting mixture was stirred at room temperature for 1 hour. According to monitoring by TLC (thin-layer chromatography, with a developing agent including ethyl acetate and petroleum ether at a ratio of 1:1), the raw material La003-1 was completely reacted.

Deionized water (50 ml) was added dropwise for quenching a reaction, and an organic phase was washed with deionized water (3*150 ml). Then, liquid separation was performed, and the organic phase was concentrated, followed by column chromatography with silica gel (200- to 300-mesh silica gel, with an eluting agent including ethyl acetate and petroleum ether at a ratio of 1:15) and concentration to obtain 40.67 g of a light yellow solid compound La003-3 with a purity of 99.81% and a yield of 85.00%. The mass spectrum was: 354.25 (M+H).

### Synthesis of a Compound La003-4

The compound La003-3 (35.00 g, 98.80 mmol), toluene (175 ml) and phosphorus oxychloride (30.30 g, 197.60 mmol) were added into a 500 ml three-necked round-bottomed flask, vacuumization was performed for nitrogen replacement for 3 times, and the above compounds were heated and stirred for reflux for 8 hours. According to monitoring by TLC (with a developing agent including ethyl acetate and petroleum ether at a ratio of 1:15), the raw material La003-3 was completely reacted.

Cooling was performed to room temperature, a reaction solution was added dropwise into deionized water (500 ml) for quenching a reaction, ethyl acetate (500 ml) was added for extraction and liquid separation, and an organic phase was washed with deionized water (3*200 ml). Then, liquid separation was performed, and the organic phase was concentrated, followed by column chromatography with silica gel (200- to 300-mesh silica gel, with an eluting agent including ethyl acetate and petroleum ether at a ratio of 1:25) and concentration to obtain 24.01 g of a white solid compound La003-4 with a purity of 99.77% and a yield of 72.31%. The mass spectrum was: 336.16 (M+H).

### Synthesis of a Compound La003

The compound La003-4 (23.50 g, 69.89 mmol), isobutaneboronic acid (10.69 g, 104.83 mmol), tris(dibenzylideneacetone)dipalladium (1.28 g, 1.40 mmol), 2-dicyclohexylphosphino-2′,6′-dimethoxybiphenyl (1.15 g, 2.80 mmol), potassium phosphate (29.67 g, 139.78 mmol) and toluene (350 ml) were added into a 1,000 ml three-necked round-bottomed flask, vacuumization was performed for nitrogen replacement for 3 times, and stirring was performed at 105° C. for 6 hours under the protection of nitrogen. According to monitoring by TLC (with a developing agent including ethyl acetate and petroleum ether at a ratio of 1:15), the raw material La003-4 was completely reacted.

Cooling was performed to room temperature, ethyl acetate (500 ml) was added, and deionized water was added for washing (3*450 ml). Then, liquid separation was performed, and an organic phase was concentrated, followed by column chromatography with silica gel (200- to 300-mesh silica gel, with an eluting agent including ethyl acetate and petroleum ether at a ratio of 1:20) and concentration to obtain 16.07 g of a white sugar-like solid compound La003 with a purity of 99.61% and a yield of 73.35%. The mass spectrum was: 314.26 (M+H).

### Synthesis of a Compound Ir(La003)₂(Lb005)

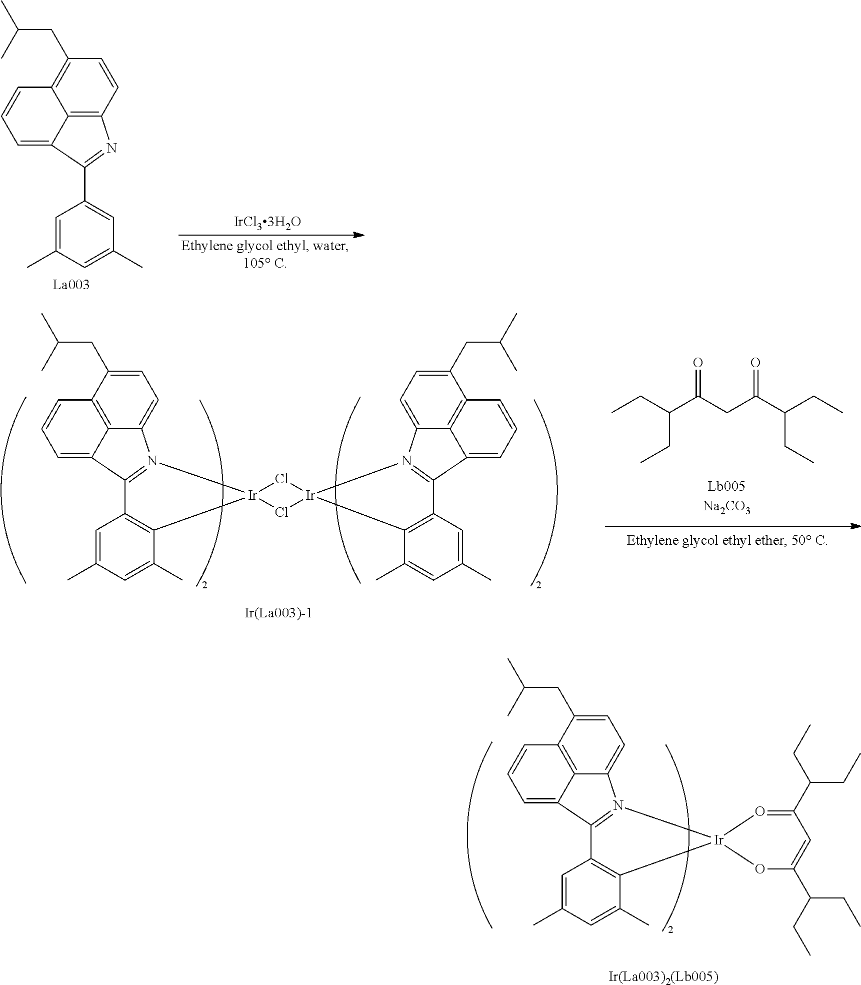

### Synthesis of a Compound Ir(La003)-1

The compound La003 (15.56 g, 49.63 mmol) and iridium trichloride trihydrate (5.00 g, 14.18 mmol) were added into a 500 ml three-necked round-bottomed flask, ethylene glycol ethyl ether (180 ml) and deionized water (60 ml) were added, vacuumization was performed for nitrogen replacement for 3 times, and the above compounds were heated to 105° C. and stirred for reflux for 24 hours.

After cooling was performed to room temperature, methanol (300 ml) was added for beating at room temperature for 1 hour, and suction filtration was performed. Then, a filter cake was washed with methanol (50 ml), and a resulting solid was dried under vacuum at 80° C. to obtain 10.05 g of a compound Ir(La003)-1 with a yield of 83.12%. The obtained compound was directly used in the next step without purification.

### Synthesis of a Compound Ir(La003)₂(Lb005)

The compound Ir(La003)-1 (9.8 g, 5.75 mmol), Lb005 (6.10 g, 28.74 mmol), sodium carbonate (6.09 g, 57.50 mmol) and ethylene glycol ethyl ether (100 ml) were added into a 500 ml one-necked round-bottomed flask, vacuumization was performed for nitrogen replacement for 3 times, and stirring was performed at 50° C. for 24 hours. According to monitoring by TLC (with a developing agent including methanol and dichloromethane at a ratio of 1:100), the Ir(La003)-1 was completely reacted.

After cooling was performed to room temperature, methanol (150 ml) was added for beating at room temperature for 2 hours, and suction filtration was performed. Then, a filter cake was dissolved in dichloromethane (300 ml) and filtered with 200- to 300-mesh silica gel (60 g), a filtrate was washed with deionized water (3*100 ml) and concentrated at 50° C. to obtain a dark red solid, and the dark red solid was recrystallized with toluene and methanol for two times to obtain 4.52 g of a red solid compound Ir(La003)₂(Lb005) with a purity of 99.89% and a yield of 38.21%. 4.52 g of the crude product Ir(La003)₂(Lb005) was sublimated and purified to obtain 2.54 g of sublimated and purified Ir(La003)₂(Lb005) with a purity of 99.78% and a yield of 56.19%. The mass spectrum was 1029.32 (M+H).

¹H NMR (400 MHz, CDCl3) δ 7.87 (m, 2H), 7.81 (m, 2H), 7.68 (s, 2H), 7.49-7.47 (m, 2H), 7.45 (d, J=7.5 Hz, 2H), 6.92 (d, J=1.6 Hz, 2H), 6.91 (s, 2H), 4.72 (s, 1H), 2.91 (m, 4H), 2.34 (s, 12H), 1.81-1.79 (m, 2H), 1.32-1.23 (m, 8H), 1.03-1.01 (m, 2H), 0.94 (t, J=6.7 Hz, 12H), 0.87 (d, J=6.3 Hz, 12H).

### Synthesis of a Compound Ir(La003)₂(Lb007)

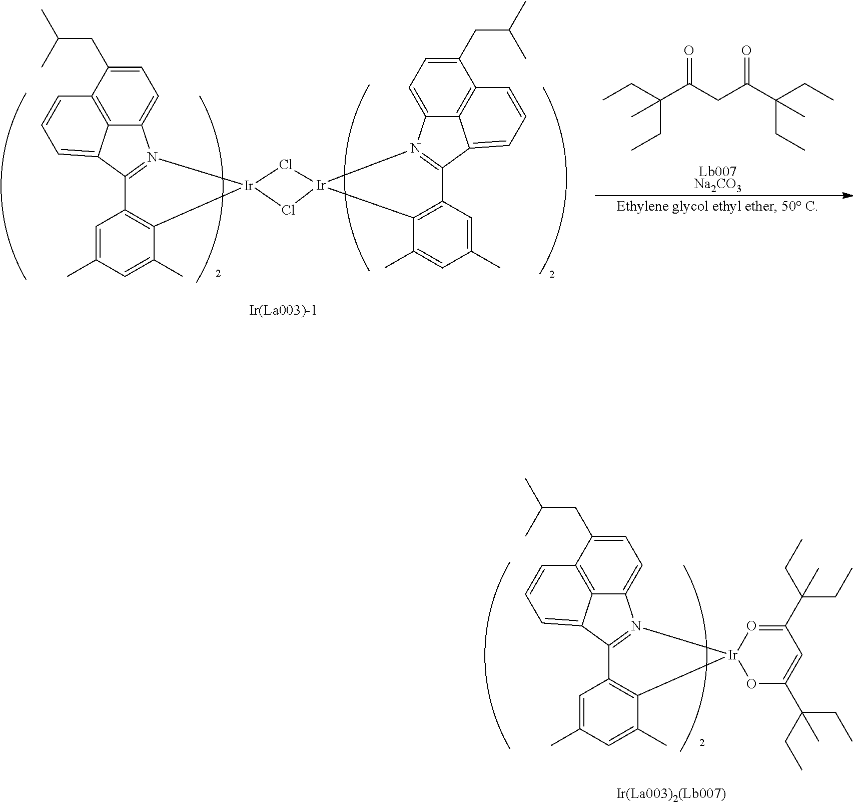

### Synthesis of a Compound Ir(La003)₂(Lb007)

With reference to synthesis and purification methods of the compound Ir(La003)₂(Lb005), only the corresponding raw materials were required to be changed, and 2.35 g of a red solid compound Ir(La003)₂(Lb007) with a purity of 99.82% and a yield of 37.64% was obtained. 2.35 g of the crude product Ir(La003)₂(Lb007) was sublimated and purified to obtain 1.28 g of sublimated and purified Ir(La003)₂(Lb007) with a purity of 99.76% and a yield of 54.46%. The mass spectrum was 1057.52 (M+H).

¹H NMR (400 MHz, CDCl3) δ 7.89-7.86 (m, 2H), 7.81 (m, 2H), 7.68 (s, 2H), 7.50-7.46 (m, 4H), 6.9-6.91 (m, 2H), 6.88 (s, 2H), 4.75 (s, 1H), 2.92-2.90 (m, 4H), 2.34 (s, 12H), 1.85-1.75 (m, 2H), 1.05-0.99 (m, 14H), 0.92-0.85 (m, 24H).

### Synthesis of a Ligand La006

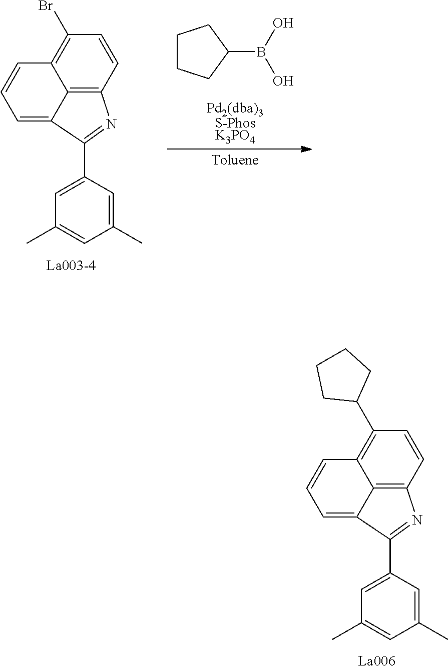

### Synthesis of a Compound La006

With reference to synthesis and purification methods of the compound La003, only the corresponding raw materials were required to be changed, and 18.54 g of a target compound La006 with a purity of 99.77% and a yield of 68.78% was obtained. The mass spectrum was 326.28 (M+H).

### Synthesis of a Compound Ir(La006)₂(Lb005)

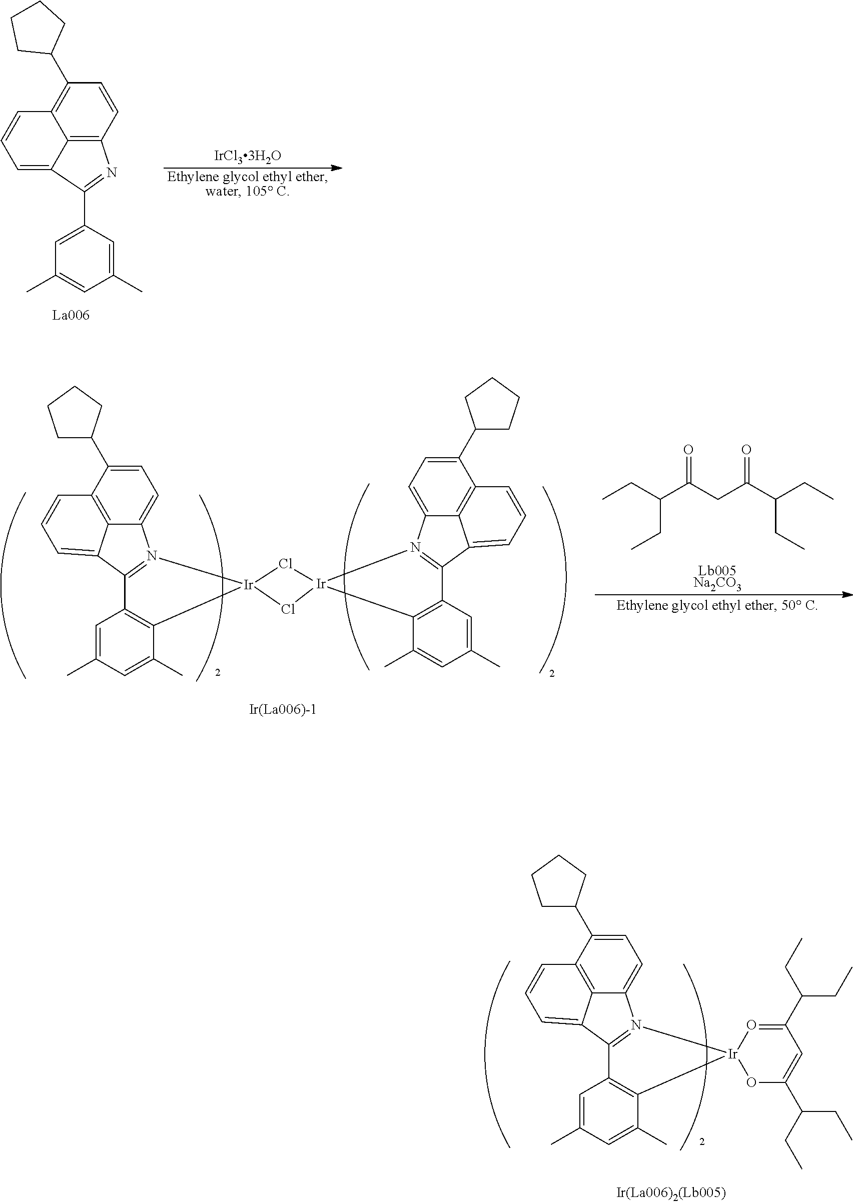

### Synthesis of a Compound Ir(La006)-1

With reference to synthesis and purification methods of the compound Ir(La003)-1, only the corresponding raw materials were required to be changed, and 9.81 g of a red solid compound Ir(La006)-1 with a yield of 68.21% was obtained. The obtained compound was directly used in the next step without purification.

### Synthesis of a Compound Ir(La006)₂(Lb005)

With reference to synthesis and purification methods of the compound Ir(La003)₂(Lb005), only the corresponding raw materials were required to be changed, and 2.12 g of a red solid compound Ir(La006)₂(Lb005) with a purity of 99.80% and a yield of 38.88% was obtained. 2.12 g of the crude product Ir(La006)₂(Lb005) was sublimated and purified to obtain 1.03 g of sublimated and purified Ir(La006)₂(Lb005) with a purity of 99.75% and a yield of 48.58%. The mass spectrum was 1053.16 (M+H).

¹H NMR (400 MHz, CDCl3) δ 7.88-7.86 (m, 2H), 7.81 (m, 2H), 7.68 (s, 2H), 7.49-7.47 (m, 2H), 7.45 (d, J=7.5 Hz, 2H), 6.92-6.89 (m, 4H), 4.75 (s, 1H), 2.34 (s, 12H), 1.91-1.89 (m, 4H), 1.77-1.76 (m, 4H), 1.70-1.64 (m, 8H), 1.32-1.31 (m, 4H), 1.27-1.21 (m, 4H), 1.03-1.00 (m, 4H), 0.94 (t, J=6.6 Hz, 12H).

### Synthesis of a Ligand La015

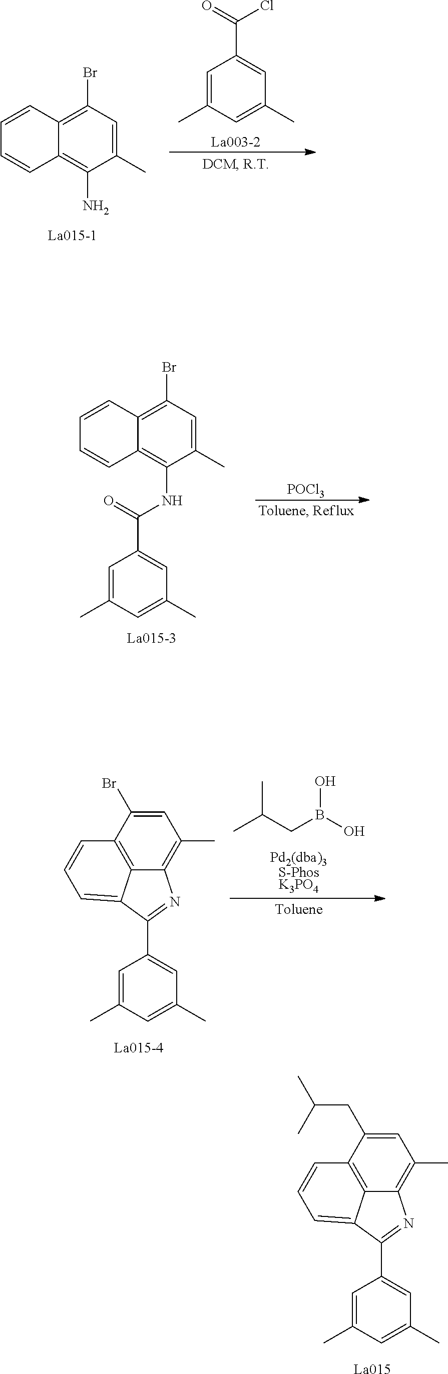

### Synthesis of a Compound La015-3

With reference to synthesis and purification methods of the compound La003-3, only the corresponding raw materials were required to be changed, and 35.47 g of a white solid compound La015-3 with a purity of 99.81% and a yield of 84.74% was obtained. The mass spectrum was 368.08 (M+H).

### Synthesis of a Compound La015-4

With reference to synthesis and purification methods of the compound La003-4, only the corresponding raw materials were required to be changed, and 20.63 g of a white solid compound La015-4 with a purity of 99.83% and a yield of 71.55% was obtained. The mass spectrum was 350.16 (M+H).

### Synthesis of a Compound La015

With reference to synthesis and purification methods of the compound La003, only the corresponding raw materials were required to be changed, and 15.22 g of a white sugar-like solid compound La015 with a purity of 99.75% and a yield of 68.73% was obtained. The mass spectrum was 328.48 (M+H).

### Synthesis of a Compound Ir(La015)₂(Lb005)

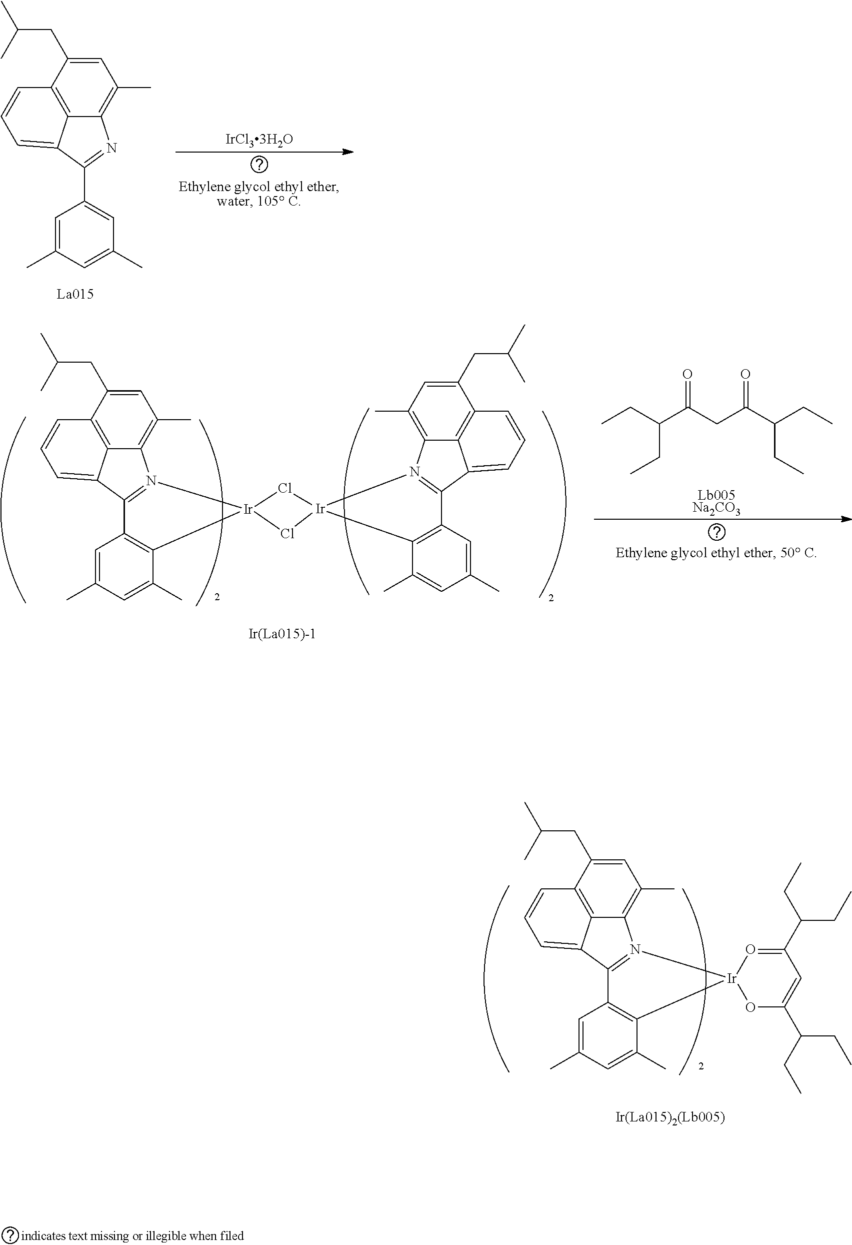

### Synthesis of a Compound Ir(La015)-1

With reference to synthesis and purification methods of the compound Ir(La003)-1, only the corresponding raw materials were required to be changed, and 8.78 g of a red solid compound Ir(La015)-1 with a yield of 65.13% was obtained. The obtained compound was directly used in the next step without purification.

### Synthesis of a Compound Ir(La015)₂(Lb005)

With reference to synthesis and purification methods of the compound Ir(La003)₂(Lb005), only the corresponding raw materials were required to be changed, and 1.98 g of a red solid compound Ir(La015)₂(Lb005) with a purity of 99.88% and a yield of 40.05% was obtained. 1.98 g of the crude product Ir(La015)₂(Lb005) was sublimated and purified to obtain 1.10 g of sublimated and purified Ir(La015)₂(Lb005) with a purity of 99.75% and a yield of 55.55%. The mass spectrum was 1057.32 (M+H).

¹H NMR (400 MHz, CDCl3) δ 7.88-7.86 (m, 2H), 7.81 (m, 2H), 7.68 (m, 2H), 7.63 (s, 2H), 7.49-7.47 (m, 2H), 6.92 (s, 2H), 4.75 (s, 1H), 2.92 (d, J=6.8 Hz, 4H), 2.70 (s, 6H), 2.34 (d, J=15.0 Hz, 12H), 1.83-1.77 (m, 2H), 1.34-1.28 (m, 4H), 1.25-1.23 (m, 4H), 1.03-1.00 (m, 2H), 0.94 (t, J=6.7 Hz, 12H), 0.87 (d, J=6.3 Hz, 12H).

### Synthesis of a Ligand La029

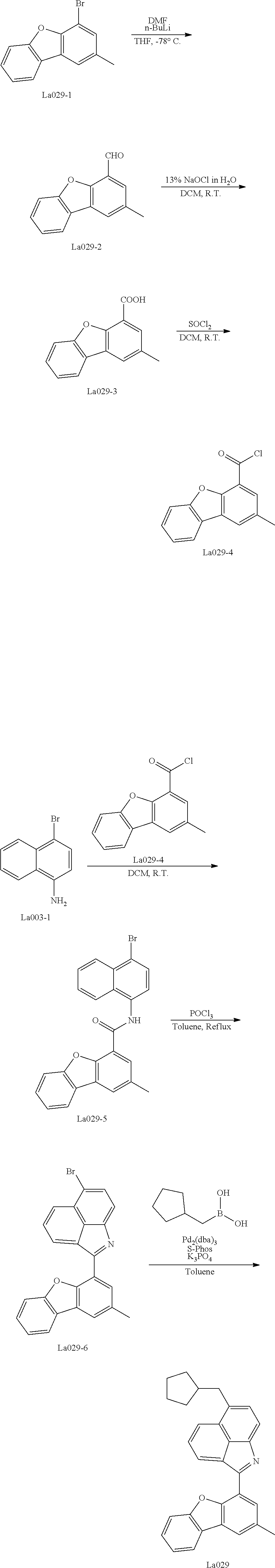

### Synthesis of a Compound La029-2

La029-1 (50.00 g, 191.48 mmol) and dry tetrahydrofuran (500 ml) was added into a 1,000 ml three-necked round-bottomed flask, and vacuumization was performed for nitrogen replacement for 3 times. The system was cooled to −78° C., n-butyl lithium (86.25 ml, 210.63 mmol, 2.5 mol/1 n-hexane solution) was completely added dropwise within 30 minutes, and a resulting mixture was stirred at −78° C. for 1 hour. Then, N,N-dimethylformamide (27.99 g, 382.96 mmol) was completely added dropwise within 10 minutes, and a resulting mixture was stirred at −78° C. for 1 hour. According to monitoring by TLC (with petroleum ether as a developing agent), the raw material La029-1 was completely reacted.

Deionized water (100 ml) was added dropwise for quenching a reaction, a resulting reaction solution was heated to room temperature and concentrated to remove the tetrahydrofuran, ethyl acetate (500 ml) was added, and an organic phase was washed with deionized water (3*150 ml). Then, liquid separation was performed, and the organic phase was concentrated, followed by column chromatography with silica gel (200- to 300-mesh silica gel, with an eluting agent including ethyl acetate and petroleum ether at a ratio of 1:12) and concentration to obtain 28.63 g of a light yellow liquid compound La029-2 with a purity of 99.51% and a yield of 71.12%. The mass spectrum was: 211.06 (M+H).

### Synthesis of a Compound La029-3

The La029-2 (28.11 g, 133.71 mmol) and dichloromethane (300 ml) were added into a 1,000 ml three-necked round-bottomed flask, sodium hypochlorite containing 13% of active chlorine (49.76 g, 668.55 mmol, calculated based on sodium hypochlorite) (the pH of the sodium hypochlorite was adjusted to 6 by sulfuric acid with a mass concentration of 20%) was completely added dropwise within 40 minutes, and a resulting mixture was stirred at room temperature for 1 hour. According to monitoring by TLC (with a developing agent including ethyl acetate and petroleum ether at a ratio of 1:10), the raw material La029-2 was completely reacted.

Liquid separation was performed, and an organic phase was washed with deionized water (3*100 ml). Then, liquid separation was performed, and the organic phase was concentrated to obtain 25.75 g of a light yellow liquid compound La029-3 with a purity of 99.32% and a yield of 85.12%. The mass spectrum was: 227.16 (M+H). The crude product was directly used in the next step without purification.

### Synthesis of a Compound La029-4

The La029-3 (23.54 g, 104.05 mmol) and dichloromethane (250 ml) were added into a 500 ml three-necked round-bottomed flask, vacuumization was performed for nitrogen replacement for three times, thionyl chloride (24.76 g, 208.11 mmol) was completely added dropwise within 10 minutes under stirring at room temperature, and a resulting mixture was stirred at room temperature for 40 minutes. According to monitoring by TLC (with a developing agent including ethyl acetate and petroleum ether at a ratio of 1:10), the raw material La029-3 was completely reacted.

A reaction solution was directly concentrated, and an organic phase was concentrated to obtain 19.31 g of a light yellow liquid compound La029-4 with a yield of 75.85%. The crude product was directly used in the next step without purification.

### Synthesis of a Compound La029-5

With reference to synthesis and purification methods of the compound La003-3, only the corresponding raw materials were required to be changed, and 30.11 g of a white solid compound La029-5 with a purity of 99.78% and a yield of 83.34% was obtained. The mass spectrum was 430.06 (M+H).

### Synthesis of a Compound La029-6

With reference to synthesis and purification methods of the compound La003-4, only the corresponding raw materials were required to be changed, and 18.67 g of a white solid compound La029-6 with a purity of 99.83% and a yield of 68.56% was obtained. The mass spectrum was 412.04 (M+H).

### Synthesis of a Compound La029

With reference to synthesis and purification methods of the compound La003, only the corresponding raw materials were required to be changed, and 11.62 g of a white sugar-like solid compound La029 with a purity of 99.75% and a yield of 65.81% was obtained. The mass spectrum was 416.2 (M+H).

### Synthesis of a Compound Ir(La029)₂(Lb005)

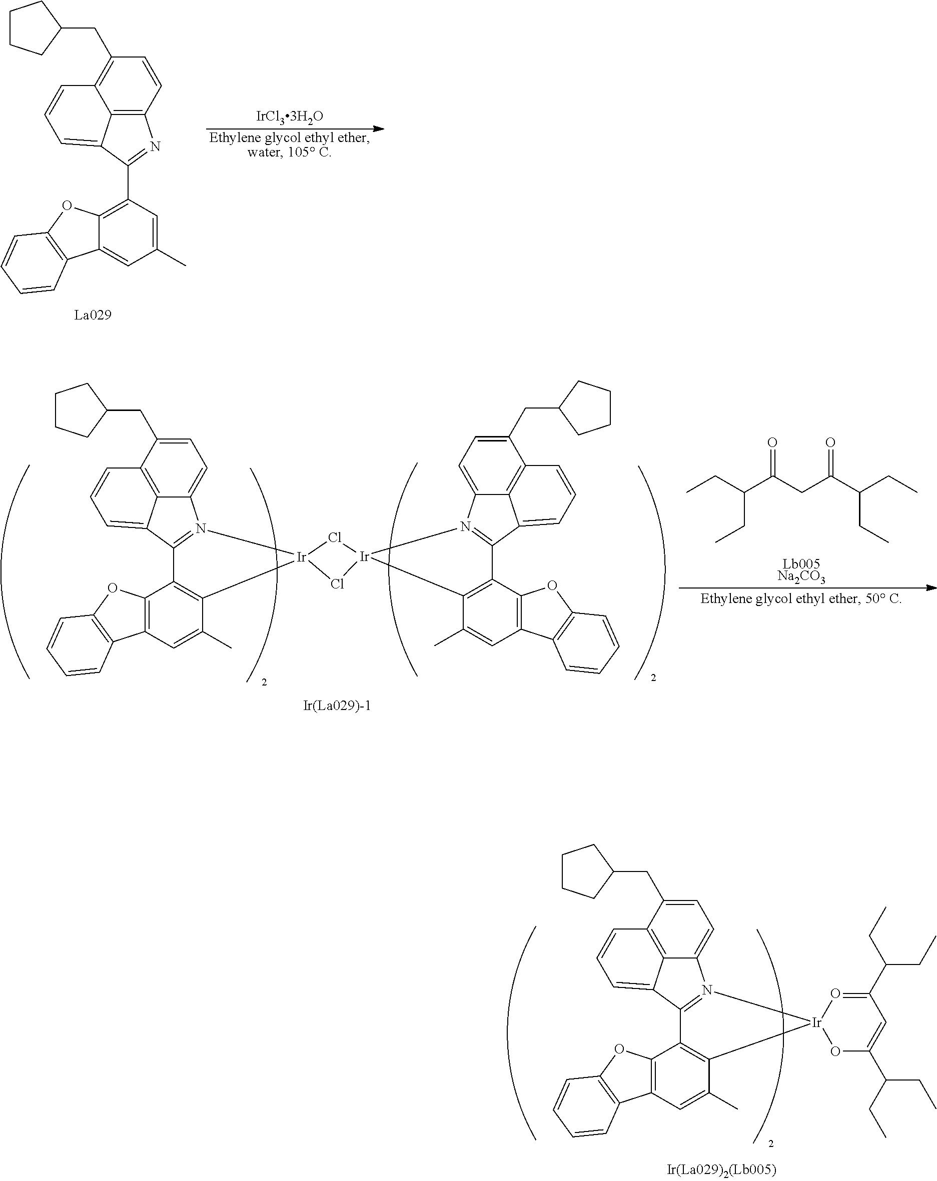

### Synthesis of a Compound Ir(La029)-1

With reference to synthesis and purification methods of the compound Ir(La003)-1, only the corresponding raw materials were required to be changed, and 9.31 g of a red solid compound Ir(La029)-1 with a yield of 68.18% was obtained. The obtained compound was directly used in the next step without purification.

### Synthesis of a Compound Ir(La029)₂(Lb005)

With reference to synthesis and purification methods of the compound Ir(La003)₂(Lb005), only the corresponding raw materials were required to be changed, and 2.52 g of a red solid compound Ir(La029)₂(Lb005) with a purity of 99.85% and a yield of 43.33% was obtained. 2.52 g of the crude product Ir(La029)₂(Lb005) was sublimated and purified to obtain 1.31 g of sublimated and purified Ir(La029)₂(Lb005) with a purity of 99.82% and a yield of 51.98%. The mass spectrum was 1233.54 (M+H).

¹H NMR (400 MHz, CDCl3) δ 7.99-7.97 (m, 2H), 7.88-7.86 (m, 2H), 7.81-7.80 (m, 4H), 7.55-7.53 (m, 2H), 7.49-7.47 (dd, J=7.4, 1.5 Hz, 2H), 7.45 (d, J=7.5 Hz, 2H), 7.41-7.37 (m, 2H), 7.33-7.29 (m, 2H), 6.91 (s, 2H), 4.74 (s, 1H), 2.92 (d, J=7.6 Hz, 4H), 2.34 (s, 6H), 1.91-1.90 (m, 4H), 1.77-1.75 (m, 4H), 1.68-1.63 (m, 8H), 1.33-1.28 (m, 4H), 1.26-1.21 (m, 4H), 1.03-1.00 (m, 4H), 0.94 (t, J=6.6 Hz, 12H).

### Synthesis of a Compound Ir(La029)₂(Lb009)

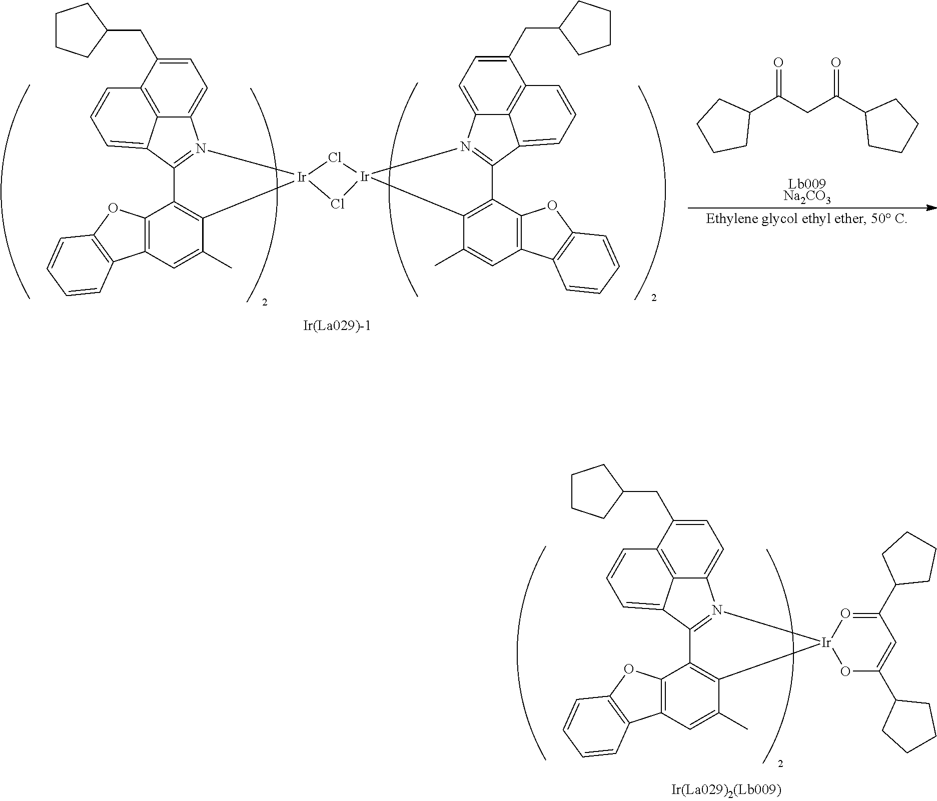

### Synthesis of a Compound Ir(La029)₂(Lb009)

With reference to synthesis and purification methods of the compound Ir(La003)₂(Lb005), only the corresponding raw materials were required to be changed, and 1.99 g of a red solid compound Ir(La029)₂(Lb009) with a purity of 99.90% and a yield of 45.25% was obtained. 1.99 g of the crude product Ir(La029)₂(Lb009) was sublimated and purified to obtain 1.20 g of sublimated and purified Ir(La029)₂(Lb009) with a purity of 99.88% and a yield of 60.30%. The mass spectrum was 1229.18 (M+H).

¹H NMR (400 MHz, CDCl3) δ 7.99 (m, 2H), 7.88-7.86 (m, 2H), 7.81-7.80 (m, 4H), 7.55-7.53 (m, 2H), 7.49-7.43 (m, 2H), 7.45 (d, J=7.5 Hz, 2H), 7.41-7.37 (m, 2H), 7.33-7.29 (m, 2H), 6.91 (s, 2H), 4.75 (s, 1H), 2.91 (dd, J=5.7, 2.2 Hz, 4H), 2.34 (s, 6H), 2.22-2.18 (m, 2H), 1.93-1.87 (m, 4H), 1.79-1.73 (m, 8H), 1.70-1.61 (m, 14H), 1.57-1.53 (m, 2H), 1.40-1.37 (m, 2H), 1.32-1.28 (m, 2H), 1.02-0.98 (m, 2H).

### Synthesis of a Ligand La039

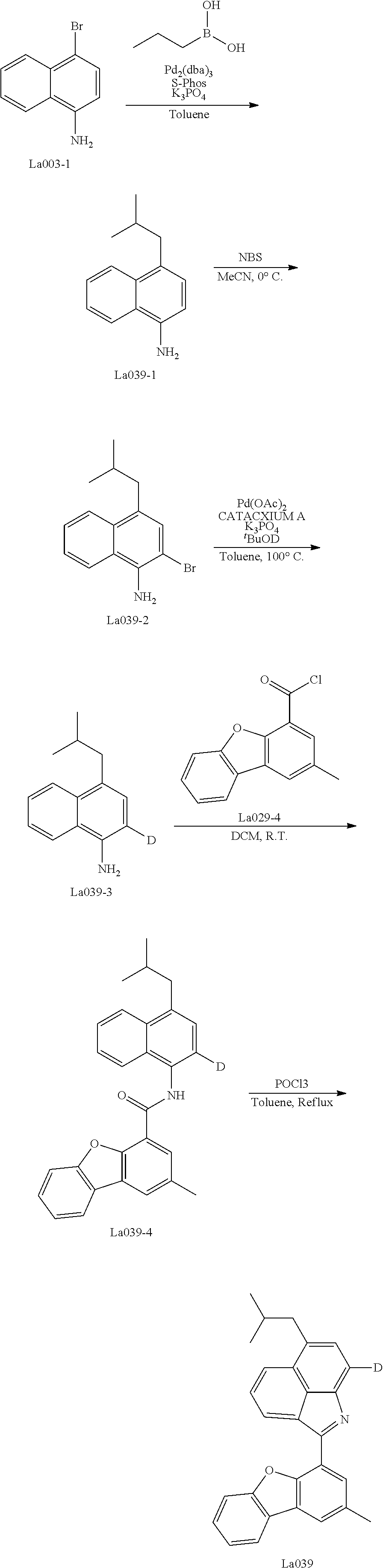

### Synthesis of a Compound La039-1

With reference to synthesis and purification methods of the compound La003, only the corresponding raw materials were required to be changed, and 35.42 g of a compound La039-1 with a purity of 99.80% and a yield of 68.44% was obtained. The mass spectrum was 200.06 (M+H).

### Synthesis of a Compound La039-2

The La039-1 (30.00 g, 150.53 mmol) and acetonitrile (300 ml) were added into a 1,000 ml three-necked round-bottomed flask, and vacuumization was performed for nitrogen replacement for three times. Then, the system was cooled to 0° C., N-bromosuccinimide (8.99 g, 158.06 mmol) was completely added in three batches within 15 minutes, and a resulting mixture was stirred at room temperature for 5 hours. According to monitoring by TLC (with a developing agent including ethyl acetate and petroleum ether at a ratio of 2:1), the raw material La039-1 was completely reacted.

Deionized water (100 ml) was added dropwise for quenching a reaction, ethyl acetate (800 ml) was added for extraction, and an organic phase was washed with deionized water (3*280 ml). Then, the organic phase was concentrated, followed by column chromatography with silica gel (200- to 300-mesh silica gel, with an eluting agent including ethyl acetate and petroleum ether at a ratio of 1:2) and concentration to obtain 37.69 g of a light yellow liquid compound La039-2 with a purity of 99.73% and a yield of 90.00%. The mass spectrum was: 278.16 (M+H).

### Synthesis of a Compound La039-3

The La039-2 (30.00 g, 107.84 mmol), palladium acetate (484.94 mg, 2.16 mmol), butyldi-1-adamantylphosphine (1.55 g, 4.32 mmol), dry potassium phosphate (45.78 g, 215.68 mmol), deuterated tert-butanol (16.20 g, 2. 215.68 mmol) and dry toluene (300 ml) were added into a 1,000 ml three-necked round-bottomed flask, vacuumization was performed for nitrogen replacement for three times, and the above compounds were heated to 100° C. for reflux overnight for 16 hours. According to monitoring by TLC (with a developing agent including ethyl acetate and petroleum ether at a ratio of 2:1), the raw material La039-2 was completely reacted.

Cooling was performed to room temperature, ethyl acetate (300 ml) was added, and deionized water was added for washing (3*200 ml). Then, an organic phase was concentrated, followed by column chromatography with silica gel (200- to 300-mesh silica gel, with an eluting agent including ethyl acetate and petroleum ether at a ratio of 1:2) and concentration to obtain 20.52 g of a light yellow liquid compound La039-3 with a purity of 99.85%, a deuterated ratio of 99% and a yield of 95.00%. The mass spectrum was: 201.26 (M+H).

### Synthesis of a Compound La039-4

With reference to synthesis and purification methods of the compound La003-3, only the corresponding raw materials were required to be changed, and 27.63 g of a compound La039-4 with a purity of 99.78% and a yield of 83.15% was obtained. The mass spectrum was 409.20 (M+H).

### Synthesis of a Compound La039

With reference to synthesis and purification methods of the compound La003-4, only the corresponding raw materials were required to be changed, and 18.76 g of a compound La039 with a purity of 99.73% and a yield of 70.26% was obtained. The mass spectrum was 391.28 (M+H).

### Synthesis of a Compound Ir(La039)₂(Lb005)

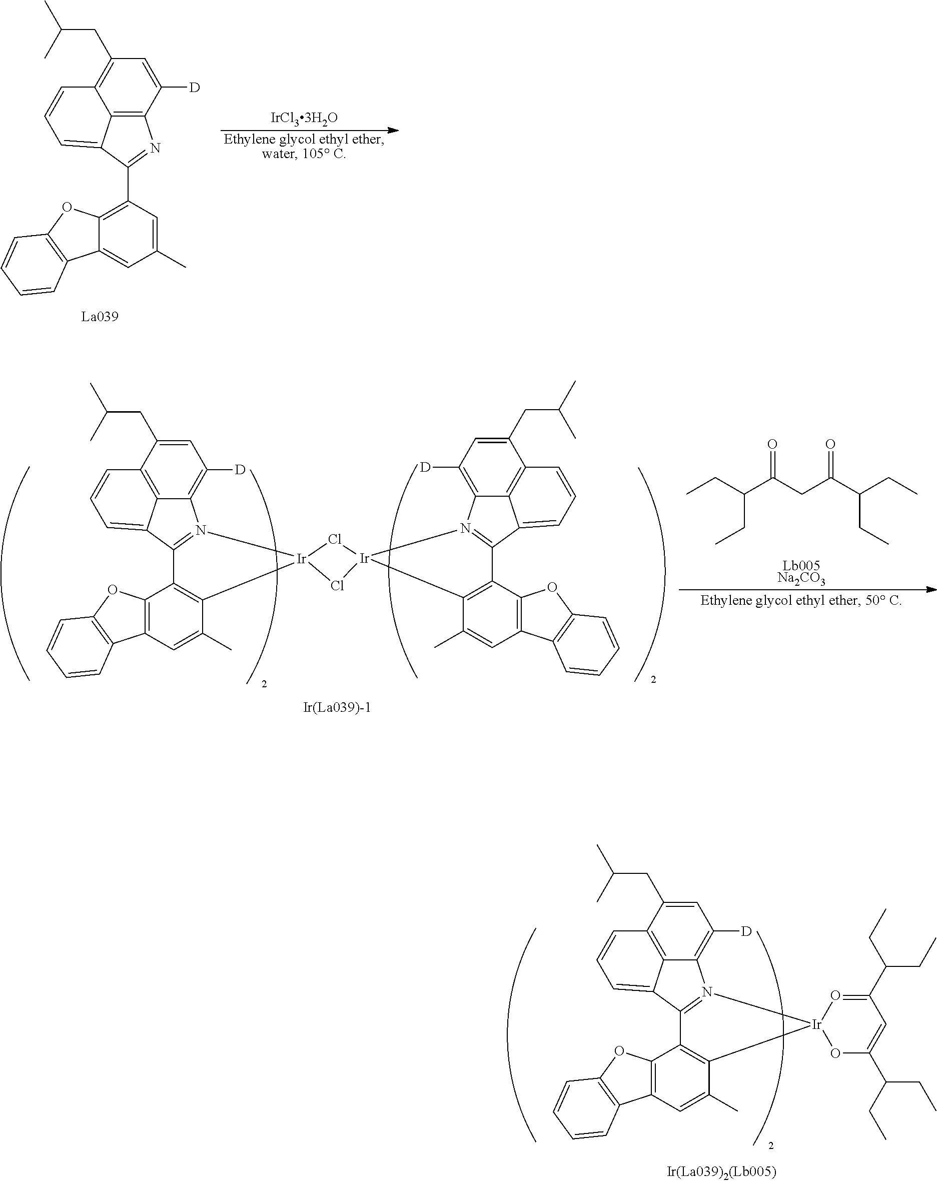

### Synthesis of a Compound Ir(La039)-1

With reference to synthesis and purification methods of the compound Ir(La003)-1, only the corresponding raw materials were required to be changed, and 7.89 g of a red solid compound Ir(La039)-1 with a yield of 68.78% was obtained. The obtained compound was directly used in the next step without purification.

### Synthesis of a Compound Ir(La039)₂(Lb005)

With reference to synthesis and purification methods of the compound Ir(La003)₂(Lb005), only the corresponding raw materials were required to be changed, and 1.56 g of a red solid compound Ir(La039)₂(Lb005) with a purity of 99.89% and a yield of 48.68% was obtained. 1.56 g of the crude product Ir(La039)₂(Lb005) was sublimated and purified to obtain 0.98 g of sublimated and purified Ir(La039)₂(Lb005) with a purity of 99.88%, a deuterated ratio of 99% and a yield of 62.82%. The mass spectrum was 1183.50 (M+H).

¹H NMR (400 MHz, CDCl3) δ 7.98 (m, 2H), 7.86-7.84 (m, 3H), 7.81-7.79 (m, 5H), 7.54-7.52 (m, 2H), 7.50-7.46 (m, 2H), 7.42-7.36 (m, 2H), 7.34-7.27 (m, 2H), 4.75 (s, 1H), 2.92 (d, J=5.7 Hz, 4H), 2.31 (s, 6H), 1.85-1.75 (m, 2H), 1.25-1.16 (m, 10H), 0.94 (t, J=6.7 Hz, 12H), 0.87 (d, J=6.3 Hz, 12H).

### Synthesis of a Ligand La051

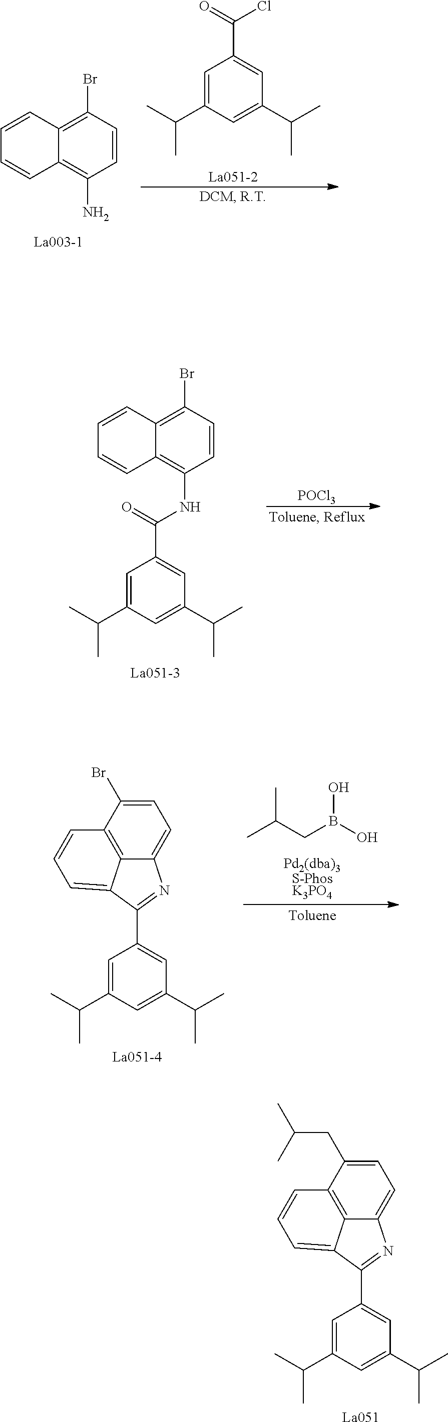

### Synthesis of a Compound La051-3

With reference to synthesis and purification methods of the compound La003-3, only the corresponding raw materials were required to be changed, and 40.33 g of a white solid compound La015 with a purity of 99.79% and a yield of 85.63% was obtained. The mass spectrum was 410.08 (M+H).

### Synthesis of a Compound La051-4

With reference to synthesis and purification methods of the compound La003-4, only the corresponding raw materials were required to be changed, and 26.09 g of a white solid compound La051-4 with a purity of 99.83% and a yield of 72.36% was obtained. The mass spectrum was 392.08 (M+H).

### Synthesis of a Compound La051

With reference to synthesis and purification methods of the compound La003, only the corresponding raw materials were required to be changed, and 19.05 g of a white sugar-like solid compound La051 with a purity of 99.78% and a yield of 70.01% was obtained. The mass spectrum was 370.28 (M+H).

### Synthesis of a Compound Ir(La051)₂(Lb005)

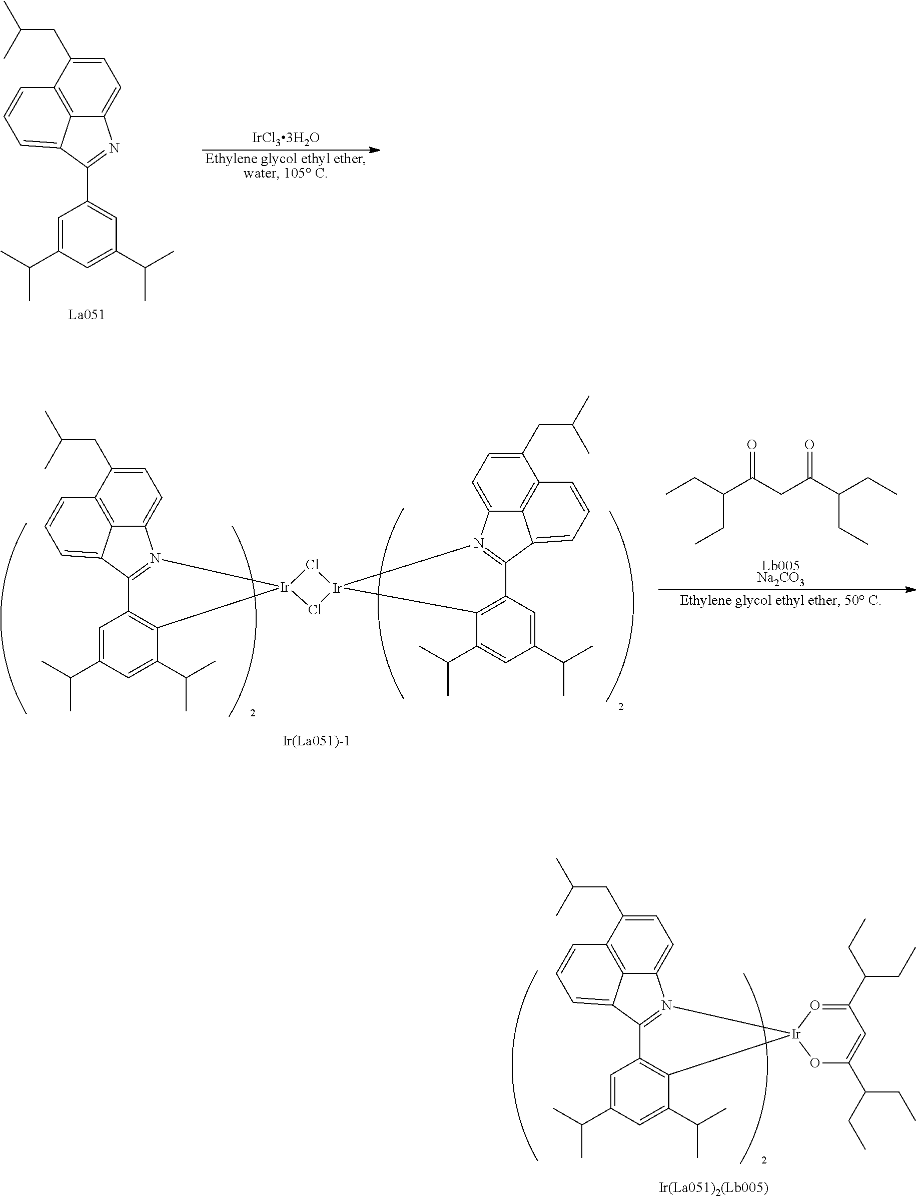

### Synthesis of a Compound Ir(La051)-1

With reference to synthesis and purification methods of the compound Ir(La003)-1, only the corresponding raw materials were required to be changed, and 10.87 g of a red solid compound Ir(La051)-1 with a yield of 68.45% was obtained. The obtained compound was directly used in the next step without purification.

### Synthesis of a Compound Ir(La051)₂(Lb005)

With reference to synthesis and purification methods of the compound Ir(La003)₂(Lb005), only the corresponding raw materials were required to be changed, and 3.50 g of a red solid compound Ir(La051)₂(Lb005) with a purity of 99.88% and a yield of 43.52% was obtained. 3.50 g of the crude product Ir(La051)₂(Lb005) was sublimated and purified to obtain 2.13 g of sublimated and purified Ir(La051)₂(Lb005) with a purity of 99.82% and a yield of 60.85%. The mass spectrum was 1141.64 (M+H).

¹H NMR (400 MHz, CDCl3) δ 7.88-7.84 (m, 4H), 7.81 (t, J=7.4 Hz, 2H), 7.49 (dd, J=7.4, 1.5 Hz, 2H), 7.45 (d, J=7.5 Hz, 2H), 7.24 (d, J=1.4 Hz, 2H), 6.91 (s, 2H), 4.74 (s, 1H), 2.92-2.84 (m, 8H), 1.81-1.79 (m, 2H), 1.31-1.30 (m, 4H), 1.25-1.16 (m, 28H), 1.03-1.00 (m, 2H), 0.94 (t, J=6.7 Hz, 12H), 0.87 (d, J=6.3 Hz, 12H).

### Synthesis of a Ligand La076

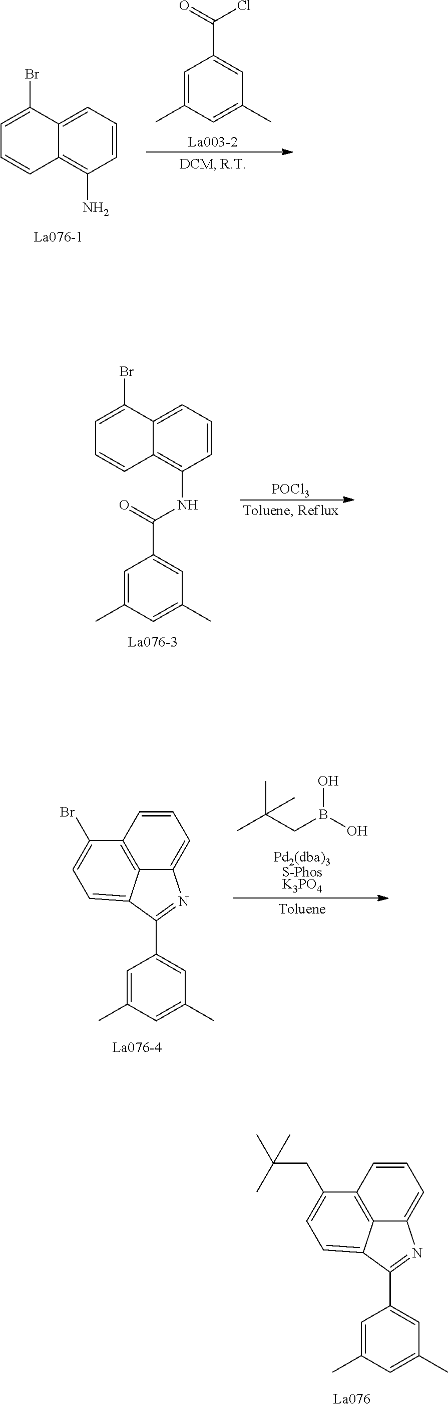

### Synthesis of a Compound La076-3

With reference to synthesis and purification methods of the compound La003-3, only the corresponding raw materials were required to be changed, and 25.10 g of a white solid compound La076-3 with a purity of 99.75% and a yield of 84.46% was obtained. The mass spectrum was 354.04 (M+H).

### Synthesis of a Compound La076-4

With reference to synthesis and purification methods of the compound La003-4, only the corresponding raw materials were required to be changed, and 16.80 g of a white solid compound La076-4 with a purity of 99.73% and a yield of 70.08% was obtained. The mass spectrum was 336.23 (M+H).

### Synthesis of a Compound La076

With reference to synthesis and purification methods of the compound La003, only the corresponding raw materials were required to be changed, and 8.92 g of a white sugar-like solid compound La076 with a purity of 99.81% and a yield of 68.61% was obtained. The mass spectrum was 328.24 (M+H).

### Synthesis of a Compound Ir(La076)₂(Lb005)

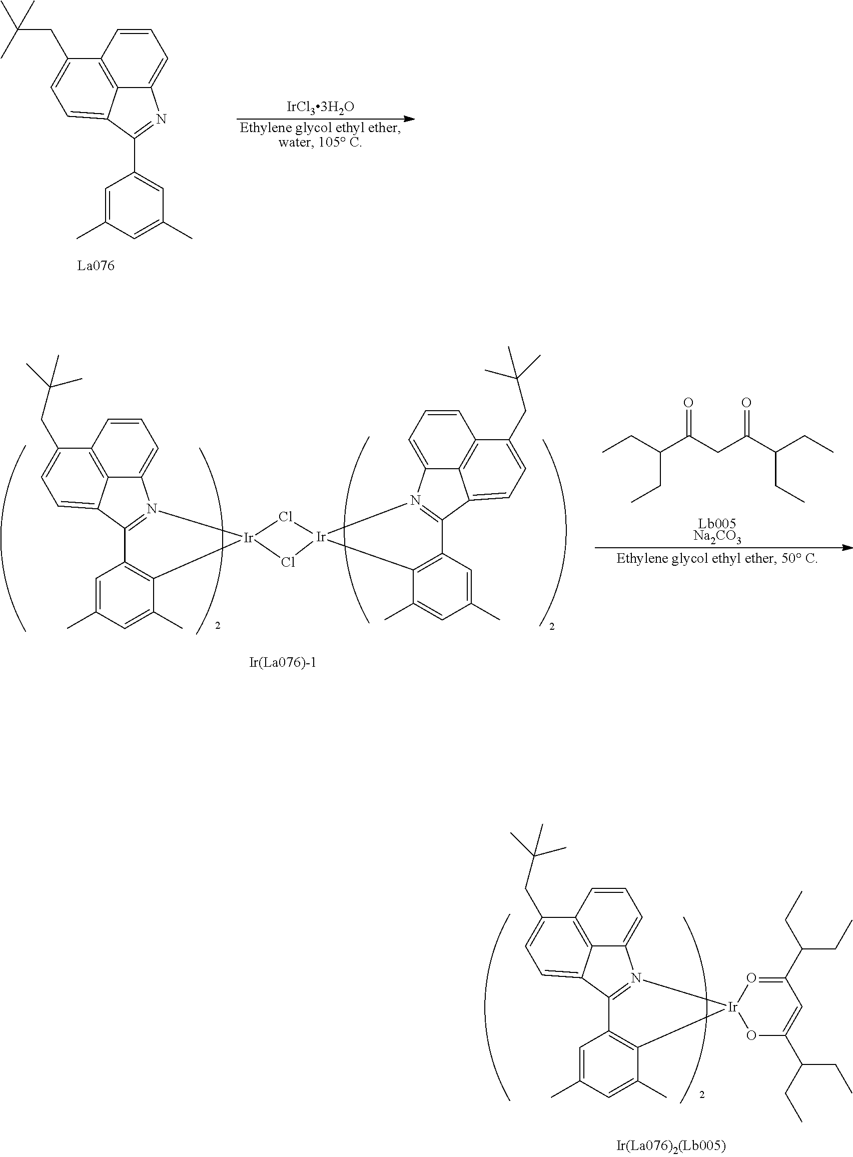

### Synthesis of a Compound Ir(La076)-1

With reference to synthesis and purification methods of the compound Ir(La003)-1, only the corresponding raw materials were required to be changed, and 7.56 g of a red solid compound Ir(La076)-1 with a yield of 65.63% was obtained. The obtained compound was directly used in the next step without purification.

### Synthesis of a Compound Ir(La076)₂(Lb005)

With reference to synthesis and purification methods of the compound Ir(La003)₂(Lb005), only the corresponding raw materials were required to be changed, and 1.79 g of a red solid compound Ir(La076)₂(Lb005) with a purity of 99.81% and a yield of 40.11% was obtained. 1.79 g of the crude product Ir(La076)₂(Lb005) was sublimated and purified to obtain 1.15 g of sublimated and purified Ir(La076)₂(Lb005) with a purity of 99.77% and a yield of 64.24%. The mass spectrum was 1057.53 (M+H).

¹H NMR (400 MHz, CDCl3) δ 7.68 (m, 2H), 7.61-7.59 (m, 2H), 7.44-7.39 (m, 4H), 7.08 (t, J=7.5 Hz, 2H), 6.99 (d, J=7.3 Hz, 2H), 6.92 (s, 2H), 4.73 (s, 1H), 3.09 (d, 4H), 2.34-2.31 (s, 12H), 1.34-1.22 (m, 8H), 1.03-1.00 (m, 2H), 0.94 (t, J=6.7 Hz, 12H), 0.85 (s, 18H).

### Synthesis of a Ligand La083

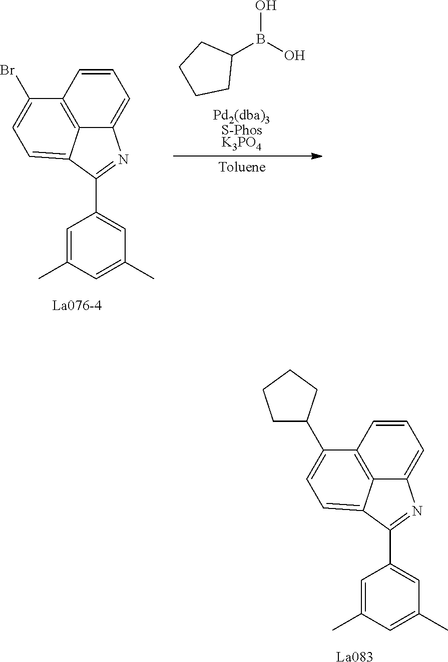

### Synthesis of a Compound La083

With reference to synthesis and purification methods of the compound La003, only the corresponding raw materials were required to be changed, and 7.66 g of a white sugar-like solid compound La083 with a purity of 99.78% and a yield of 63.31% was obtained. The mass spectrum was 326.23 (M+H).

### Synthesis of a Compound Ir(La083)₂(Lb005)

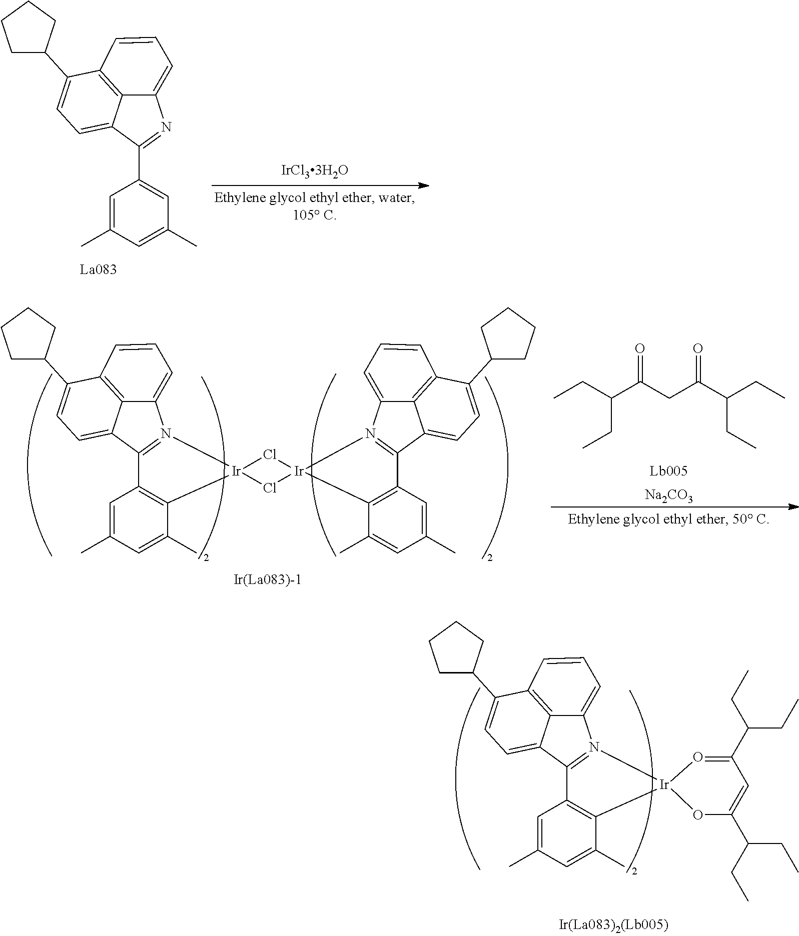

### Synthesis of a Compound Ir(La083)-1

With reference to synthesis and purification methods of the compound Ir(La003)-1, only the corresponding raw materials were required to be changed, and 6.83 g of a red solid compound Ir(La083)-1 with a yield of 75.63% was obtained. The obtained compound was directly used in the next step without purification.

### Synthesis of a Compound Ir(La083)₂(Lb005)

With reference to synthesis and purification methods of the compound Ir(La003)₂(Lb005), only the corresponding raw materials were required to be changed, and 1.38 g of a red solid compound Ir(La083)₂(Lb005) with a purity of 99.89% and a yield of 45.31% was obtained. 1.38 g of the crude product Ir(La083)₂(Lb005) was sublimated and purified to obtain 0.66 g of sublimated and purified Ir(La083)₂(Lb005) with a purity of 99.86% and a yield of 47.82%. The mass spectrum was 1053.28 (M+H).

¹H NMR (400 MHz, CDCl3) δ 7.68 (m, 2H), 7.62-7.58 (m, 2H), 7.45-7.39 (m, 4H), 7.08 (t, J=14.9 Hz, 2H), 6.98 (d, J=15.0 Hz, 2H), 6.92 (s, 2H), 4.74 (s, 1H), 2.34-2.31 (s, 12H), 1.92-1.63 (m, 16H), 1.33-1.19 (m, 12H), 1.08-0.89 (m, 12H).

### Synthesis of a Ligand La091

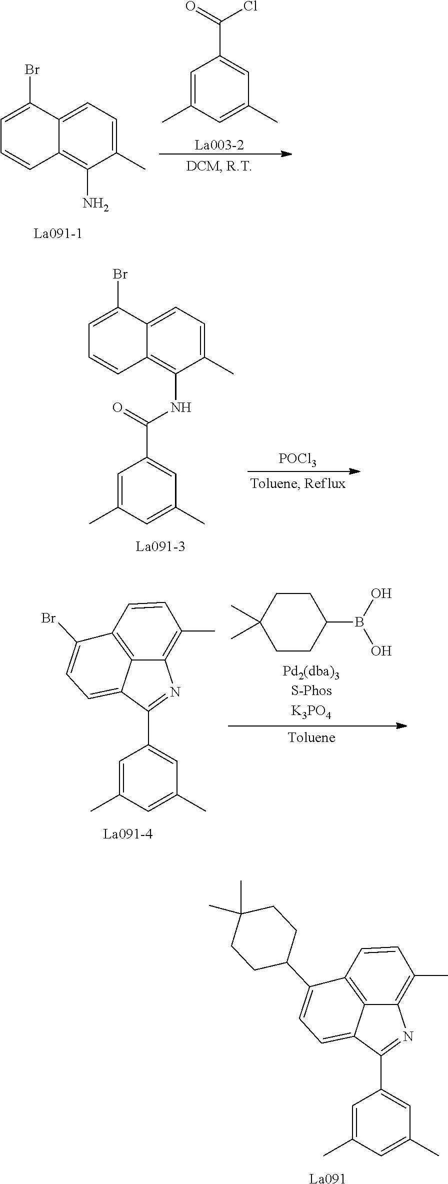

### Synthesis of a Compound La091-3

With reference to synthesis and purification methods of the compound La003-3, only the corresponding raw materials were required to be changed, and 25.16 g of a white solid compound La091-3 with a purity of 99.75% and a yield of 86.74% was obtained. The mass spectrum was 368.08 (M+H).

### Synthesis of a Compound La091-4

With reference to synthesis and purification methods of the compound La003-4, only the corresponding raw materials were required to be changed, and 17.63 g of a white solid compound La091-4 with a purity of 99.80% and a yield of 70.55% was obtained. The mass spectrum was 350.16 (M+H).

### Synthesis of a Compound La091

With reference to synthesis and purification methods of the compound La003, only the corresponding raw materials were required to be changed, and 12.00 g of a white sugar-like solid compound La091 with a purity of 99.78% and a yield of 68.77% was obtained. The mass spectrum was 382.26 (M+H).

### Synthesis of a Compound Ir(La091)₂(Lb005)

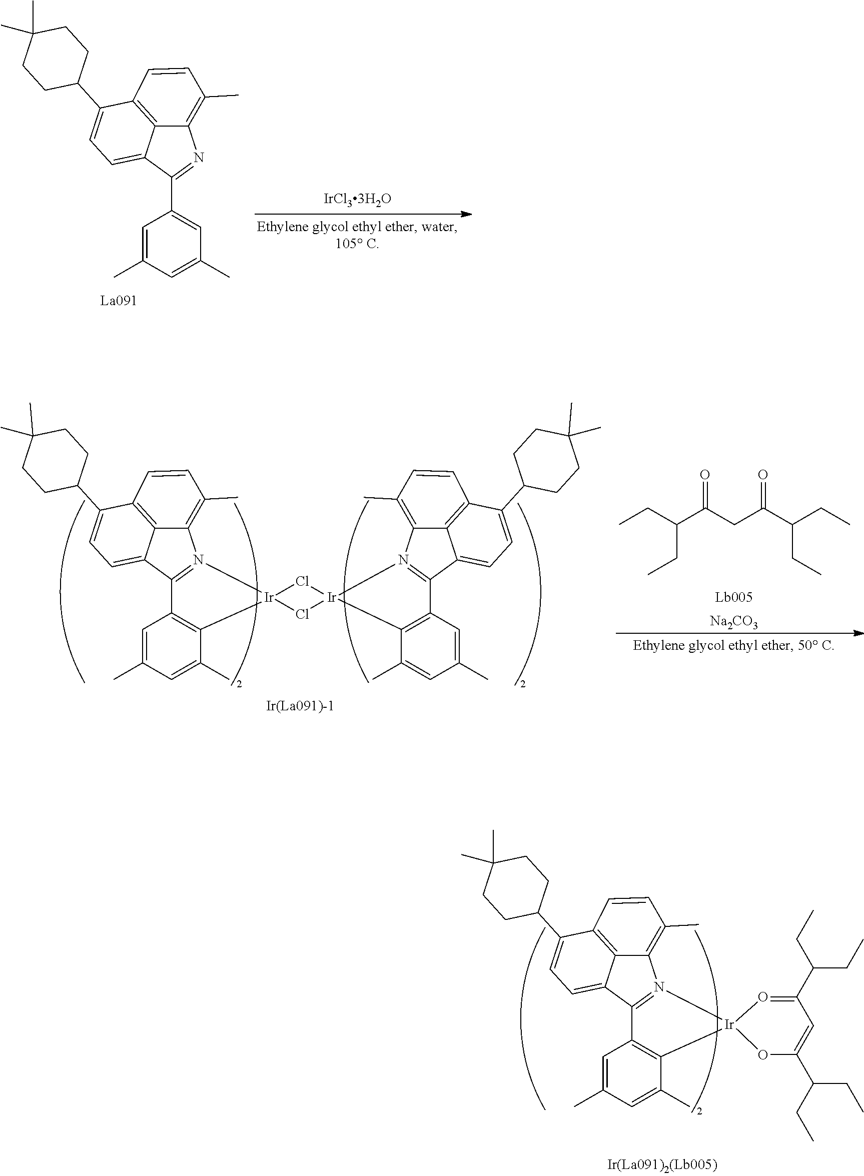

### Synthesis of a Compound Ir(La091)-1

With reference to synthesis and purification methods of the compound Ir(La003)-1, only the corresponding raw materials were required to be changed, and 8.08 g of a red solid compound Ir(La091)-1 with a yield of 78.03% was obtained. The obtained compound was directly used in the next step without purification.

### Synthesis of a Compound Ir(La091)₂(Lb005)

With reference to synthesis and purification methods of the compound Ir(La003)₂(Lb005), only the corresponding raw materials were required to be changed, and 2.31 g of a red solid compound Ir(La091)₂(Lb005) with a purity of 99.87% and a yield of 45.55% was obtained. 2.31 g of the crude product Ir(La091)₂(Lb005) was sublimated and purified to obtain 1.11 g of sublimated and purified Ir(La091)₂(Lb005) with a purity of 99.82% and a yield of 48.05%. The mass spectrum was 1165.62 (M+H).

¹H NMR (400 MHz, CDCl3) δ 7.68 (m, 2H), 7.40 (d, J=7.5 Hz, 2H), 7.26 (d, J=7.5 Hz, 2H), 7.06 (d, J=7.5 Hz, 2H), 6.99 (d, J=7.3 Hz, 2H), 6.92 (s, 2H), 4.75 (s, 1H), 2.70 (s, 6H), 2.34-2.31 (s, 12H), 1.33-1.23 (m, 16H), 1.12-1.10 (m, 5H), 1.03-1.00 (m, 7H), 0.94 (t, J=6.6 Hz, 12H), 0.87 (s, 12H).

### Synthesis of a Ligand La111

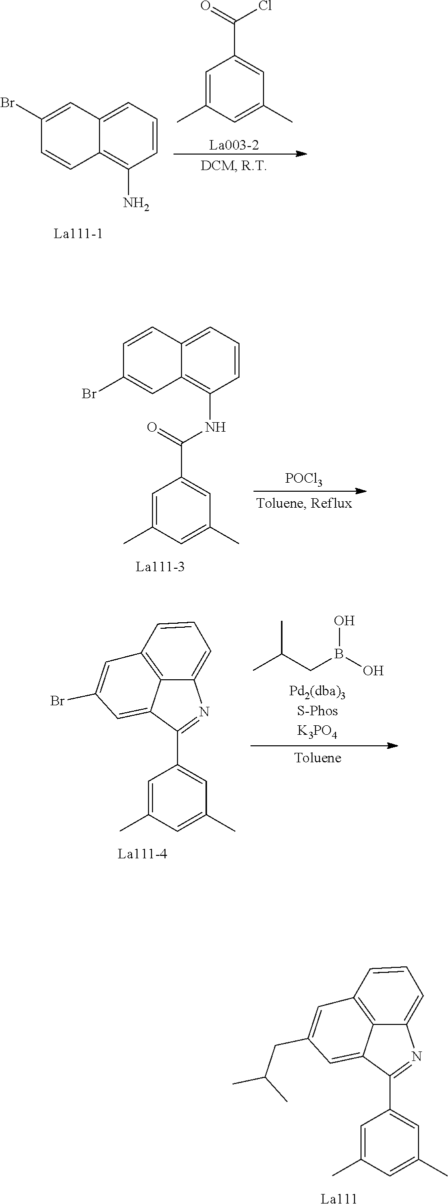

### Synthesis of a Compound La111-3

With reference to synthesis and purification methods of the compound La003-3, only the corresponding raw materials were required to be changed, and 24.38 g of a white solid compound La111-3 with a purity of 99.71% and a yield of 81.22% was obtained. The mass spectrum was 354.26 (M+H).

### Synthesis of a Compound La111-4

With reference to synthesis and purification methods of the compound La003-4, only the corresponding raw materials were required to be changed, and 15.00 g of a white solid compound La111-4 with a purity of 99.73% and a yield of 72.63% was obtained. The mass spectrum was 336.04 (M+H).

### Synthesis of a Compound La111

With reference to synthesis and purification methods of the compound La003, only the corresponding raw materials were required to be changed, and 10.23 g of a white sugar-like solid compound La11 with a purity of 99.78% and a yield of 67.43% was obtained. The mass spectrum was 314.12 (M+H).

### Synthesis of a Compound Ir(La111)₂(Lb005)

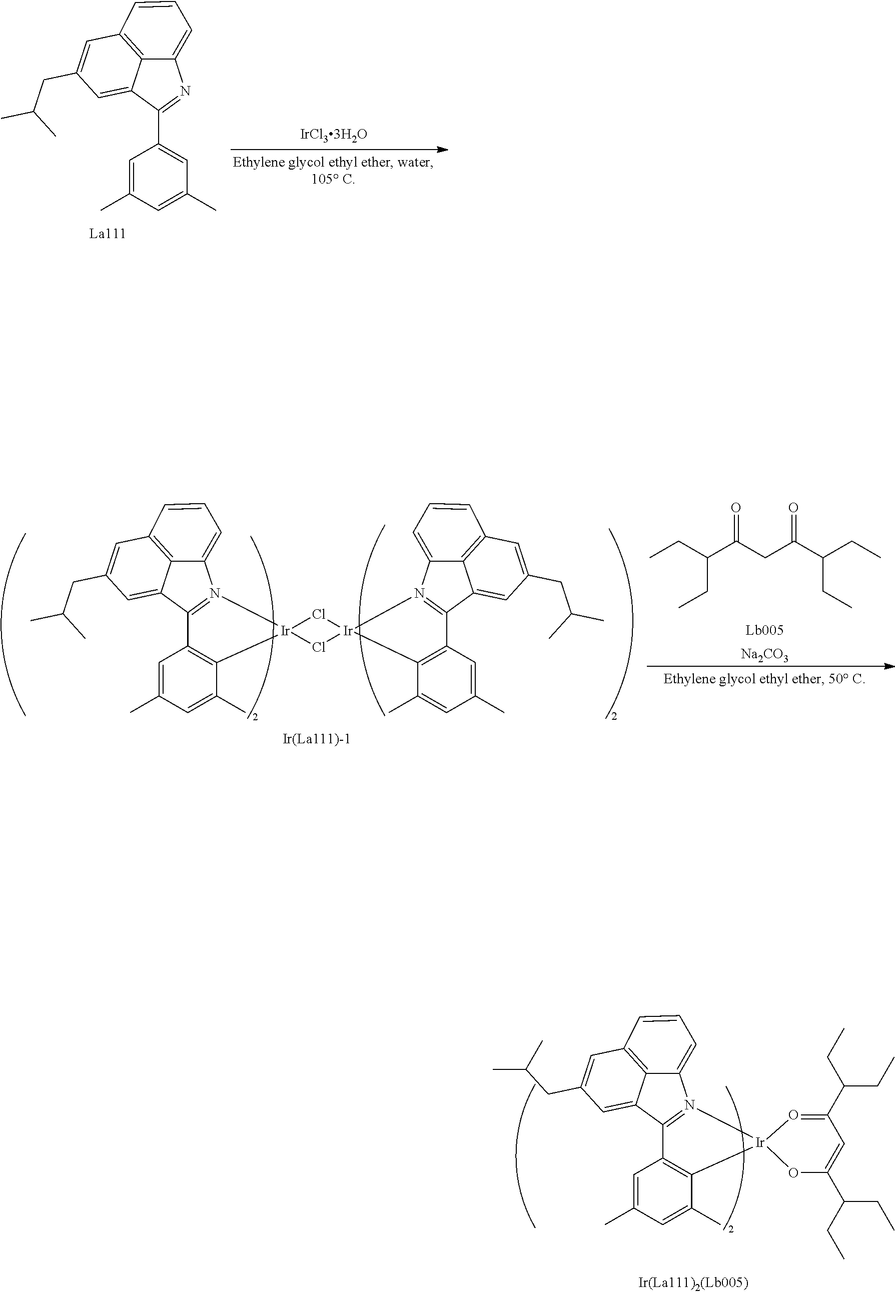

### Synthesis of a Compound Ir(La111)-1

With reference to synthesis and purification methods of the compound Ir(La003)-1, only the corresponding raw materials were required to be changed, and 7.06 g of a red solid compound Ir(La111)-1 with a yield of 75.38% was obtained. The obtained compound was directly used in the next step without purification.

### Synthesis of a Compound Ir(La111)₂(Lb005)

With reference to synthesis and purification methods of the compound Ir(La003)₂(Lb005), only the corresponding raw materials were required to be changed, and 1.87 g of a red solid compound Ir(La111)₂(Lb005) with a purity of 99.89% and a yield of 48.52% was obtained. 1.87 g of the crude product Ir(La111)₂(Lb005) was sublimated and purified to obtain 1.01 g of sublimated and purified Ir(La111)₂(Lb005) with a purity of 99.86% and a yield of 54.01%. The mass spectrum was 1029.38 (M+H).

¹H NMR (400 MHz, CDCl3) δ 7.68 (s, 2H), 7.76-7.60 (m, 4H), 7.48-7.43 (m, 4H), 7.08 (m, 2H), 6.92 (s, 2H), 4.75 (s, 1H), 2.54-2.53 (dd, J=10.6, 3.9 Hz, 4H), 2.34-2.31 (s, 12H), 1.85-1.77 (m, 2H), 1.34-1.19 (m, 10H), 1.16-0.78 (m, 24H).

### Synthesis of a Ligand La135

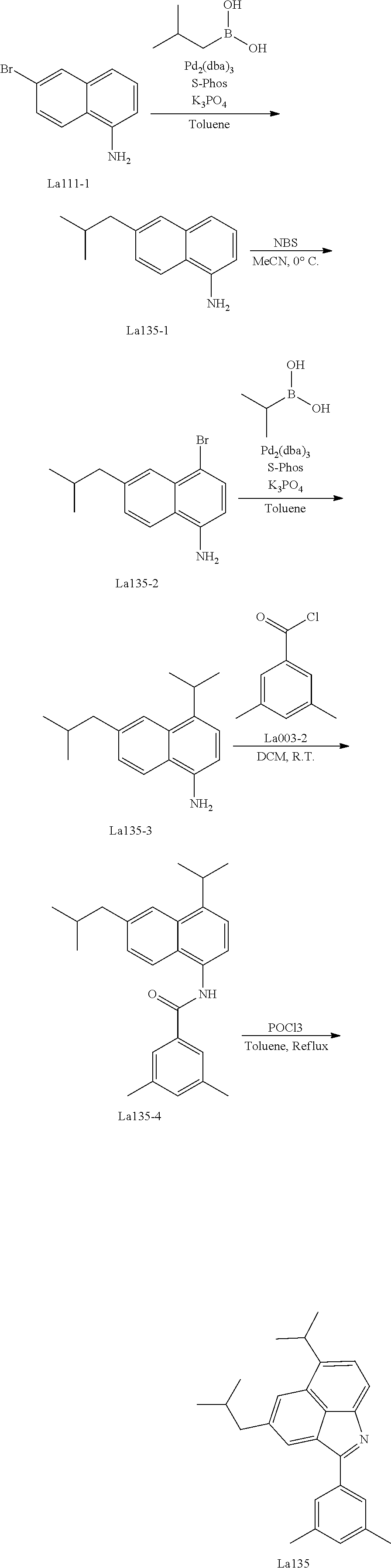

### Synthesis of a Compound La135-1

With reference to synthesis and purification methods of the compound La003, only the corresponding raw materials were required to be changed, and 38.96 g of a compound La135-1 with a purity of 99.68% and a yield of 60.41% was obtained. The mass spectrum was 200.04 (M+H).

### Synthesis of a Compound La135-2

With reference to synthesis and purification methods of the compound La039-2, only the corresponding raw materials were required to be changed, and 32.77 g of a compound La135-2 with a purity of 99.71% and a yield of 85.55% was obtained. The mass spectrum was 278.06 (M+H).

### Synthesis of a Compound La135-3

With reference to synthesis and purification methods of the compound La003, only the corresponding raw materials were required to be changed, and 16.21 g of a compound La135-3 with a purity of 99.75% and a yield of 58.43% was obtained. The mass spectrum was 242.48 (M+H).

### Synthesis of a Compound La135-4

With reference to synthesis and purification methods of the compound La003-3, only the corresponding raw materials were required to be changed, and 22.14 g of a compound La135-4 with a purity of 99.68% and a yield of 86.15% was obtained. The mass spectrum was 374.20 (M+H).

### Synthesis of a Compound La135

With reference to synthesis and purification methods of the compound La003-4, only the corresponding raw materials were required to be changed, and 13.51 g of a compound La135 with a purity of 99.68% and a yield of 74.61% was obtained. The mass spectrum was 356.16 (M+H).

### Synthesis of a Compound Ir(La135)₂(Lb005)

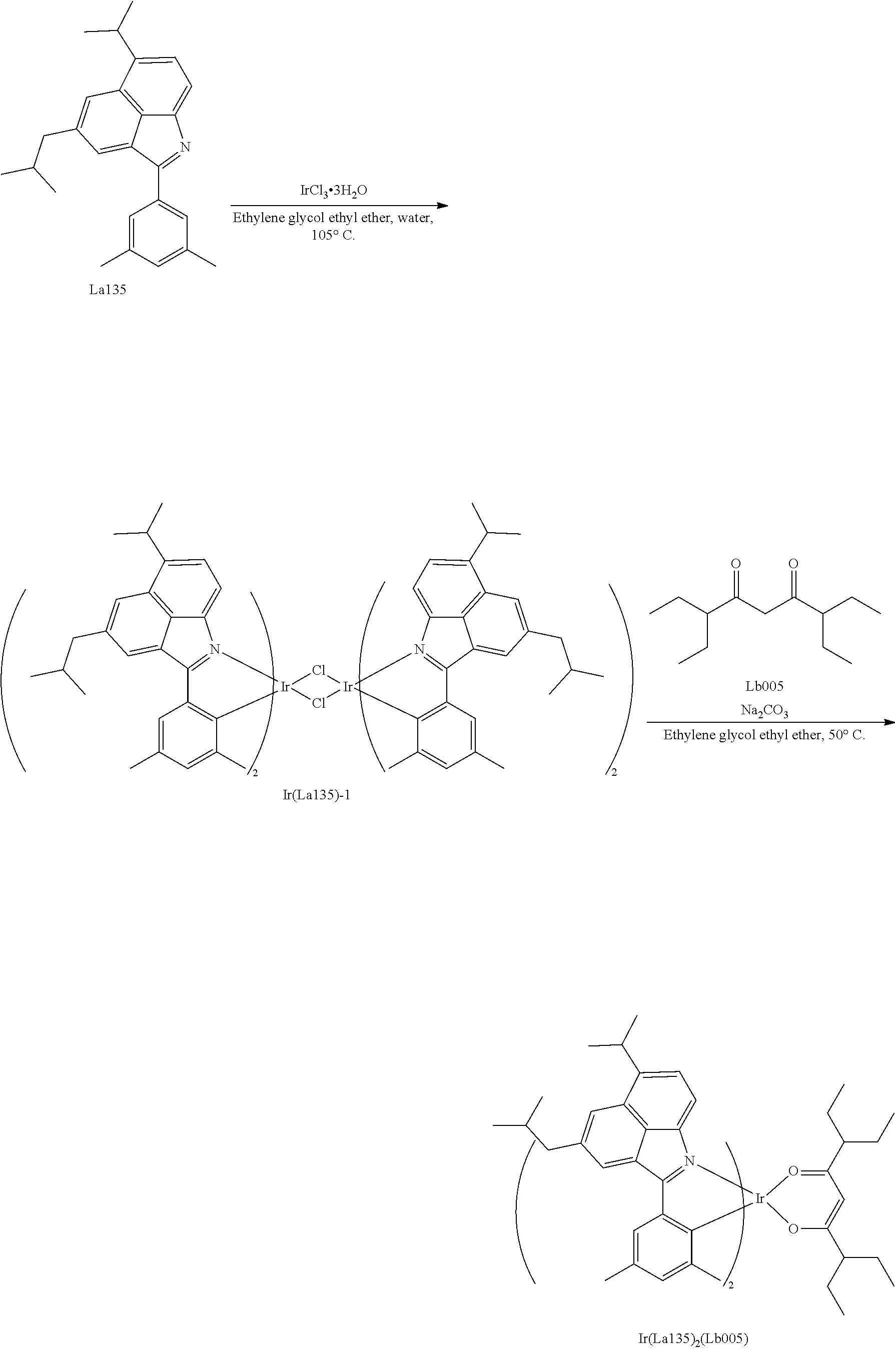

### Synthesis of a Compound Ir(La135)-1

With reference to synthesis and purification methods of the compound Ir(La003)-1, only the corresponding raw materials were required to be changed, and 9.89 g of a red solid compound Ir(La135)-1 with a yield of 74.01% was obtained. The obtained compound was directly used in the next step without purification.

### Synthesis of a Compound Ir(La135)₂(Lb005)

With reference to synthesis and purification methods of the compound Ir(La003)₂(Lb005), only the corresponding raw materials were required to be changed, and 3.55 g of a red solid compound Ir(La135)₂(Lb005) with a purity of 99.87% and a yield of 49.33% was obtained. 3.55 g of the crude product Ir(La135)₂(Lb005) was sublimated and purified to obtain 2.13 g of sublimated and purified Ir(La135)₂(Lb005) with a purity of 99.86% and a yield of 60.00%. The mass spectrum was 1113.28 (M+H).

¹H NMR (400 MHz, CDCl3) δ 7.97 (s, 2H), 7.83 (m, 2H), 7.68 (d, J=1.4 Hz, 2H), 7.45 (d, J=7.5 Hz, 2H), 6.92-6.89 (m, 4H), 4.73 (s, 1H), 2.90-2.85 (m, 2H), 2.55 (d, J=7.4 Hz, 4H), 2.34 (s, 12H), 1.85-1.79 (m, 2H), 1.32-1.21 (m, 20H), 1.03-1.00 (m, 2H), 0.94 (t, J=6.7 Hz, 12H), 0.87 (d, J=6.3 Hz, 12H).

### Synthesis of a Ligand La155

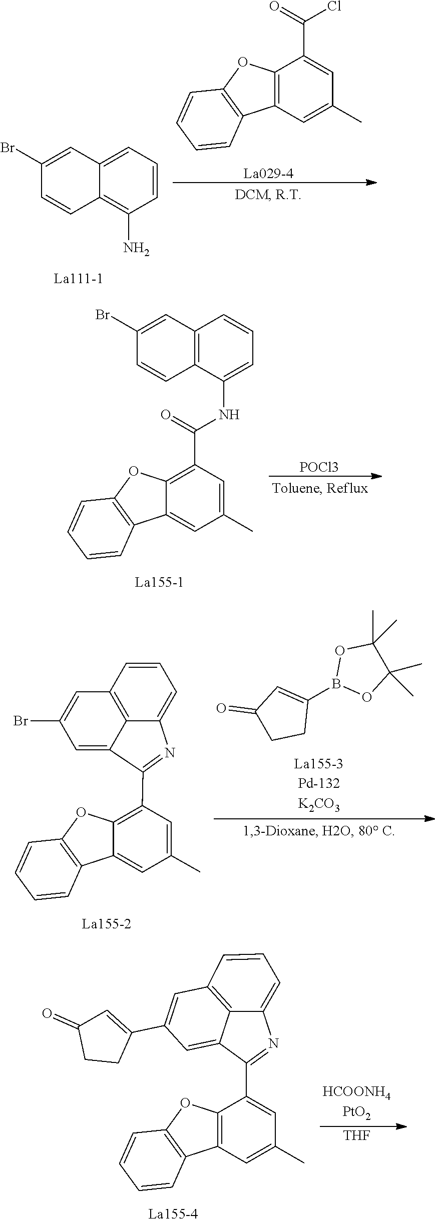

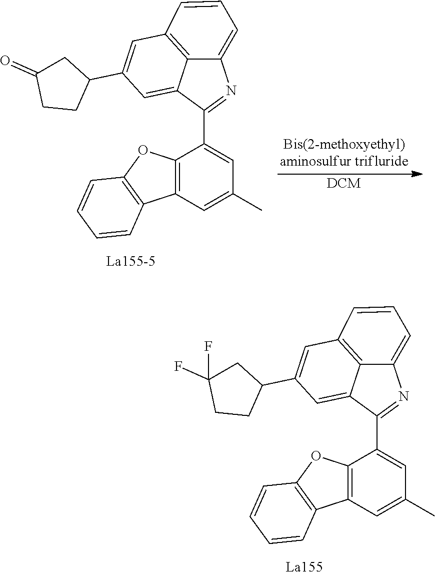

### Synthesis of a Compound La155-1

With reference to synthesis and purification methods of the compound La003-3, only the corresponding raw materials were required to be changed, and 30.56 g of a compound La155-1 with a purity of 99.75% and a yield of 85.66% was obtained. The mass spectrum was 430.02 (M+H).

### Synthesis of a Compound La155-2

With reference to synthesis and purification methods of the compound La003-4, only the corresponding raw materials were required to be changed, and 18.35 g of a compound La155-2 with a purity of 99.78% and a yield of 73.43% was obtained. The mass spectrum was 412.02 (M+H).

### Synthesis of a Compound La155-4

The La155-2 (25.03 g, 60.71 mmol), La115-3 (15.16 g, 72.85 mmol), bis(di-tert-butyl(4-dimethylaminophenyl)phosphine)dichloropalladium (859.73 mg, 1.21 mmol), potassium carbonate (16.78 g, 121.42 mmol), 1,4-dioxane (300 ml) and deionized water (100 ml) were added into a 1,000 ml one-necked round-bottomed flask, vacuumization was performed for nitrogen replacement for 3 times, and stirring was performed at 80° C. for 2 hours. According to monitoring by TLC (with a developing agent including ethyl acetate and petroleum ether at a ratio of 1:5), the raw material La115-2 was completely reacted.

Cooling was performed to room temperature, concentration was performed to remove a solvent, dichloromethane (500 ml) was added, and deionized water was added for washing (3*150 ml). Then, liquid separation was performed, and an organic phase was concentrated, followed by column chromatography with silica gel (200- to 300-mesh silica gel, with an eluting agent including ethyl acetate and petroleum ether at a ratio of 1:10) and concentration to obtain 21.34 g of a white solid compound La115-4 with a purity of 99.62% and a yield of 85.02%. The mass spectrum was: 414.16 (M+H).

### Synthesis of a Compound La115-5

The La115-4 (15.03 g, 36.35 mmol), ammonium formate (22.92 g, 363.50 mmol), platinum dioxide (825.45 mg, 3.64 mmol) and tetrahydrofuran (150 ml) were added into a 500 ml three-necked round-bottomed flask, vacuumization was performed for nitrogen replacement for 3 times, and the above compounds were stirred at 65° C. for 6 hours. According to monitoring by TLC, the raw material La115-4 was completely reacted.

Cooling was performed to room temperature, concentration was performed to remove a solvent, dichloromethane (500 ml) was added, and deionized water was added for washing (3*150 ml). Then, liquid separation was performed, and an organic phase was concentrated, followed by column chromatography with silica gel (200- to 300-mesh silica gel, with an eluting agent including ethyl acetate and petroleum ether at a ratio of 1:12) and concentration to obtain 10.56 g of a white sugar-like solid compound La115-5 with a purity of 99.63% and a yield of 72.36%. The mass spectrum was: 416.26 (M+H).

### Synthesis of a Compound La155

The La115-5 (21.65 g, 52.15 mmol) and dichloromethane (200 ml) were added into a 500 ml three-necked round-bottomed flask, vacuumization was performed for nitrogen replacement for 3 times, bis(2-methoxyethyl)aminosulfur trifluoride (23.07 g, 104.30 mmol) was added dropwise under stirring at room temperature, and stirring was performed overnight at room temperature. According to monitoring by TLC (with a developing agent including ethyl acetate and petroleum ether at a ratio of 1:10), the raw material La115-5 was completely reacted.

A reaction solution was added dropwise into a saturated sodium bicarbonate aqueous solution for quenching a reaction, the pH value of the system was adjusted to 8, concentration was performed to remove tetrahydrofuran, dichloromethane (500 ml) was added for liquid separation, and deionized water was added for washing (3*150 ml). Then, liquid separation was performed, and an organic phase was concentrated, followed by column chromatography with silica gel (200- to 300-mesh silica gel, with an eluting agent including ethyl acetate and petroleum ether at a ratio of 1:20) and concentration to obtain 15.60 g of a white sugar-like solid compound La155 with a purity of 99.73% and a yield of 68.45%. The mass spectrum was: 438.20 (M+H).

### Synthesis of a Compound Ir(La155)₂(Lb005)

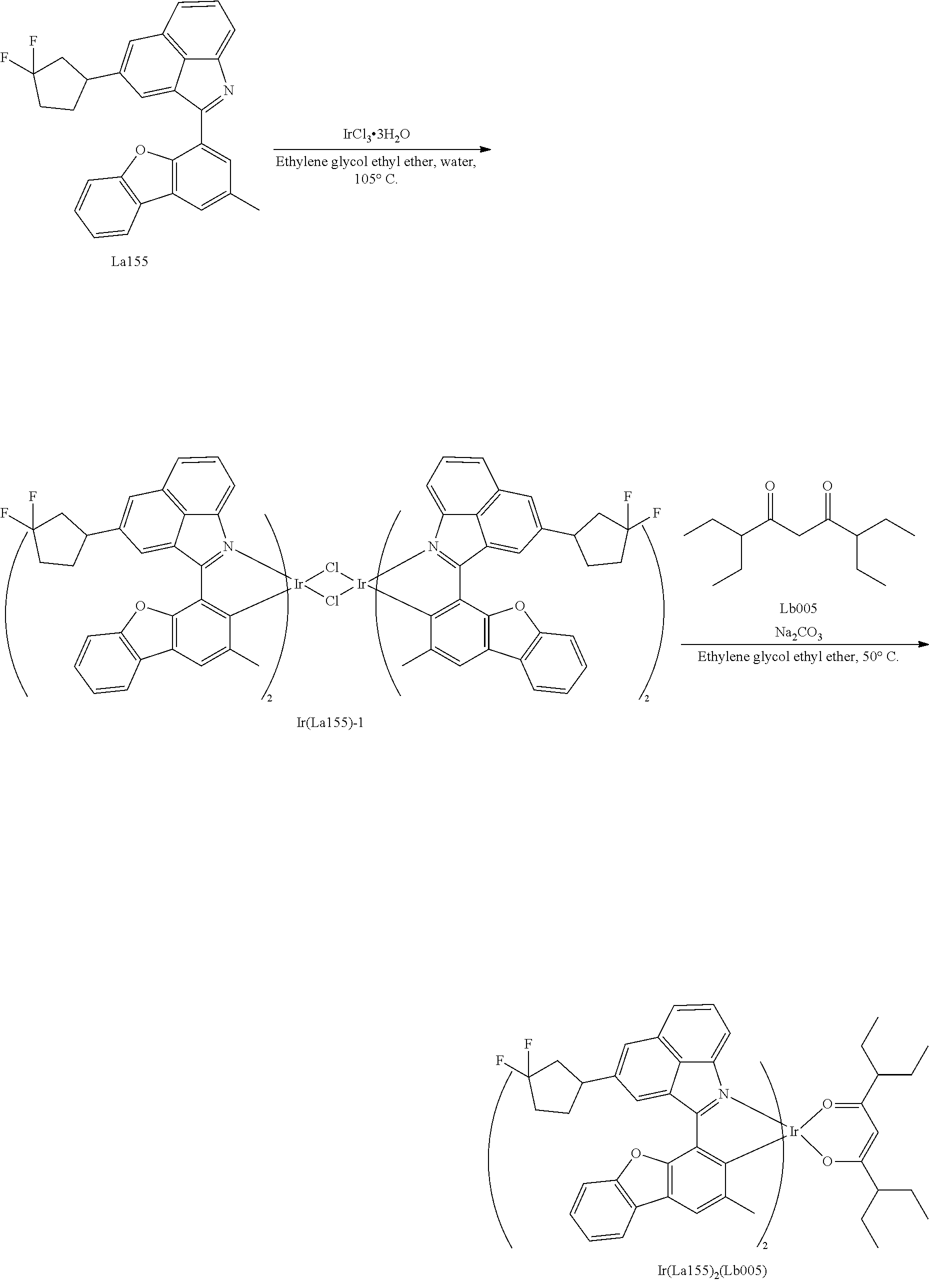

### Synthesis of a Compound Ir(La155)-1

With reference to synthesis and purification methods of the compound Ir(La003)-1, only the corresponding raw materials were required to be changed, and 8.69 g of a red solid compound Ir(La155)-1 with a yield of 75.46% was obtained. The obtained compound was directly used in the next step without purification.

### Synthesis of a Compound Ir(La155)₂(Lb005)

With reference to synthesis and purification methods of the compound Ir(La003)₂(Lb005), only the corresponding raw materials were required to be changed, and 2.73 g of a red solid compound Ir(La155)₂(Lb005) with a purity of 99.86% and a yield of 41.22% was obtained. 2.73 g of the crude product Ir(La155)₂(Lb005) was sublimated and purified to obtain 1.19 g of sublimated and purified Ir(La155)₂(Lb005) with a purity of 99.86% and a yield of 43.58%. The mass spectrum was 1277.46 (M+H).

¹H NMR (400 MHz, CDCl3) δ 7.97 (m, 2H), 7.82 (m, 2H), 7.68 (s, 2H), 7.61-7.59 (m, 4H), 7.44-7.42 (m, 2H), 7.39-7.32 (m, 2H), 7.30-7.26 (m, 4H), 7.10 (m, 2H), 4.73 (s, 1H), 2.32 (s, 6H), 1.95-1.60 (m, 10H), 1.34-1.28 (m, 6H), 1.11-0.97 (m, 8H), 0.97-0.89 (m, 12H).

### Synthesis of a Ligand La172

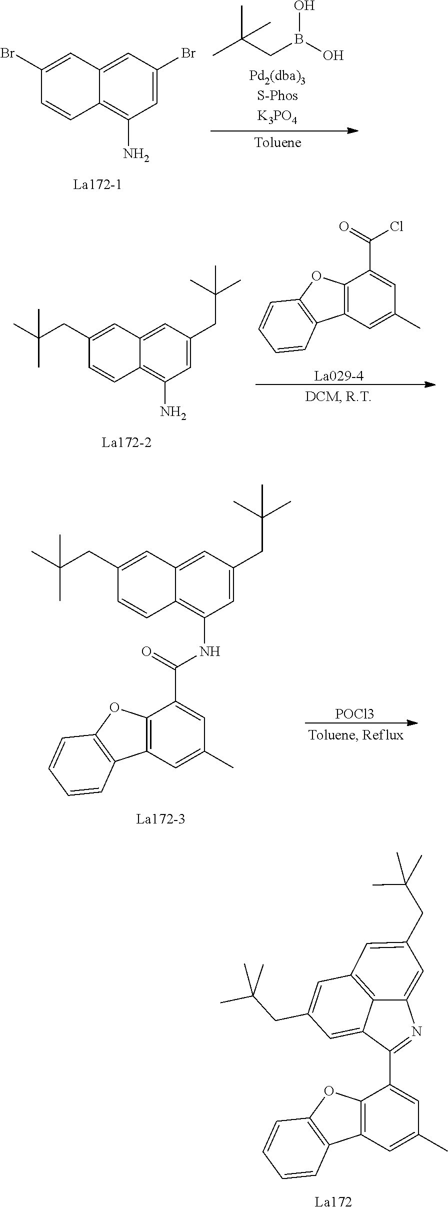

### Synthesis of a Compound La172-2

With reference to synthesis and purification methods of the compound La003, only the corresponding raw materials were required to be changed, and 27.47 g of a compound La172-2 with a purity of 99.63% and a yield of 55.45% was obtained. The mass spectrum was 284.24 (M+H).

### Synthesis of a Compound La172-3

With reference to synthesis and purification methods of the compound La003-3, only the corresponding raw materials were required to be changed, and 20.05 g of a compound La172-3 with a purity of 99.70% and a yield of 75.65% was obtained. The mass spectrum was 464.26 (M+H).

### Synthesis of a Compound La172

With reference to synthesis and purification methods of the compound La003-4, only the corresponding raw materials were required to be changed, and 15.36 g of a compound La172-3 with a purity of 99.76% and a yield of 71.11% was obtained. The mass spectrum was 474.18 (M+H).

### Synthesis of a Compound Ir(La172)₂(Lb005)

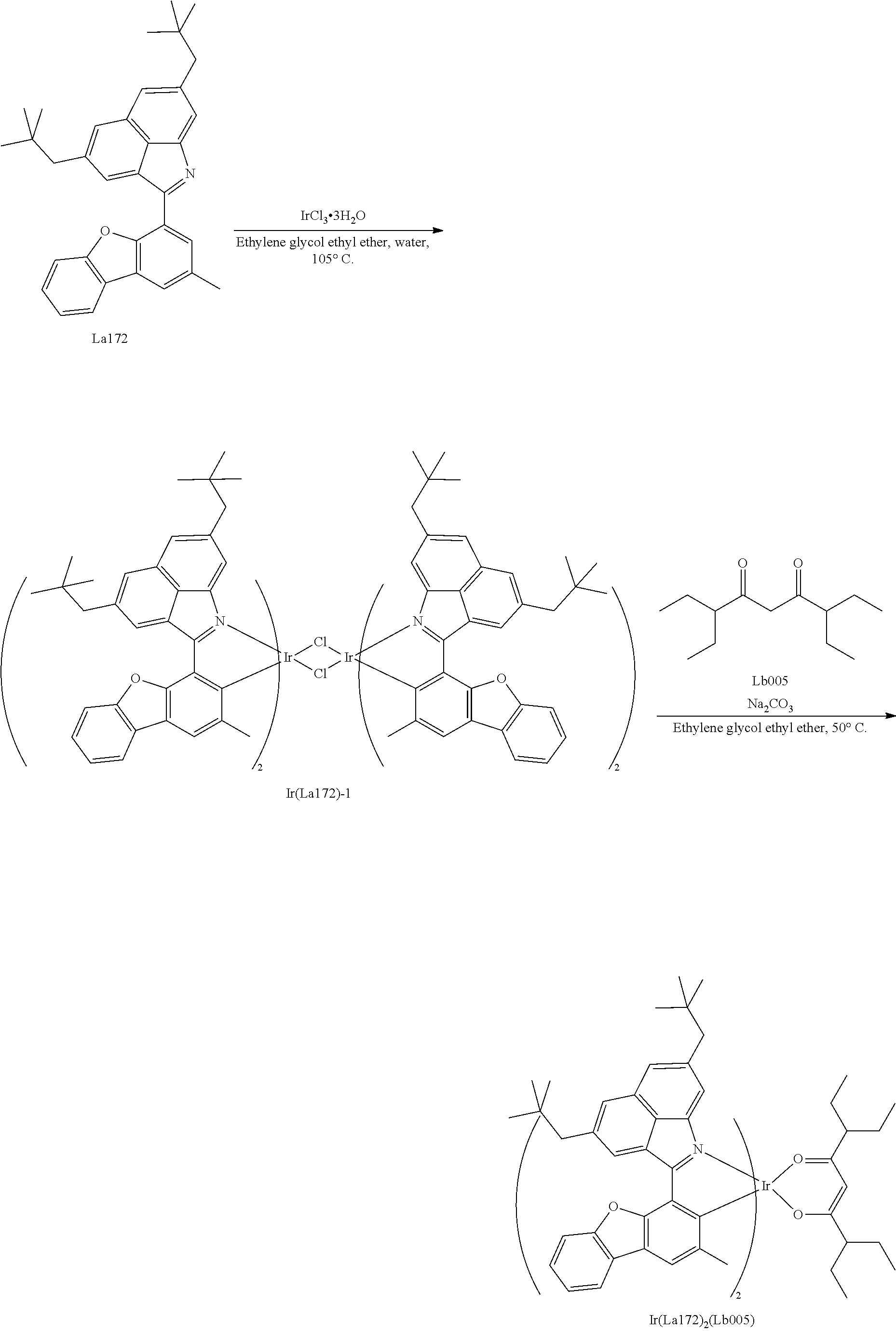

### Synthesis of a Compound Ir(La172)-1

With reference to synthesis and purification methods of the compound Ir(La003)-1, only the corresponding raw materials were required to be changed, and 7.35 g of a red solid compound Ir(La172)-1 with a yield of 67.91% was obtained. The obtained compound was directly used in the next step without purification.

### Synthesis of a Compound Ir(La172)₂(Lb005)

With reference to synthesis and purification methods of the compound Ir(La003)₂(Lb005), only the corresponding raw materials were required to be changed, and 1.56 g of a red solid compound Ir(La172)₂(Lb005) with a purity of 99.82% and a yield of 46.12% was obtained. 1.56 g of the crude product Ir(La172)₂(Lb005) was sublimated and purified to obtain 0.72 g of sublimated and purified Ir(La172)₂(Lb005) with a purity of 99.78% and a yield of 46.15%. The mass spectrum was 1349.68 (M+H).

¹H NMR (400 MHz, CDCl3) δ 7.99-7.97 (m, 2H), 7.81 (m, 2H), 7.60-7.58 (m, 4H), 7.54-7.53 (m, 2H), 7.39-7.31 (m, 2H), 7.30-7.28 (m, 4H), 7.10 (t, J=1.4 Hz, 2H), 4.72 (s, 1H), 2.54 (t, J=3.8 Hz, 8H), 2.34 (s, 6H), 1.34-1.21 (m, 10H), 0.94 (t, J=6.7 Hz, 12H), 0.89-0.83 (m, 36H).

### Synthesis of a Compound Ir(La003)(Lb005)(Lc004)

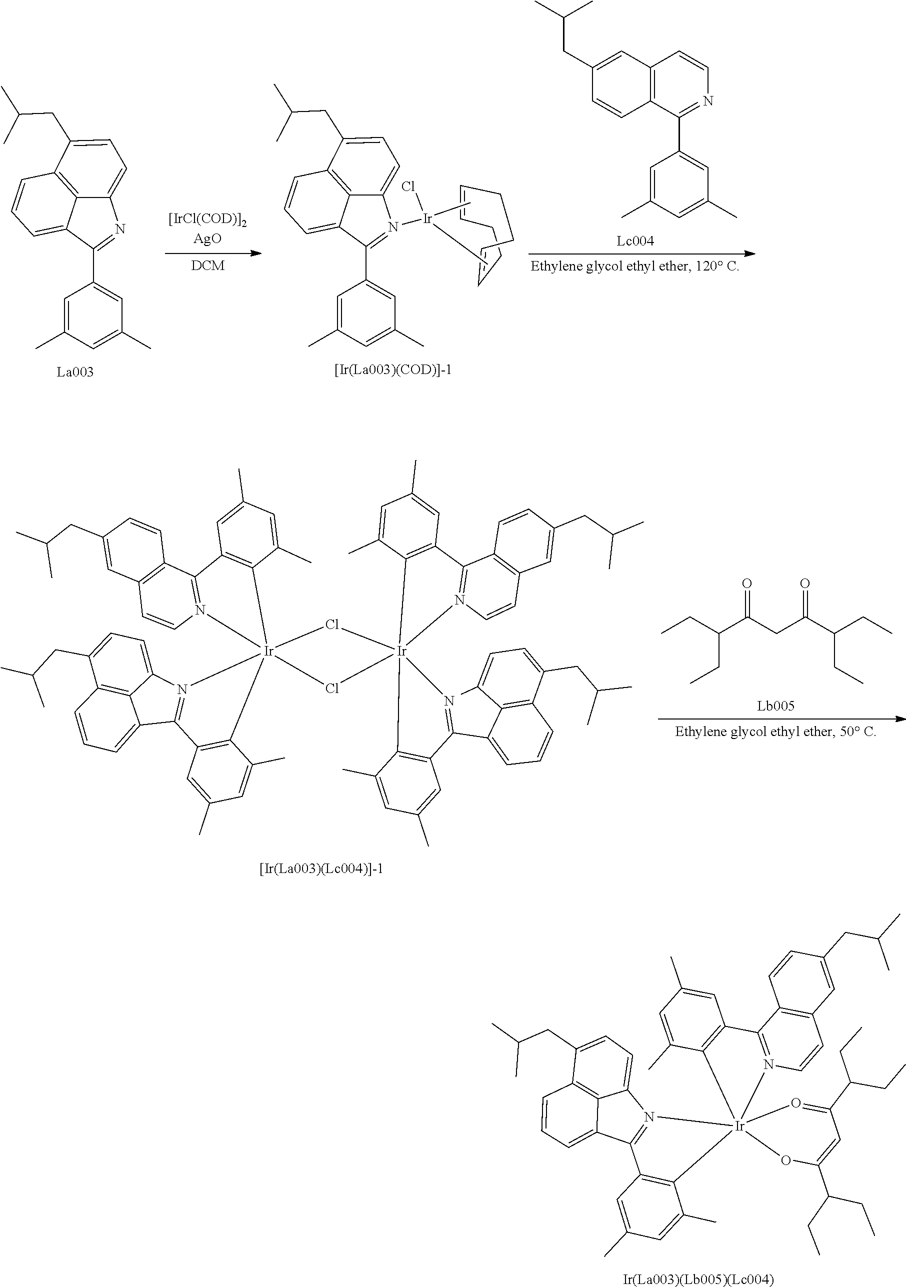

### Synthesis of a Compound [Ir(La003)(COD)]-1

The La003 (14.27 g, 45.52 mmol), silver oxide (5.27 g, 22.76 mmol), 4 A powdered molecular sieve (30 g) and dichloromethane (320 ml) were added into a 1,000 ml one-necked round-bottomed flask, vacuumization was performed for nitrogen replacement for 3 times, and stirring was performed to carry out a reaction at room temperature for 5 hours until a reaction solution became a brownish black turbid solution. According to monitoring by TLC (with a developing agent including ethyl acetate and petroleum ether at a ratio of 1:15), the raw material La003 was completely consumed. Then, chloro(1,5-cyclooctadiene)iridium dimer (15.28 g, 22.76 mmol) was added into the reaction solution and stirred overnight at room temperature for 16 hours. According to monitoring by TLC (with a developing agent including methanol and dichloromethane at a ratio of 1:90), a reaction was stopped when a large amount of a high-polarity red product was produced.

Filtration was performed, a filtrate was collected and concentrated, and n-hexane (150 ml) was added for beating at room temperature for 2 hours. Then, suction filtration was performed, and a filter cake was dried to obtain 10.67 g of a red solid [Ir(La003)(COD)]-1 with a yield of 70.71%. The mass spectrum was: 648.19 (M+H).

### Synthesis of a Compound [Ir(La003)(Lc004)]-1

The compound [Ir(La003)(COD)]-1 (10.00 g, 15.45 mmol), Lc004 (13.40 g, 46.35 mmol) and ethylene glycol ethyl ether (180 ml) were added into a 500 ml three-necked round-bottomed flask, vacuumization was performed for replacement for 3 times, and the above compounds were heated to 120° C. and stirred overnight for 24 hours. According to monitoring by TLC (with a developing agent including methanol and dichloromethane at a ratio of 1:97), the raw material [Ir(La003)(COD)]-1 was completely consumed.

After cooling was performed to room temperature, methanol (350 ml) was added, and filtration was performed. Then, a filter cake was dried under vacuum at 80° C. to obtain 5.34 g of a compound [Ir(La003)(Lc004)]-1 with a yield of 41.96%. The obtained compound was directly used in the next step without purification.

### Synthesis of a Compound Ir(La003)(Lb005)(Lc004)

With reference to synthesis and purification methods of the compound Ir(La003)₂(Lb005), only the corresponding raw materials were required to be changed, and 2.85 g of a red solid compound Ir(La003)(Lb005)(Lc004) with a purity of 99.87% and a yield of 43.21% was obtained. 2.85 g of the crude product Ir(La003)(Lb005)(Lc004) was sublimated and purified to obtain 1.63 g of sublimated and purified Ir(La003)(Lb005)(Lc004) with a purity of 99.81% and a yield of 57.19%. The mass spectrum was 1005.28 (M+H).

¹H NMR (400 MHz, CDCl₃) δ 8.59 (d, J=7.5 Hz, 1H), 8.20 (d, J=1.4 Hz, 1H), 7.96-7.82 (m, 1H), 7.83-7.76 (m, 2H), 7.68 (d, J=1.4 Hz, 3H), 7.52-7.49 (m, 2H), 7.45 (d, J=7.5 Hz, 1H), 6.92-6.89 (m, 3H), 4.76 (s, 1H), 2.91 (d, J=7.2 Hz, 2H), 2.43 (d, J=7.8 Hz, 2H), 2.32 (s, 12H), 1.85-1.77 (m, 2H), 1.36-1.21 (m, 10H), 0.94 (t, J=6.7 Hz, 12H), 0.88-0.85 (m, 12H).

### Synthesis of a Compound Ir(La029)(Lb005)(Lc011)

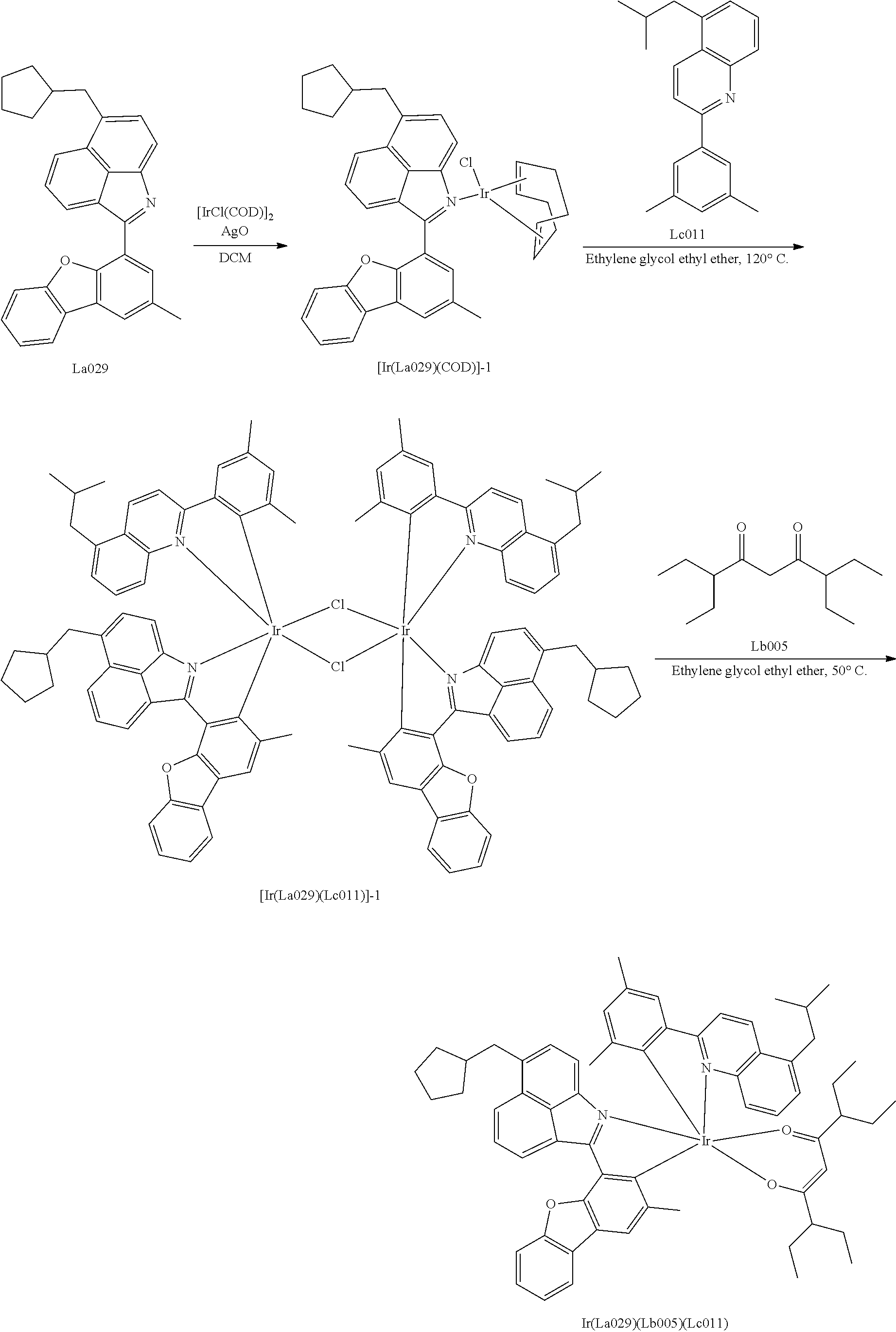

### Synthesis of a Compound [Ir(La029)(COD)]-1

With reference to synthesis and purification methods of the compound [Ir(La003)(COD)]-1, only the corresponding raw materials were required to be changed, and 12.54 g of compound [Ir(La029)(COD)]-1 with a yield of 72.36% was obtained. The mass spectrum was 751.24 (M+H).

### Synthesis of a Compound [Ir(La029)(Lc011)]-1

With reference to synthesis and purification methods of the compound [Ir(La003)(Lc004)]-1, only the corresponding raw materials were required to be changed, and 7.01 g of a red solid compound [Ir(La029)(Lc011)]-1 with a yield of 52.64% was obtained. The obtained compound was directly used in the next step without purification.

### Synthesis of a Compound Ir(La029)(Lb005)(Lc011)

With reference to synthesis and purification methods of the compound Ir(La003)₂(Lb005), only the corresponding raw materials were required to be changed, and 2.33 g of a red solid compound Ir(La029)(Lb005)(Lc011) with a purity of 99.89% and a yield of 46.77% was obtained. 2.33 g of the crude product Ir(La029)(Lb005)(Lc011) was sublimated and purified to obtain 1.40 g of sublimated and purified Ir(La029)(Lb005)(Lc011) with a purity of 99.87% and a yield of 60.08%. The mass spectrum was 1107.20 (M+H).

¹H NMR (400 MHz, CDCl₃) δ 8.61 (d, J=7.5 Hz, 1H), 8.07 (d, J=1.4 Hz, 1H), 7.99-7.94 (m, 2H), 7.88-7.86 (m, 3H), 7.67-7.64 (m, 1H), 7.55-7.53 (m, 1H), 7.48 (dd, J=7.4, 1.5 Hz, 1H), 7.44 (d, J=7.5 Hz, 1H), 7.40-7.29 (m, 3H), 7.19 (m, 1H), 6.92-6.89 (m, 2H), 4.74 (s, 1H), 2.91 (d, J=7.5 Hz, 2H), 2.48 (d, J=7.2 Hz, 2H), 2.34-2.31 (m, 10H), 1.95-1.63 (m, 9H), 1.36-1.22 (m, 10H), 0.94 (t, J=6.7 Hz, 12H), 0.86 (d, J=6.3 Hz, 6H).

### Synthesis of a Compound Ir(La076)(Lb005)(Lc023)

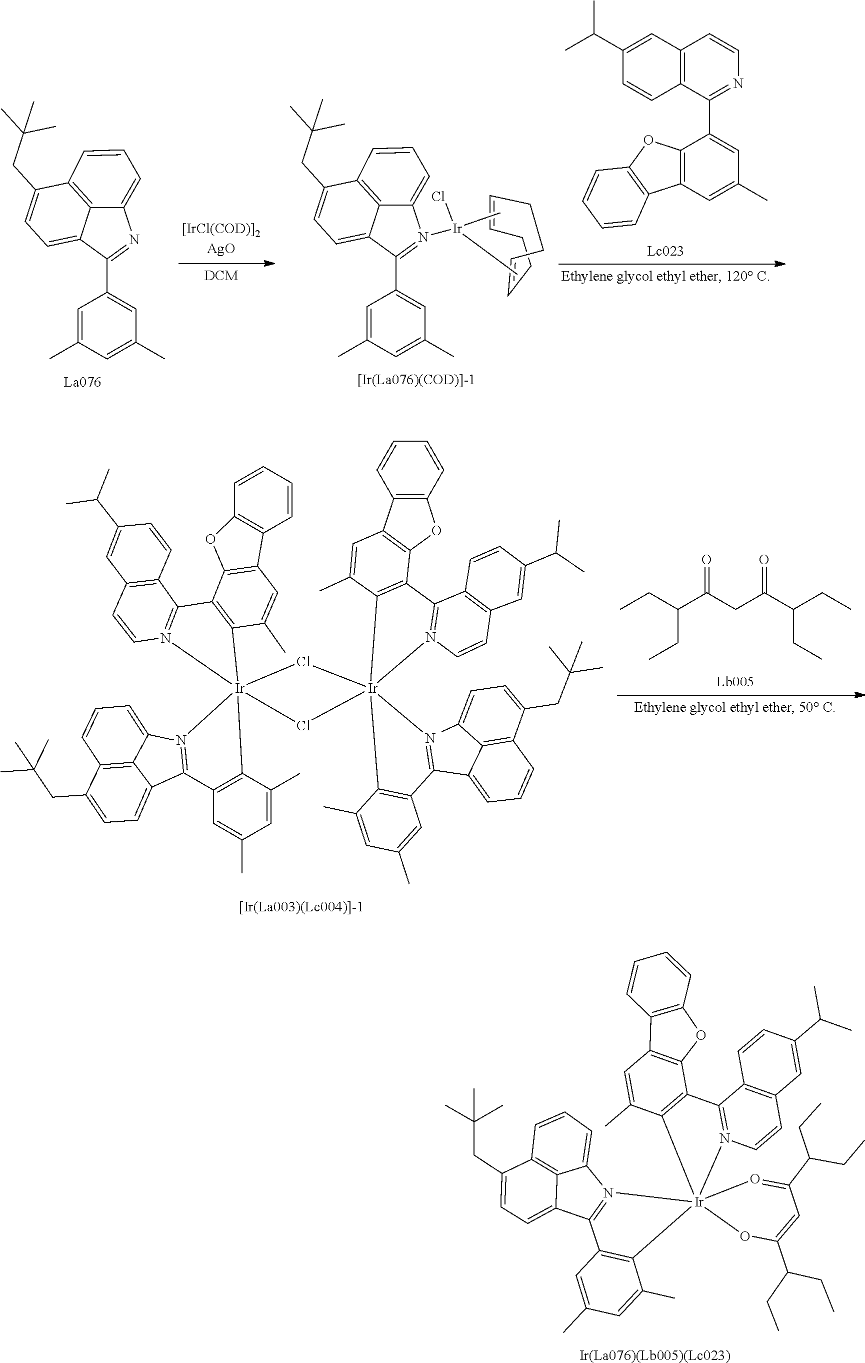

### Synthesis of a Compound [Ir(La076)(COD)]-1

With reference to synthesis and purification methods of the compound [Ir(La003)(COD)]-1, only the corresponding raw materials were required to be changed, and 14.52 g of compound [Ir(La076)(COD)]-1 with a yield of 70.11% was obtained. The mass spectrum was 663.22 (M+H).

### Synthesis of a Compound [Ir(La076)(Lc023)]-1

With reference to synthesis and purification methods of the compound [Ir(La003)(Lc004)]-1, only the corresponding raw materials were required to be changed, and 6.88 g of a red solid compound [Ir(La076)(Lc023)]-1 with a yield of 53.57% was obtained. The obtained compound was directly used in the next step without purification.

### Synthesis of a Compound Ir(La029)(Lb005)(Lc023)

With reference to synthesis and purification methods of the compound Ir(La003)₂(Lb005), only the corresponding raw materials were required to be changed, and 2.12 g of a red solid compound Ir(La029)(Lb005)(Lc023) with a purity of 99.88% and a yield of 48.44% was obtained. 2.12 g of the crude product Ir(La029)(Lb005)(Lc023) was sublimated and purified to obtain 1.08 g of sublimated and purified Ir(La029)(Lb005)(Lc023) with a purity of 99.85% and a yield of 50.94%. The mass spectrum was 1081.28 (M+H).

¹H NMR (400 MHz, CDCl₃) δ 8.53 (d, J=1.4 Hz, 1H), δ 8.23 (m, 1H), 7.98-7.77 (m, 2H), 7.68 (d, J=2.9 Hz, 1H), 7.62-7.57 (m, 4H), 7.51-7.31 (m, 5H), 7.08 (t, J=14.9 Hz, 1H), 6.99-6.92 (m, 2H), 4.74 (s, 1H), 3.09 (s, 2H), 2.892-2.82 (m, 1H), 2.34-2.31 (s, 9H), 1.37-1.26 (m, 10H), 1.24-1.19 (m, 6H), 1.09-0.94 (m, 12H), 0.85 (s, 9H).

### Application Example: Manufacturing of an Organic Electroluminescent Device

A glass substrate with a size of 50 mm*50 mm*1.0 mm including an indium tin oxide (ITO, 100 nm) transparent electrode was ultrasonically cleaned in ethanol for 10 minutes, dried at 150° C., and then treated with N₂ plasma for 30 minutes. The washed glass substrate was installed on a substrate support of a vacuum evaporation device. At first, a compound HATCN for covering the transparent electrode was evaporated on the surface of the side having a transparent electrode line to form a thin film with a thickness of 5 nm. Then, a layer of HTM1 was evaporated to form a thin film with a thickness of 60 nm. Then, a layer of HTM2 was evaporated on the HTM1 thin film to form a thin film with a thickness of 10 nm. Then, a host material and a doping compound (including a reference compound X and the compound of the present invention) were co-evaporated on the HTM2 film layer to obtain a film with a thickness of 30 nm, where the ratio of the host material to the doping material was 90%:10%. Then, an electron transport layer (ETL, 25 nm) and a LiQ film layer (1 nm) was sequentially evaporated on a light-emitting layer. Finally, a metal Al layer (100 nm) was evaporated to serve as an electrode.

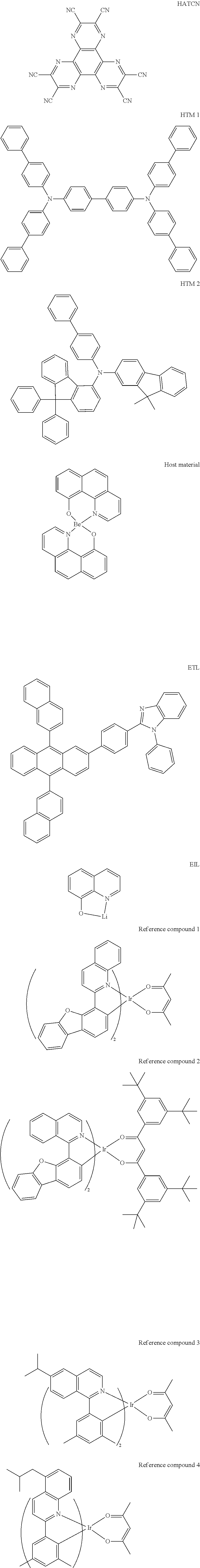

### Evaluation

Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT90) when the brightness was reduced to 90% of the initial brightness was tested. Results are shown as follows.

| | | Peak | | Starting | Current | |
|---|---|---|---|---|---|---|
| | | wavelength/ | FWHM/ | voltage/ | efficiency | LT90@ |
| | Doping material | nm | nm | V | Cd/A | 3000 nits |
| Example 1 | Ir(La003)₂(Lb005) | 614.5 | 41 | 3.98 | 25.1 | 226 |
| Example 2 | Ir(La003)₂(Lb007) | 616 | 42 | 4.03 | 25.4 | 236 |
| Example 3 | Ir(La006)₂(Lb005) | 615 | 43 | 4.05 | 24.6 | 251 |
| Example 4 | Ir(La015)₂(Lb005) | 616.5 | 44 | 4.11 | 24.3 | 233 |
| Example 5 | Ir(La029)₂(Lb005) | 615.5 | 40 | 3.96 | 24.9 | 261 |
| Example 6 | Ir(La029)₂(Lb009) | 616 | 41 | 4.04 | 23.6 | 242 |
| Example 7 | Ir(La039)₂(Lb005) | 615 | 41 | 4.02 | 24.8 | 276 |
| Example 8 | Ir(La051)₂(Lb005) | 616.5 | 45 | 4.13 | 23.1 | 229 |
| Example 9 | Ir(La076)₂(Lb005) | 615 | 44 | 4.07 | 22.4 | 255 |
| Example 10 | Ir(La083)₂(Lb005) | 615.5 | 44 | 4.10 | 23.3 | 248 |
| Example 11 | Ir(La091)₂(Lb005) | 617 | 45 | 4.11 | 25.3 | 244 |
| Example 12 | Ir(La111)₂(Lb005) | 615 | 43 | 4.04 | 22.8 | 239 |
| Example 13 | Ir(La135)₂(Lb005) | 617 | 42 | 4.07 | 24.9 | 276 |
| Example 14 | Ir(La155)₂(Lb005) | 614 | 43 | 3.94 | 24.8 | 238 |
| Example 15 | Ir(La172)₂(Lb005) | 616 | 41 | 4.07 | 25.1 | 281 |
| Example 16 | Ir(La003)(Lb005)(Lc004) | 615 | 42 | 4.11 | 23.6 | 252 |
| Example 17 | Ir(La029)(Lb005)(Lc011) | 615.5 | 41 | 4.06 | 23.9 | 244 |
| Example 18 | Ir(La076)(Lb005)(Lc023) | 615 | 42 | 4.03 | 24.4 | 256 |
| Comparative | Reference compound 1 | 610 | 50 | 4.21 | 21 | 108 |
| Example 1 | | | | | | |
| Comparative | Reference compound 2 | 612 | 52 | 4.18 | 20 | 120 |
| Example 2 | | | | | | |
| Comparative | Reference compound 3 | 613 | 53 | 4.22 | 20.3 | 101 |
| Example 3 | | | | | | |
| Comparative | Reference compound 4 | 608 | 49 | 4.28 | 19 | 86 |
| Example 4 | | | | | | |

Through comparison of the data in the above table, it can be seen that compared with reference compounds, the compound of the present invention used as a dopant in an organic electroluminescent device has narrower emission spectrum, higher color saturation and more excellent properties, such as driving voltage, luminous efficiency and device life.

Comparison in sublimation temperature: The sublimation temperature is defined as a corresponding temperature at an evaporation rate of 1 angstrom per second and a vacuum degree of 10⁻⁷ Torr. Test results are shown as follows.

| | Sublimation |
|---|---|
| Doping material | temperature |
| Ir(La003)₂(Lb005) | 268 |
| Ir(La015)₂(Lb005) | 265 |
| Ir(La029)₂(Lb005) | 273 |
| Ir(La076)₂(Lb005) | 271 |
| Ir(La172)₂(Lb005) | 263 |
| Ir(La003)(Lb005)(Lc004) | 267 |
| Reference compound 1 | 280 |
| Reference compound 2 | 288 |
| Reference compound 3 | 278 |
| Reference compound 4 | 276 |

Through comparison of the data in the above table, it can be seen that the compound of the present invention has lower sublimation temperature, which is conducive to industrial application.

In the present invention, through special combinations of substituents, better luminous efficiency and improved service life of a device are unexpectedly provided, and meanwhile, lower sublimation temperature is unexpectedly provided compared with the prior art. The above results indicate that the compound of the present invention has the advantages of lower sublimation temperature, high optical and electrochemical stability, high color saturation, high luminous efficiency, long device life and the like, and can be used in organic electroluminescent devices. In particular, the compound has the potential for application in the OLED industry as a red light-emitting dopant.

The material of the present invention has the advantages of high optical and electrical stability, low sublimation temperature, small emission half-peak width, high color saturation, high luminous efficiency, long device life and the like. As a phosphorescent material, the material of the present invention can convert a triplet excited state into light, thereby improving the luminous efficiency of organic electroluminescent devices and reducing energy consumption. In particular, the compound has the potential for application in the AMOLED industry as a red light-emitting dopant.

1. An organometallic iridium compound, having a general formula of Ir(La)(Lb)(Lc), wherein La is a structure represented by Formula (1): 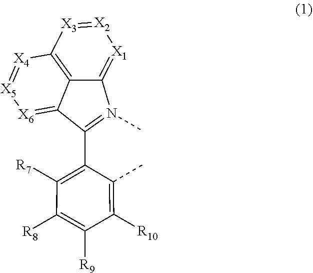
wherein dotted lines refer to positions connected to the metal Ir;
X₁ is N or CR₁, X₂ is N or CR₂, X₃ is N or CR₃, X₄ is N or CR₄, X₅ is N or CR₅, and X₆ is N or CR₆;
at most one of the X₁-X₆ is N, and when the X₁-X₆ are CR₁-CR₆, at least one of the R₁-R₆ is not H;
R₁-R₁₀ are independently selected from hydrogen, deuterium, halogen, cyano, hydroxyl, sulfhydryl, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₆ or R₇-R₁₀ may be connected to each other to form an aliphatic ring or an aromatic ring; and at least one of the R₇-R₁₀ is not hydrogen;
Lb is a structure represented by Formula (2): 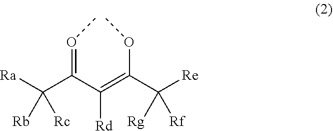
wherein dotted lines refer to positions connected to the metal Ir;
Ra-Rg are independently selected from hydrogen, deuterium, halogen, substituted or unsubstituted C₁-C₁₀ alkyl, substituted or unsubstituted C₃-C₂₀ cycloalkyl, substituted or unsubstituted C₁-C₁₀ heteroalkyl, and substituted or unsubstituted C₃-C₂₀ heterocyclic alkyl, or any two of the Ra, the Rb and the Rc are connected to form an aliphatic ring, and any two of the Re, the Rf and the Rg are connected to form an aliphatic ring;
the “substituted” refers to substitution with deuterium, F, Cl, Br, C₁-C₆ alkyl, C₁-C₆ alkoxyl, C₃-C₆ cycloalkyl, amino substituted with C₁-C₆ alkyl, cyano, isocyano, or phosphino, and the substitution ranges from a single substitution number to a maximum substitution number;
and the heteroalkyl, the heterocyclic alkyl and the heteroaryl at least contain one O, N or S heteroatom;
Lc is a monoanionic bidentate ligand, and the Lc is different from the Lb and is not an OO ligand;
the Lc and the La are the same or different, and the different indicates different parent nuclear structures, a same parent nuclear structure with different substituents, or a same parent nuclear structure with different substituent positions;
or any two or three of the La, the Lb and the Lc are connected to each other to form a polydentate ligand.

2. The organometallic iridium compound according to claim 1, wherein the La is a structure represented by Formula (3): 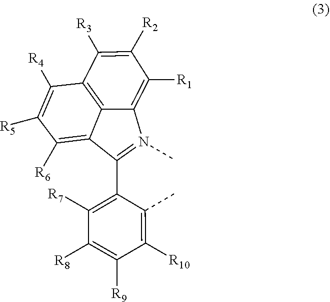
wherein dotted lines refer to positions connected to the metal Ir;
R₁-R₁₀ are independently selected from hydrogen, deuterium, halogen, cyano, hydroxyl, sulfhydryl, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁-R₆ or R₇-R₁₀ are connected to each other to form an aliphatic ring or an aromatic ring;
at least one of the R₁-R₆ is not H, and at least one of the R₇-R₁₀ is not hydrogen;
the heteroalkyl and the heteroaryl at least contain one O, N or S heteroatom;
and the “substituted” refers to substitution with deuterium, F, Cl, Br, C₁-C₄ alkyl, C₃-C₆ cycloalkyl, amino substituted with C₁-C₄ alkyl, cyano, isocyano, or phosphino, and the substitution ranges from a single substitution number to a maximum substitution number.

3. The organometallic iridium compound according to claim 2, wherein in Formula (3), at least one of the R₁, the R₃, the R₄, and the R₅ is not H.

4. The organometallic iridium compound according to claim 3, wherein in Formula (3), the R₁, the R₃, the R₄ and the R₅ are independently selected from deuterium, halogen, substituted or unsubstituted C₁-C₁₀ alkyl, and substituted or unsubstituted C₃-C₂₀ cycloalkyl.

5. The organometallic iridium compound according to claim 4, wherein in Formula (3), at least two of the R₁-R₆ are not H.

6. The organometallic iridium compound according to claim 5, wherein in Formula (3), the R₂ and the R₆ are hydrogen.

7. The organometallic iridium compound according to claim 2, wherein in Formula (3), the R₈ and/or the R₁₀ is not hydrogen.

8. The organometallic iridium compound according to claim 7, wherein in Formula (3), the R₈ and the R₁₀ are not hydrogen, the R₈ and the R₁₀ are independently selected from deuterium, halogen, substituted or unsubstituted C₁-C₁₀ alkyl, and substituted or unsubstituted C₃-C₂₀ cycloalkyl, and the R₇ and the R₉ are hydrogen.

9. The organometallic iridium compound according to claim 7, wherein the R₇ and the R₈, the R₈ and the R₉, or the R₉ and the R₁₀ are connected to each other to form a structure represented by Formula (4): 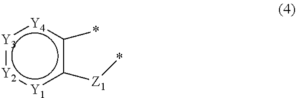
wherein * refers to a connecting position;
Y₁-Y₄ are independently CR₀ or N;
Z1 is selected from O and S;
R₀ is independently selected from hydrogen, deuterium, halogen, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃₀ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl; and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

10. The organometallic iridium compound according to claim 9, wherein the R₇ and the R₈ are connected to each other to form a structure represented by Formula (4): 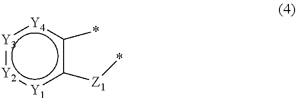
wherein * refers to a connecting position;
Y₁-Y₄ are independently CR₀;
and Z1 is selected from O.

11. The organometallic iridium compound according to claim 1, wherein the Lc and the La are the same.

12. The organometallic iridium compound according to claim 1, wherein the Lc and the La are different, and the Lc is a structure represented by Formula (5): 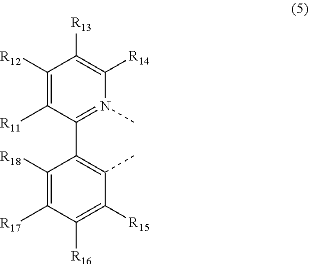
wherein dotted lines refer to positions connected to the metal Ir;
R₁₁-R₁₈ are independently selected from hydrogen, deuterium, halogen, cyano, hydroxyl, amino group, amino, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl; at least two of the R₁₅-R₁₈ are not hydrogen; or at least two adjacent groups of the R₁₁-R₁₄ form an aromatic ring structure represented by Formula (6) below: 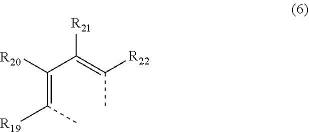
wherein dotted lines refer to positions connected to a pyridine ring;
R₁₉-R₂₂ are independently selected from hydrogen, deuterium, halogen, cyano, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, substituted or unsubstituted di-C₁-C₁₀ alkyl mono-C₆-C₃₀ aryl silyl, and substituted or unsubstituted mono-C₁-C₁₀ alkyl di-C₆-C₃₀ aryl silyl, or any two adjacent groups of the R₁₉-R₂₂ are connected to each other to form an aliphatic ring or an aromatic ring;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

13. The organometallic iridium compound according to claim 2, wherein the La has one of the following structural formulas, or is partially or completely deuterated or fluorinated correspondingly,

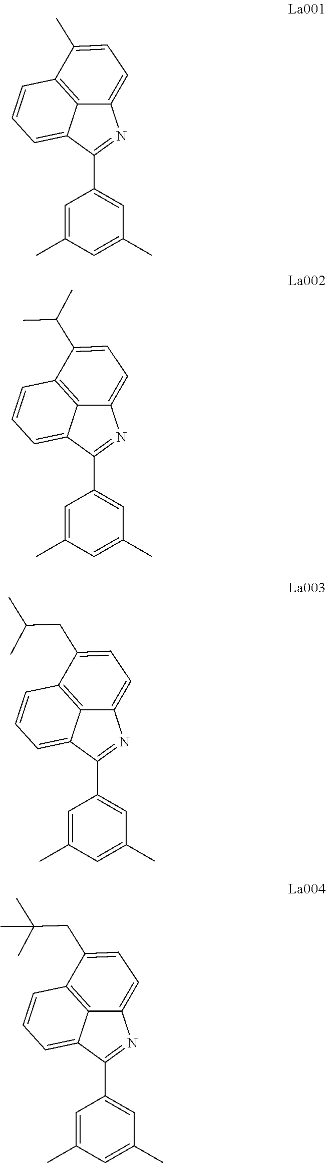

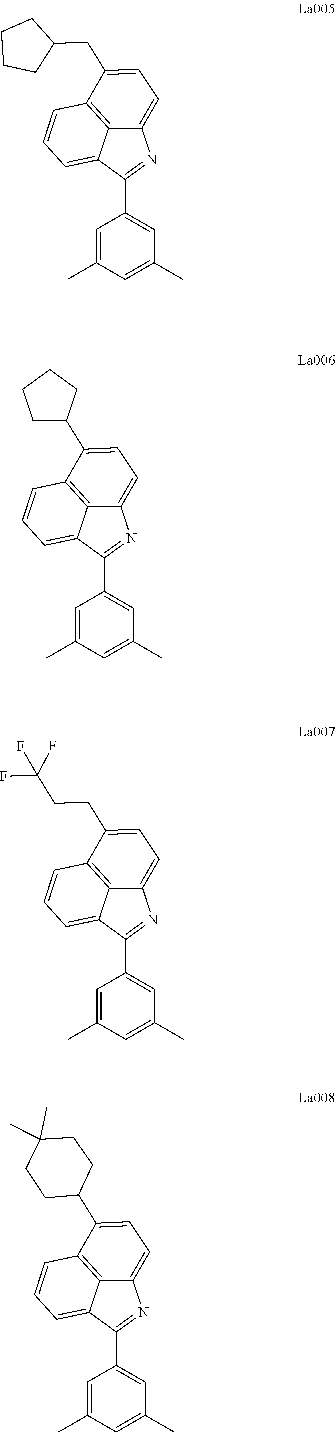

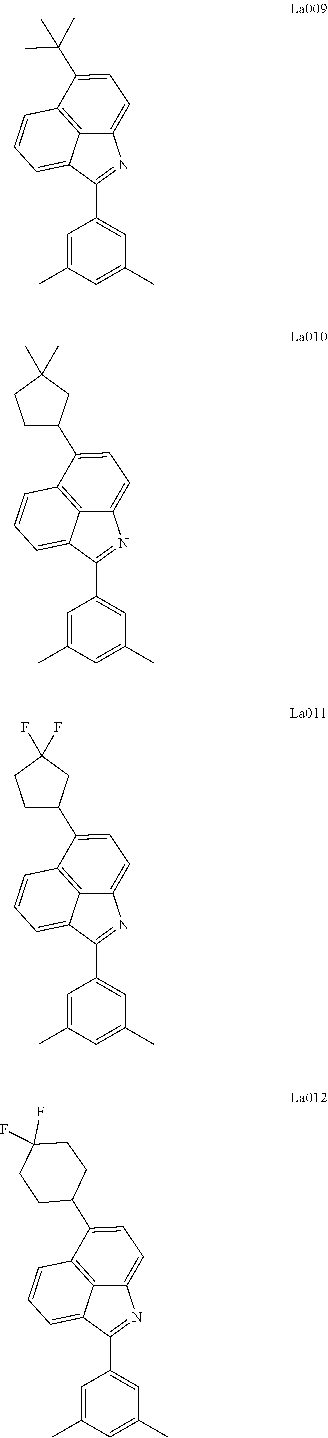 [SMILES: Cc1cc(C)cc(C2=Nc3ccc(C(C)(C)C)c4cccc2c34)c1 ; Cc1cc(C)cc(C2=Nc3ccc(C4CCC(C)(C)C4)c4cccc2c34)c1 ; Cc1cc(C)cc(C2=Nc3ccc(C4CCC(F)(F)C4)c4cccc2c34)c1 ; Cc1cc(C)cc(C2=Nc3ccc(C4CCC(F)(F)CC4)c4cccc2c34)c1]

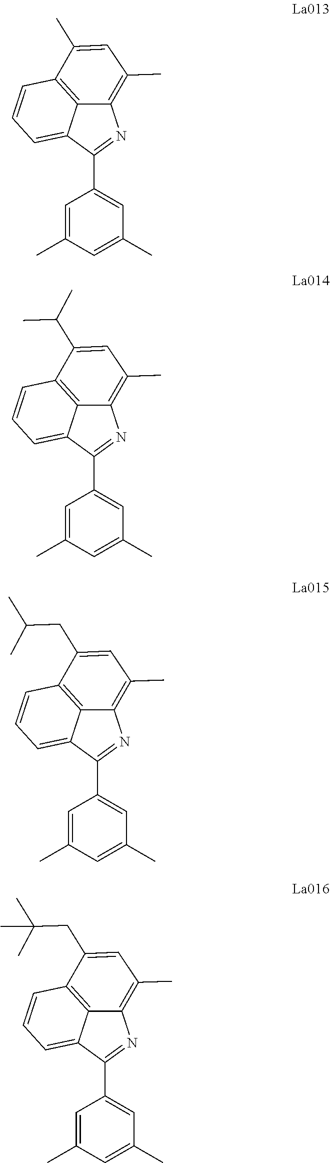

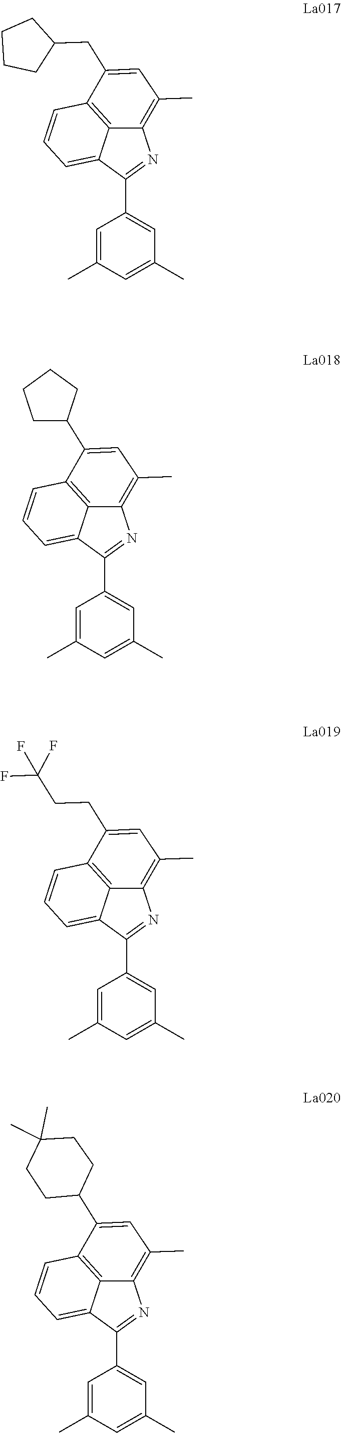

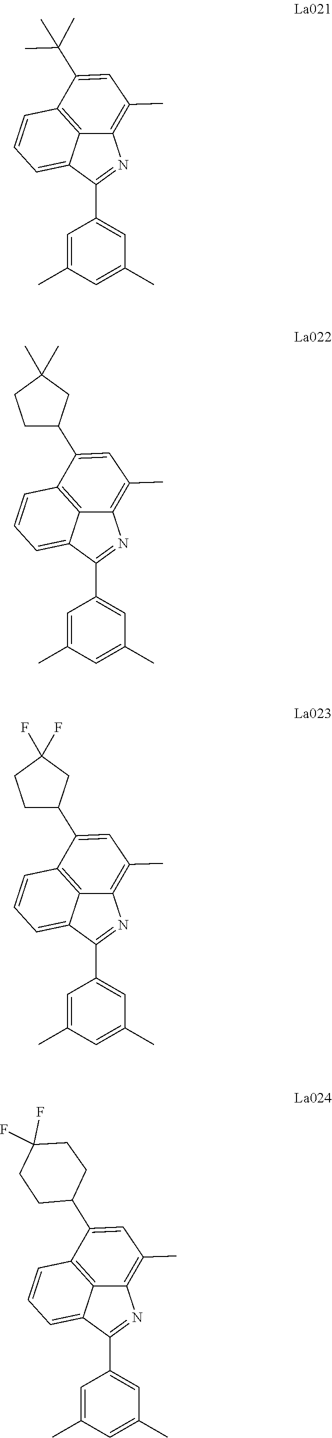 [SMILES: Cc1cc(C)cc(C2=Nc3c(C)cc(C(C)(C)C)c4cccc2c34)c1 ; Cc1cc(C)cc(C2=Nc3c(C)cc(C4CCC(C)(C)C4)c4cccc2c34)c1 ; Cc1cc(C)cc(C2=Nc3c(C)cc(C4CCC(F)(F)C4)c4cccc2c34)c1 ; Cc1cc(C)cc(C2=Nc3c(C)cc(C4CCC(F)(F)CC4)c4cccc2c34)c1]

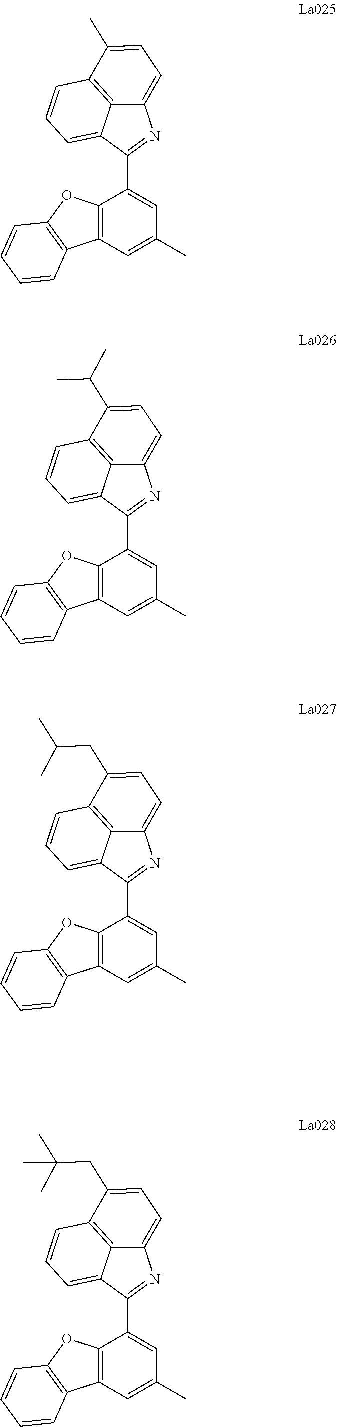 [SMILES: Cc1cc(C2=Nc3ccc(C)c4cccc2c34)c2oc3ccccc3c2c1 ; Cc1cc(C2=Nc3ccc(C(C)C)c4cccc2c34)c2oc3ccccc3c2c1 ; Cc1cc(C2=Nc3ccc(CC(C)C)c4cccc2c34)c2oc3ccccc3c2c1 ; Cc1cc(C2=Nc3ccc(CC(C)(C)C)c4cccc2c34)c2oc3ccccc3c2c1]

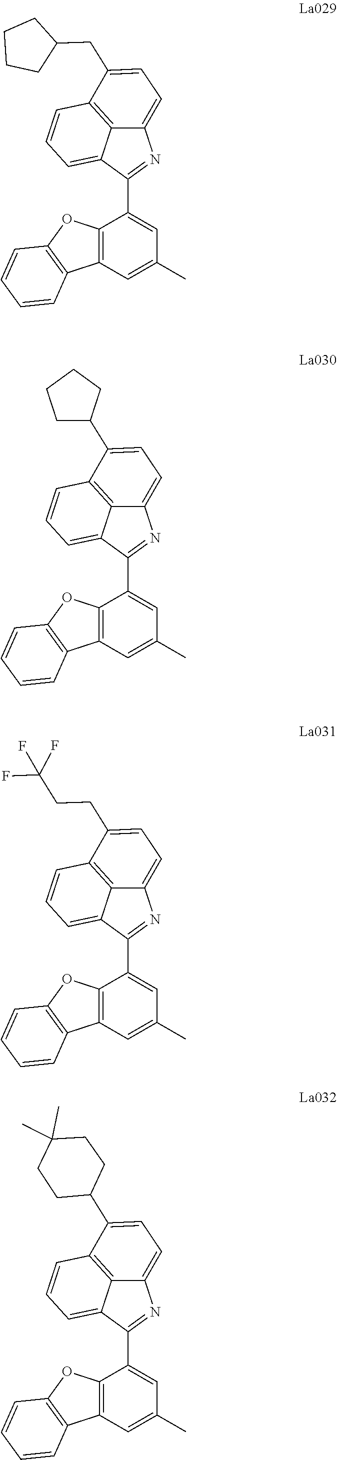

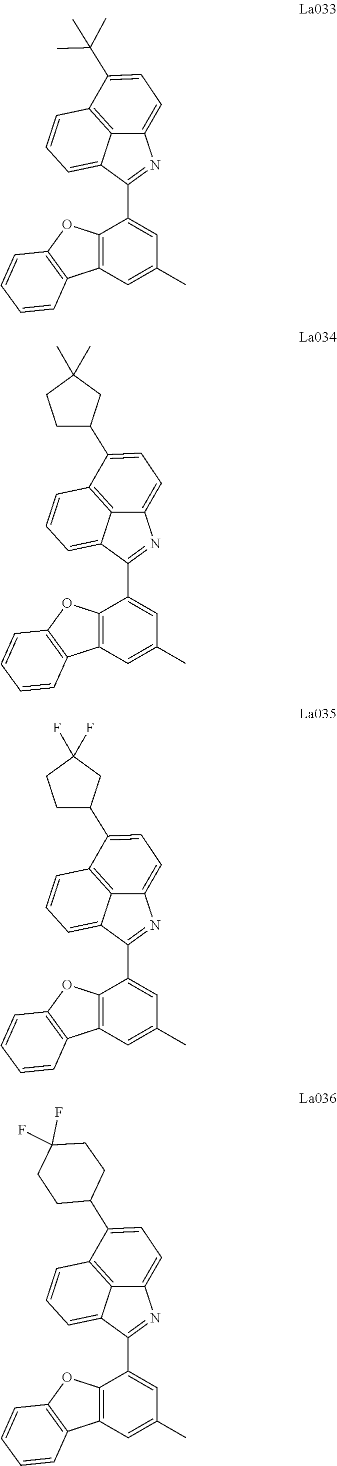

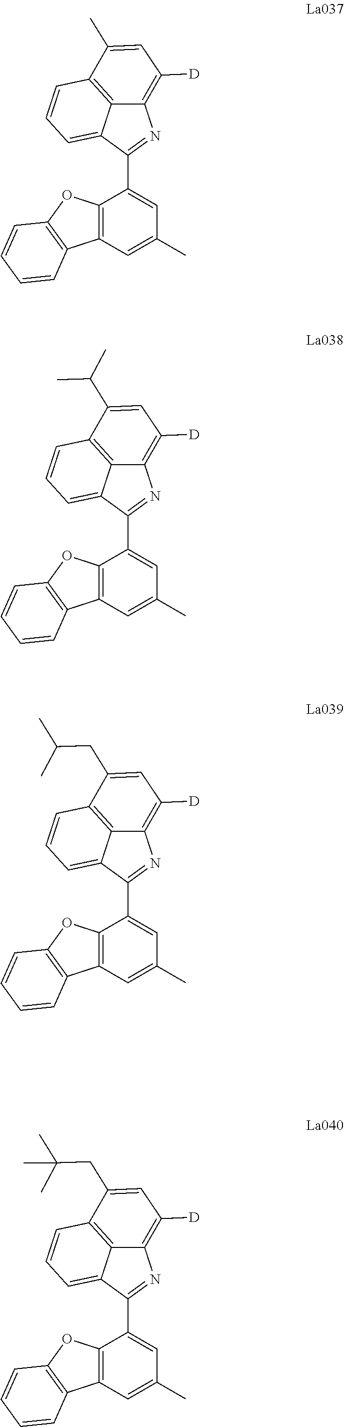 [SMILES: [2H]c1cc(C)c2cccc3c2c1N=C3c1cc(C)cc2c1oc1ccccc12 ; [2H]c1cc(C(C)C)c2cccc3c2c1N=C3c1cc(C)cc2c1oc1ccccc12 ; [2H]c1cc(CC(C)C)c2cccc3c2c1N=C3c1cc(C)cc2c1oc1ccccc12 ; [2H]c1cc(CC(C)(C)C)c2cccc3c2c1N=C3c1cc(C)cc2c1oc1ccccc12]

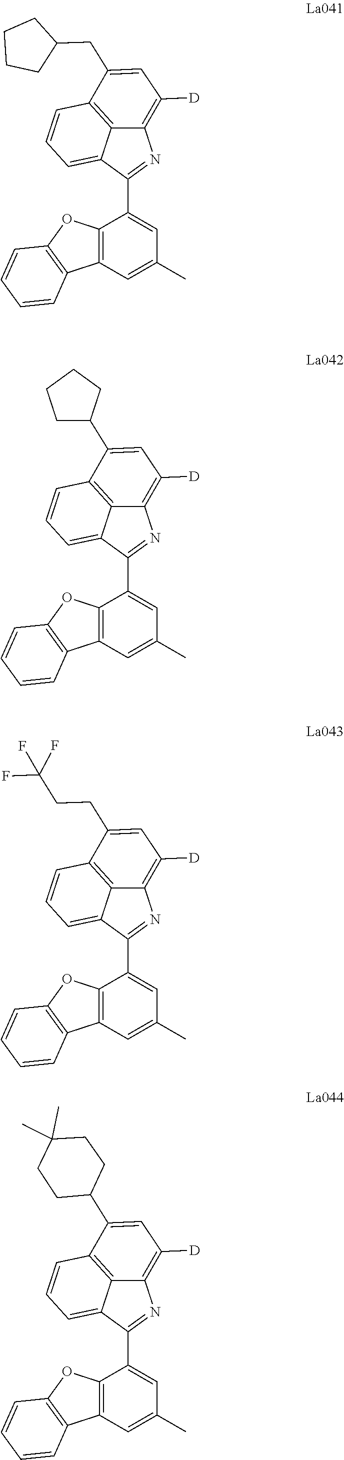

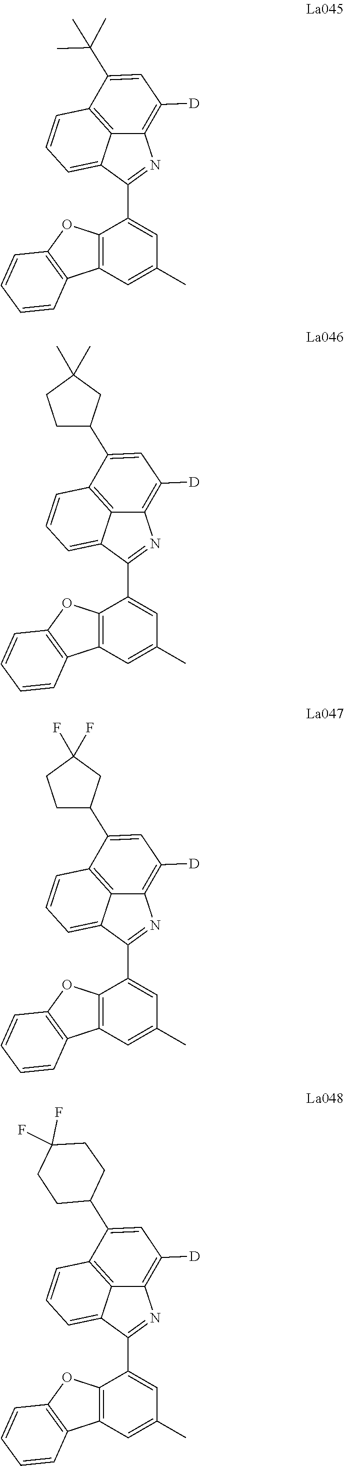

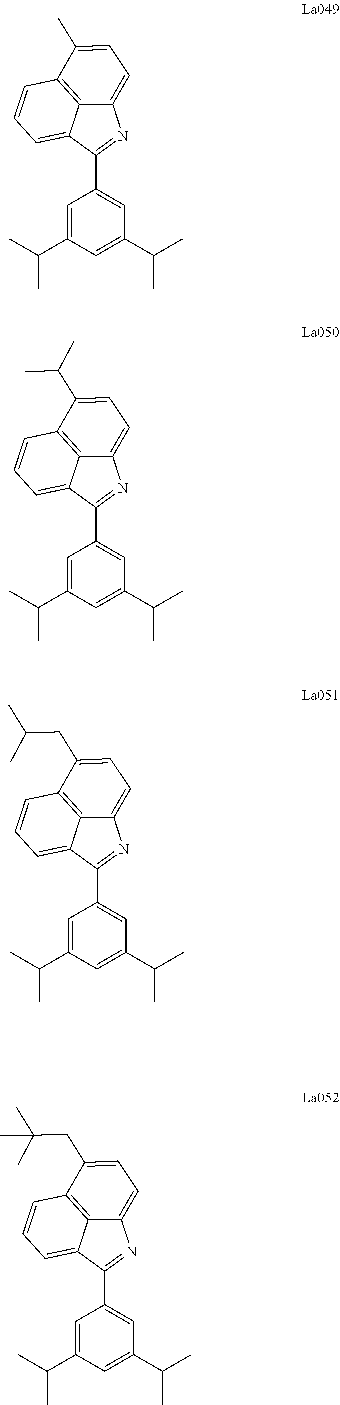

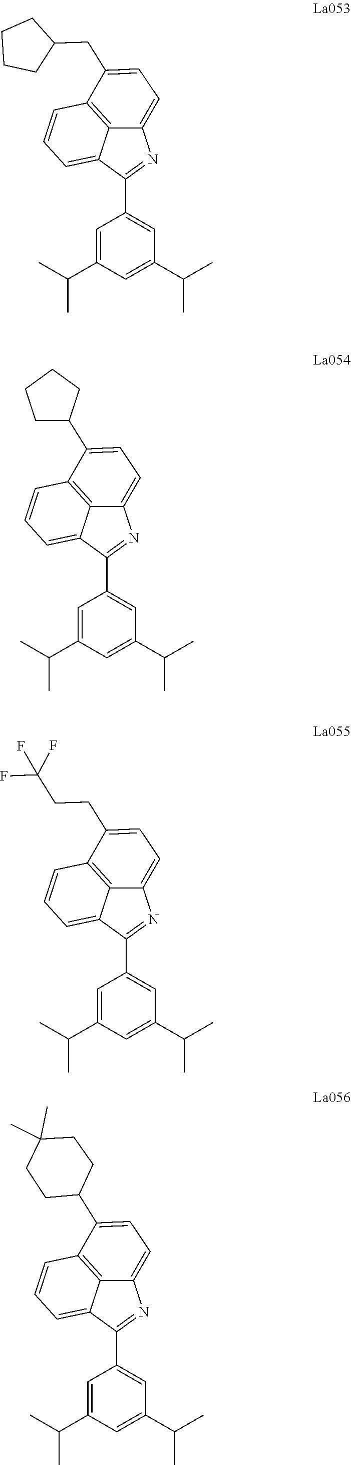

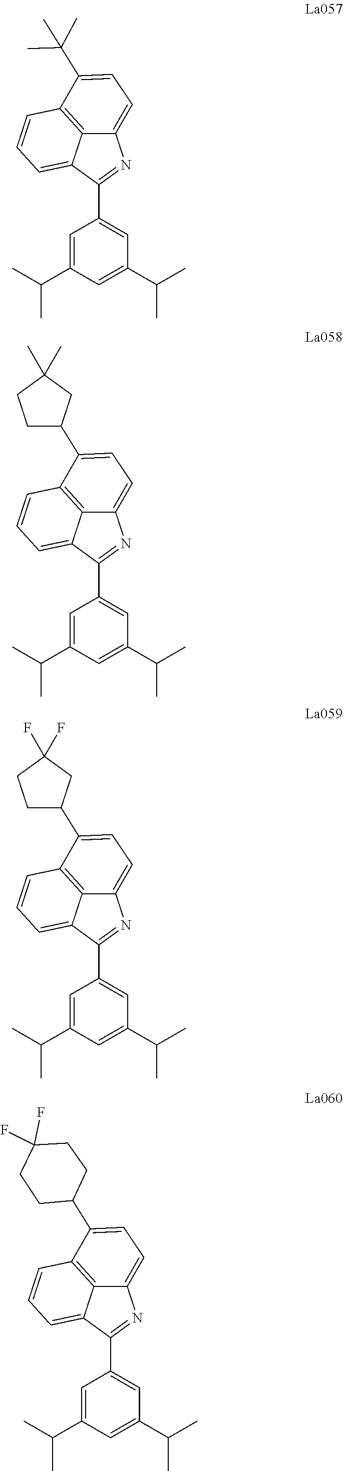

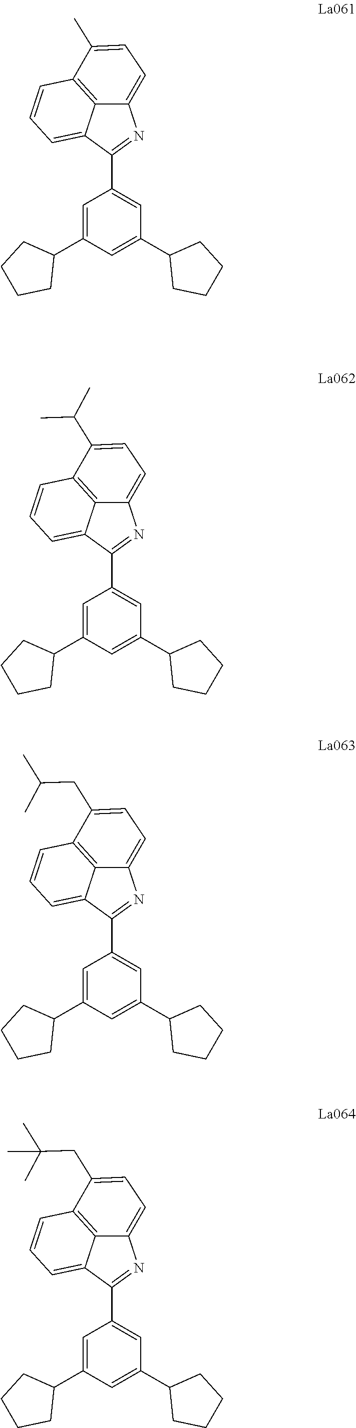 [SMILES: Cc1ccc2c3c(cccc13)C(c1cc(C3CCCC3)cc(C3CCCC3)c1)=N2 ; CC(C)c1ccc2c3c(cccc13)C(c1cc(C3CCCC3)cc(C3CCCC3)c1)=N2 ; CC(C)Cc1ccc2c3c(cccc13)C(c1cc(C3CCCC3)cc(C3CCCC3)c1)=N2 ; CC(C)(C)Cc1ccc2c3c(cccc13)C(c1cc(C3CCCC3)cc(C3CCCC3)c1)=N2]

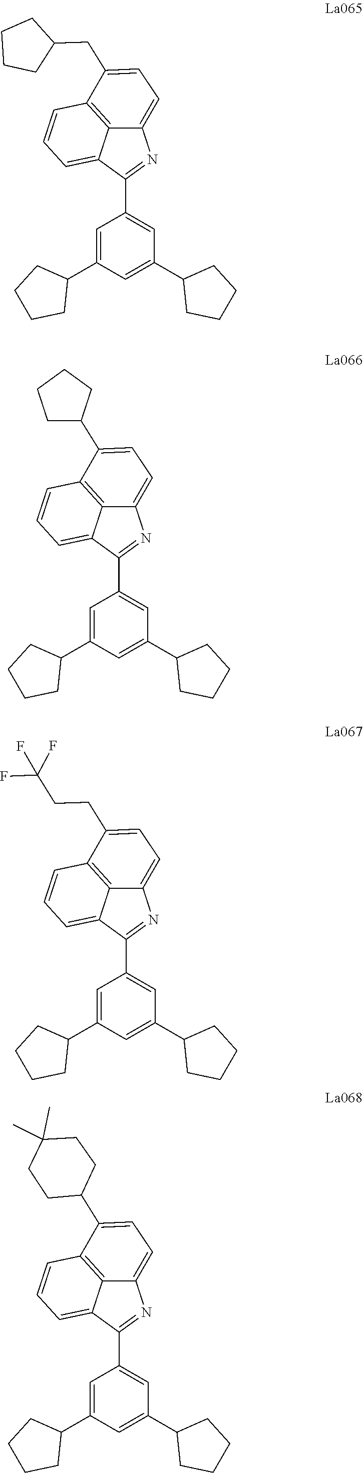

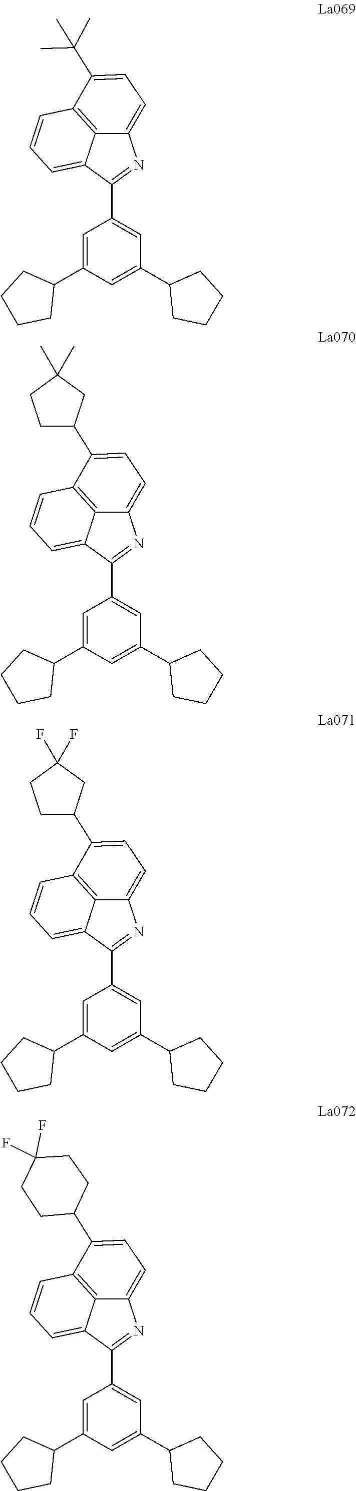

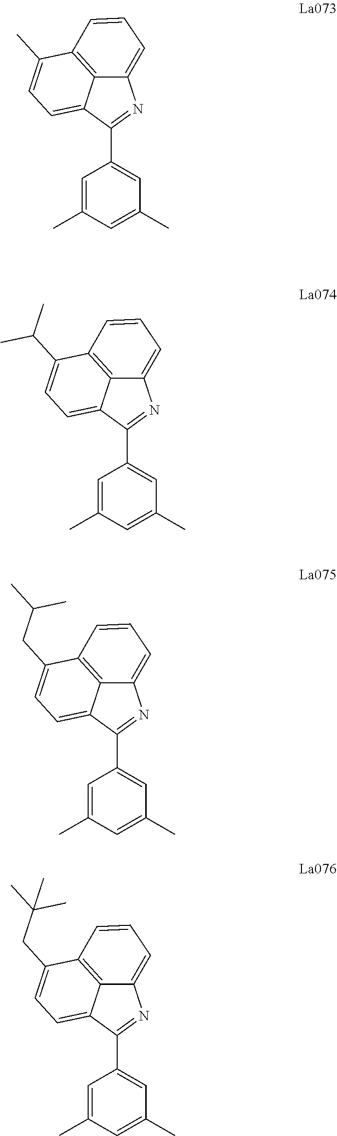

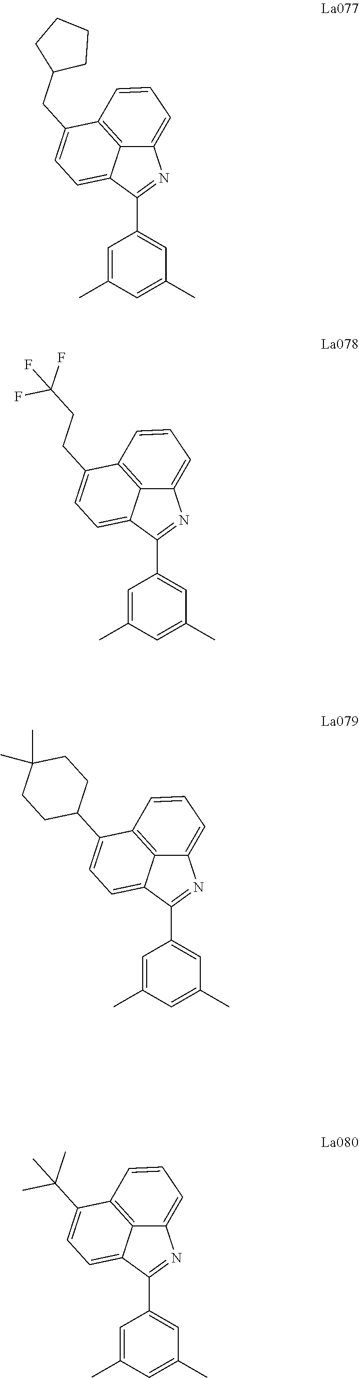

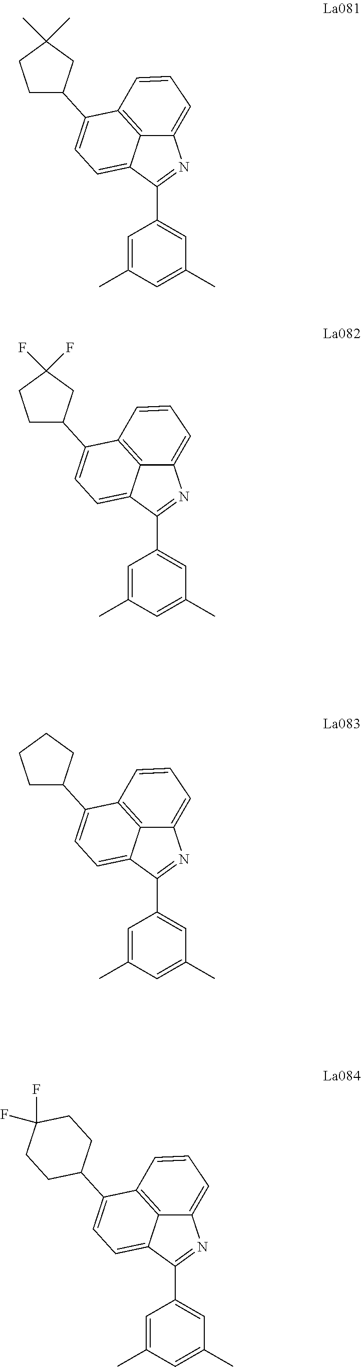 [SMILES: Cc1cc(C)cc(C2=Nc3cccc4c(C5CCC(C)(C)C5)ccc2c34)c1 ; Cc1cc(C)cc(C2=Nc3cccc4c(C5CCC(F)(F)C5)ccc2c34)c1 ; Cc1cc(C)cc(C2=Nc3cccc4c(C5CCCC5)ccc2c34)c1 ; Cc1cc(C)cc(C2=Nc3cccc4c(C5CCC(F)(F)CC5)ccc2c34)c1]

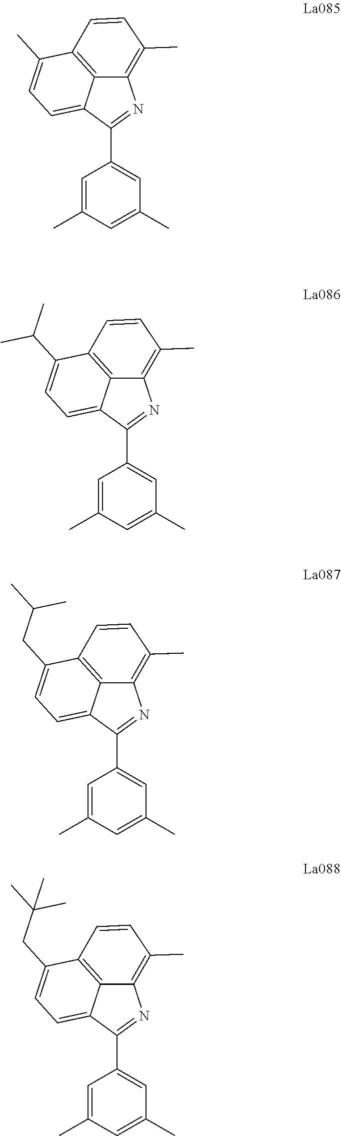

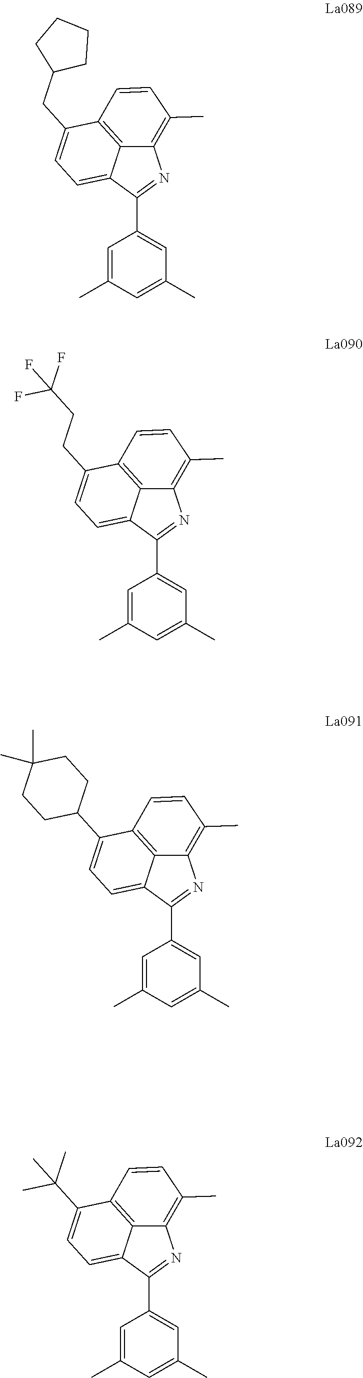

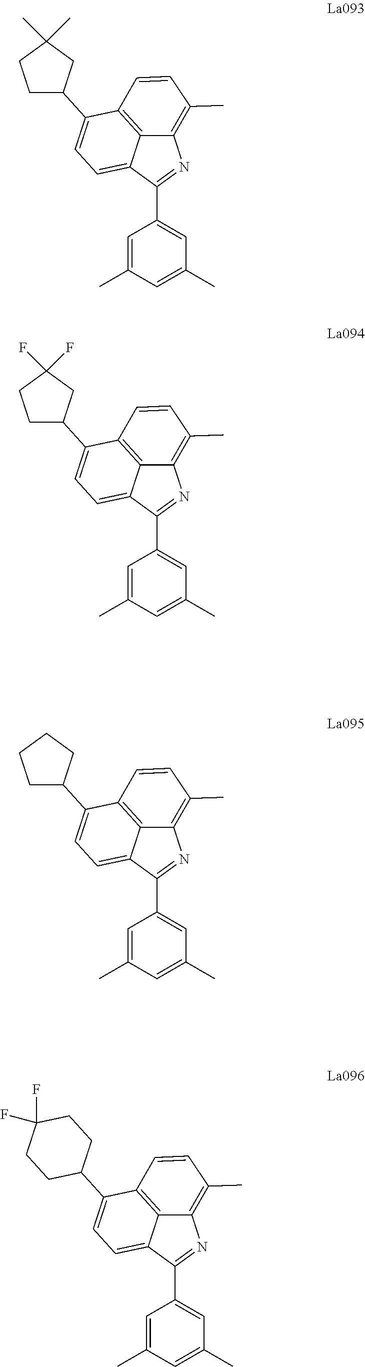 [SMILES: Cc1cc(C)cc(C2=Nc3c(C)ccc4c(C5CCC(C)(C)C5)ccc2c34)c1 ; Cc1cc(C)cc(C2=Nc3c(C)ccc4c(C5CCC(F)(F)C5)ccc2c34)c1 ; Cc1cc(C)cc(C2=Nc3c(C)ccc4c(C5CCCC5)ccc2c34)c1 ; Cc1cc(C)cc(C2=Nc3c(C)ccc4c(C5CCC(F)(F)CC5)ccc2c34)c1]

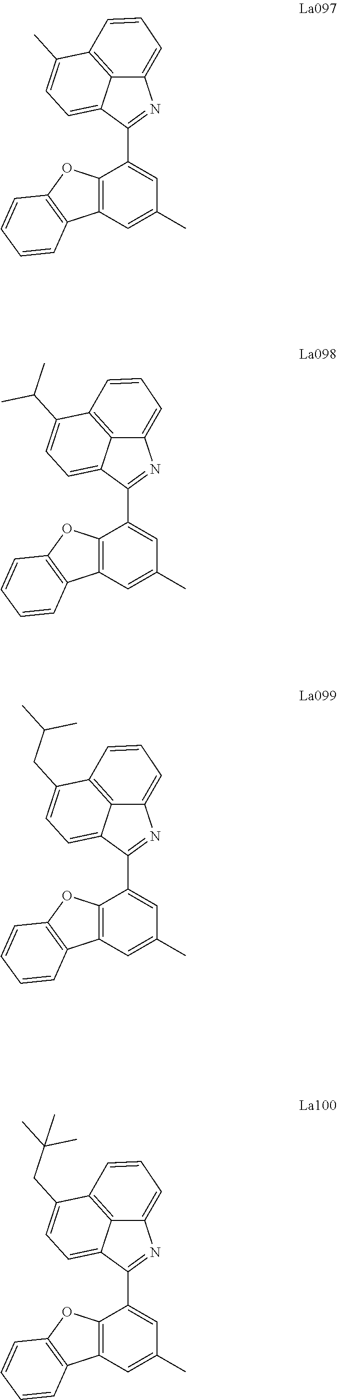 [SMILES: Cc1cc(C2=Nc3cccc4c(C)ccc2c34)c2oc3ccccc3c2c1 ; Cc1cc(C2=Nc3cccc4c(C(C)C)ccc2c34)c2oc3ccccc3c2c1 ; Cc1cc(C2=Nc3cccc4c(CC(C)C)ccc2c34)c2oc3ccccc3c2c1 ; Cc1cc(C2=Nc3cccc4c(CC(C)(C)C)ccc2c34)c2oc3ccccc3c2c1]

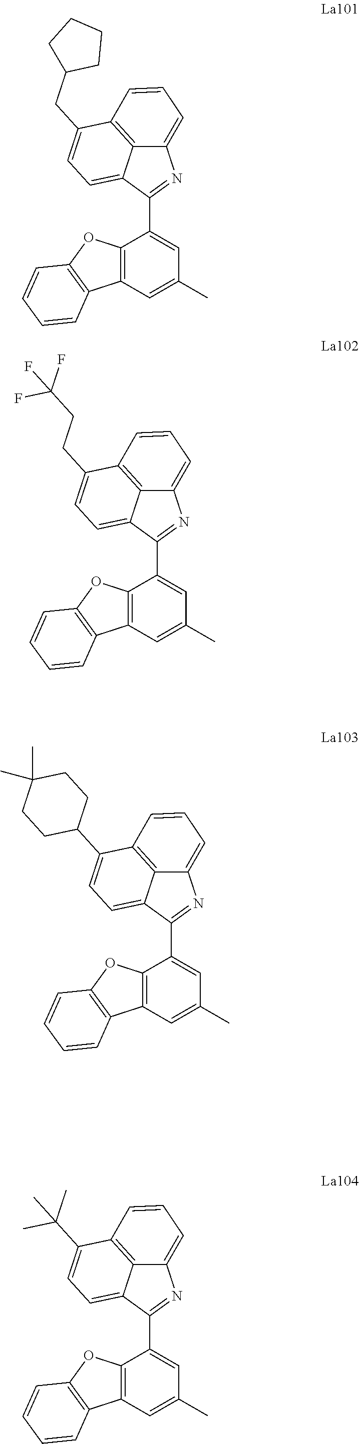

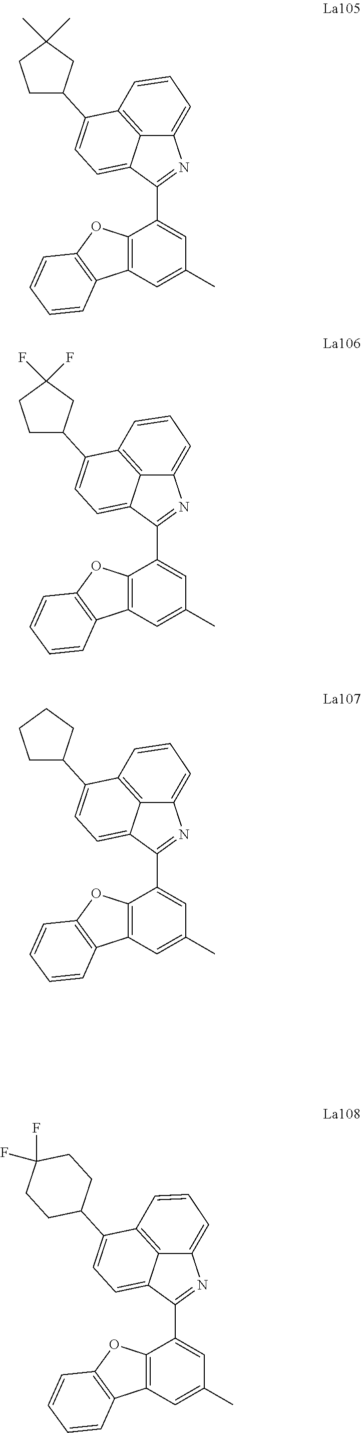 [SMILES: Cc1cc(C2=Nc3cccc4c(C5CCC(C)(C)C5)ccc2c34)c2oc3ccccc3c2c1 ; Cc1cc(C2=Nc3cccc4c(C5CCC(F)(F)C5)ccc2c34)c2oc3ccccc3c2c1 ; Cc1cc(C2=Nc3cccc4c(C5CCCC5)ccc2c34)c2oc3ccccc3c2c1 ; Cc1cc(C2=Nc3cccc4c(C5CCC(F)(F)CC5)ccc2c34)c2oc3ccccc3c2c1]

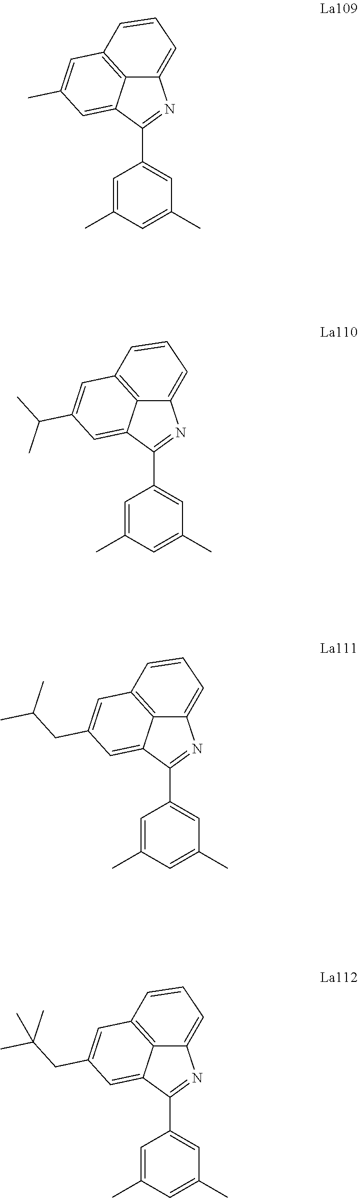

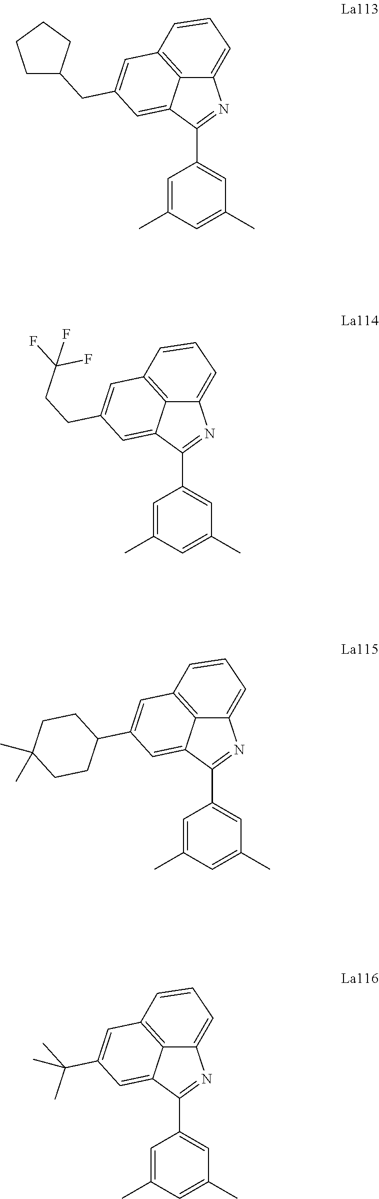

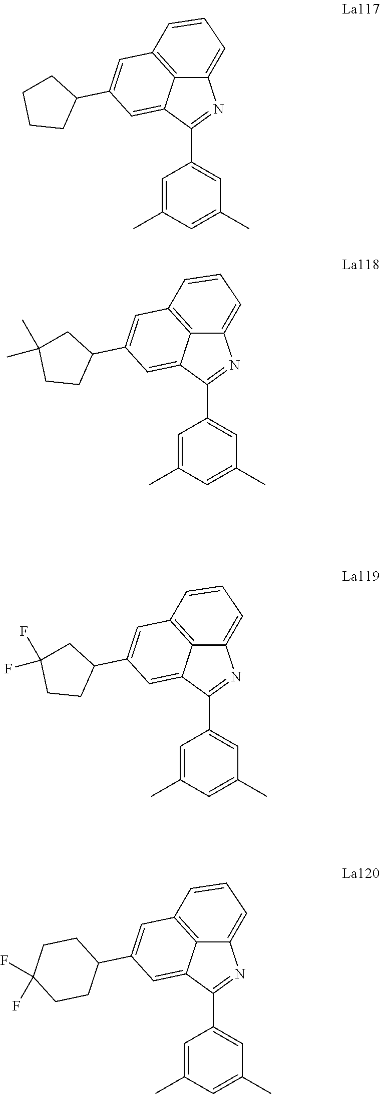

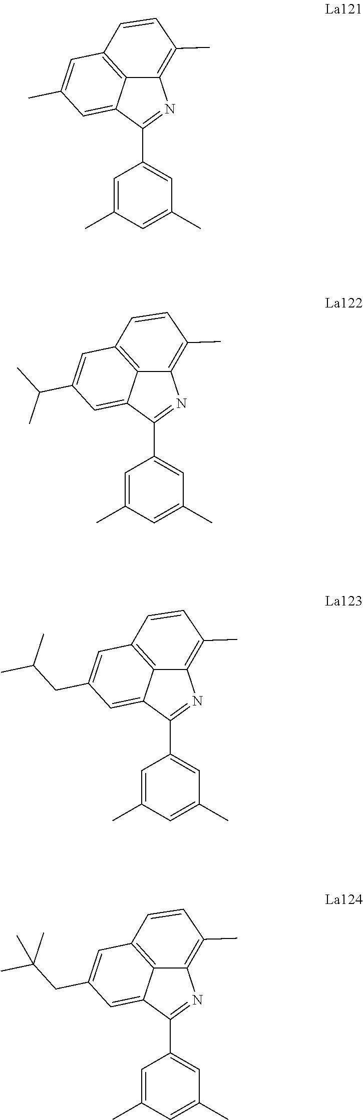

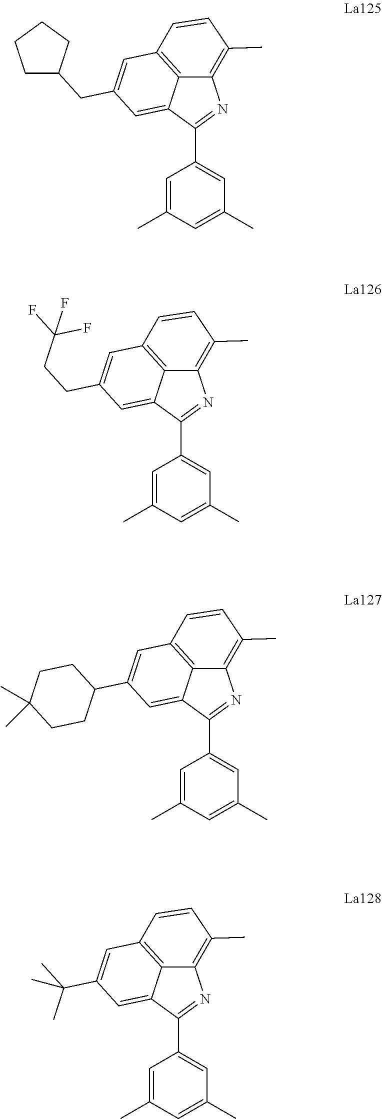

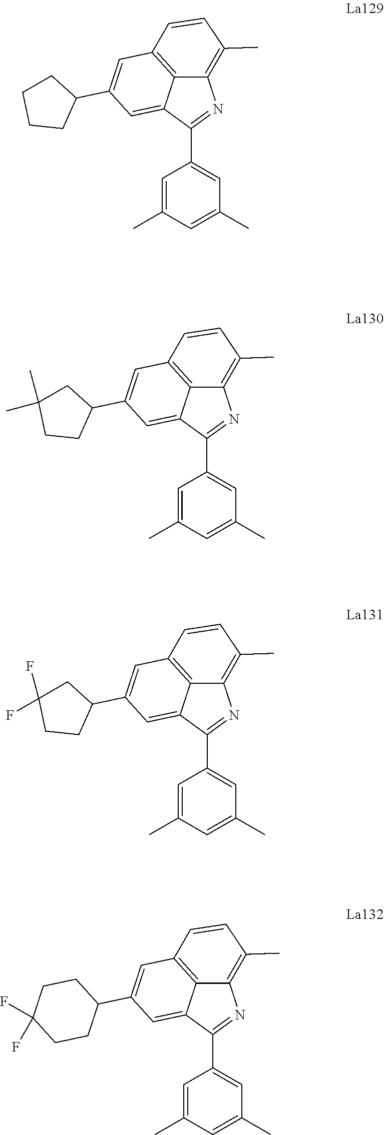

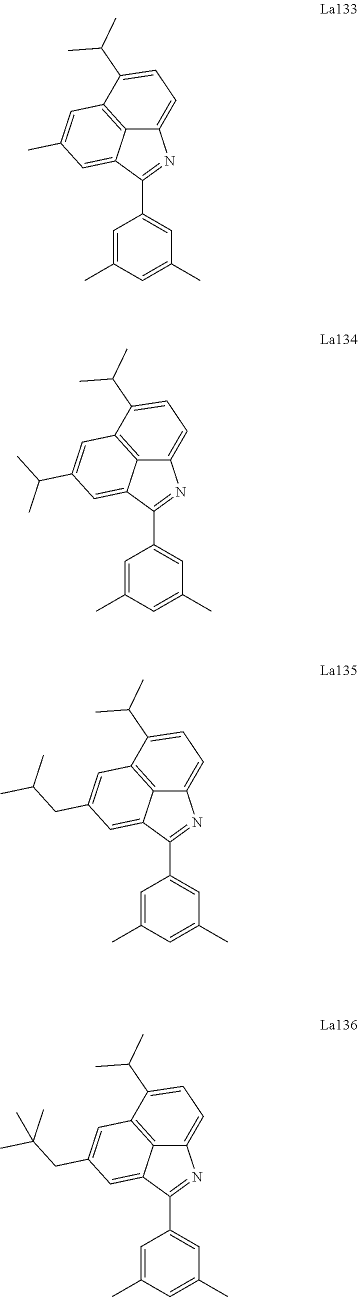

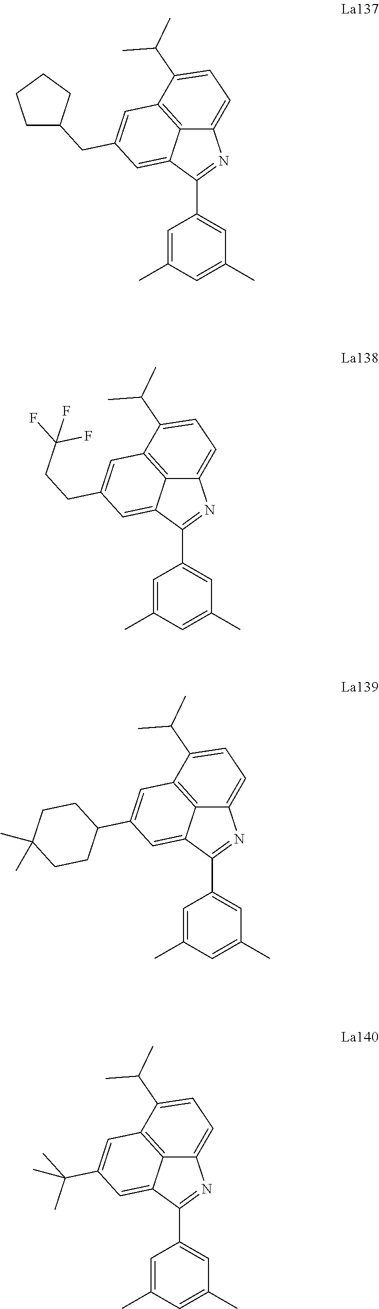

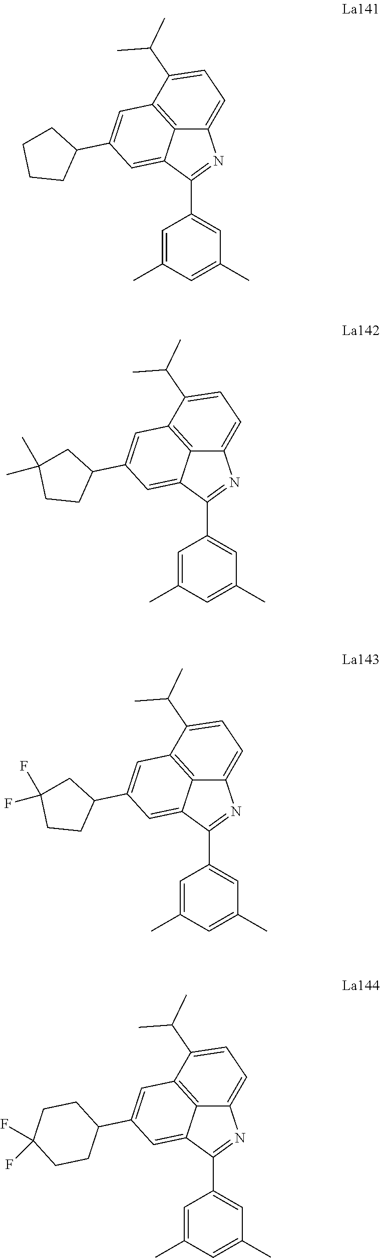

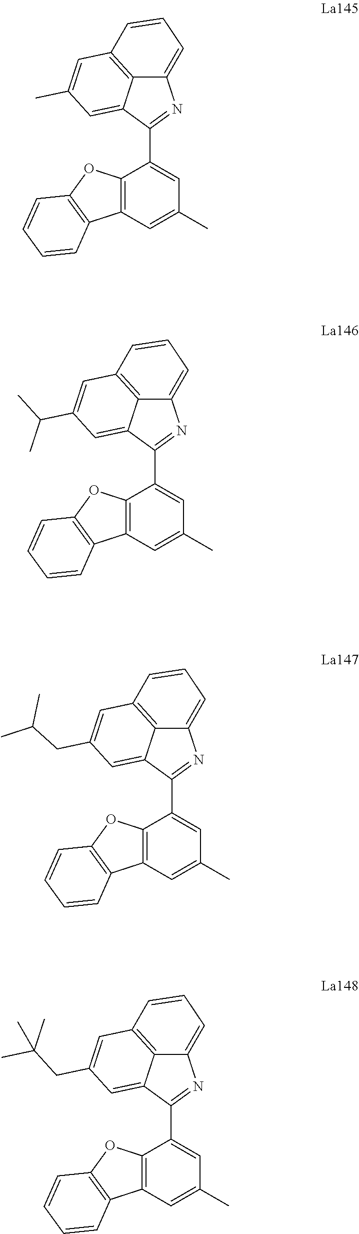

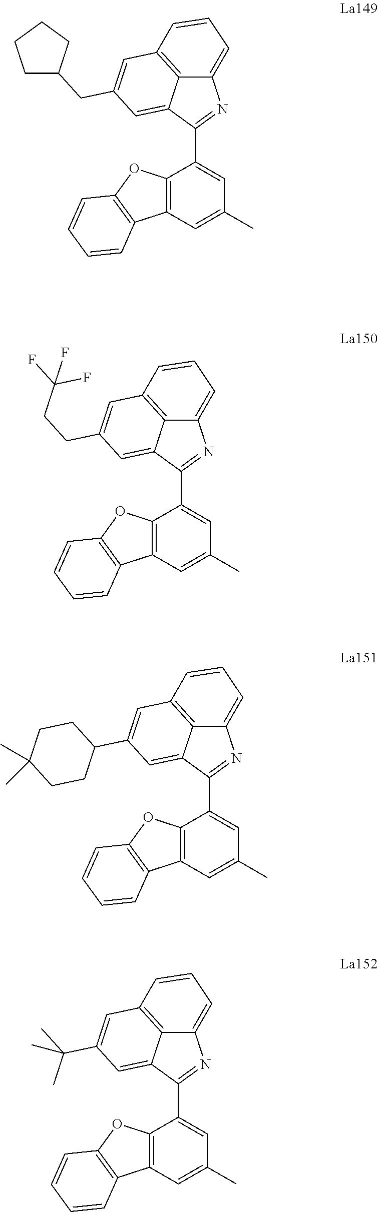

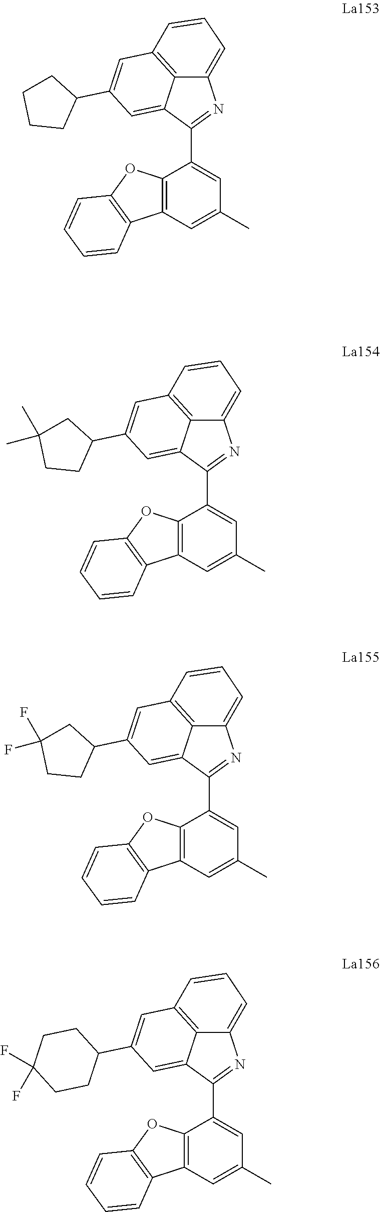

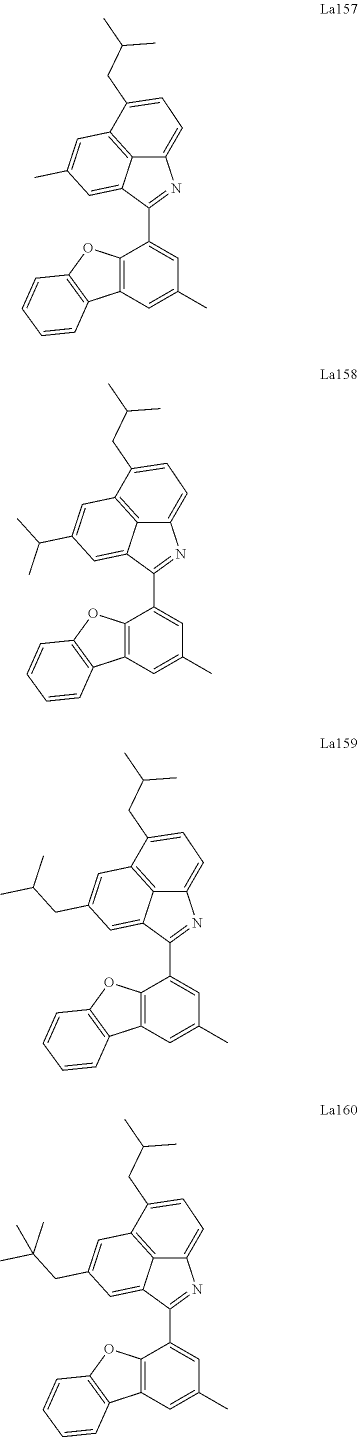

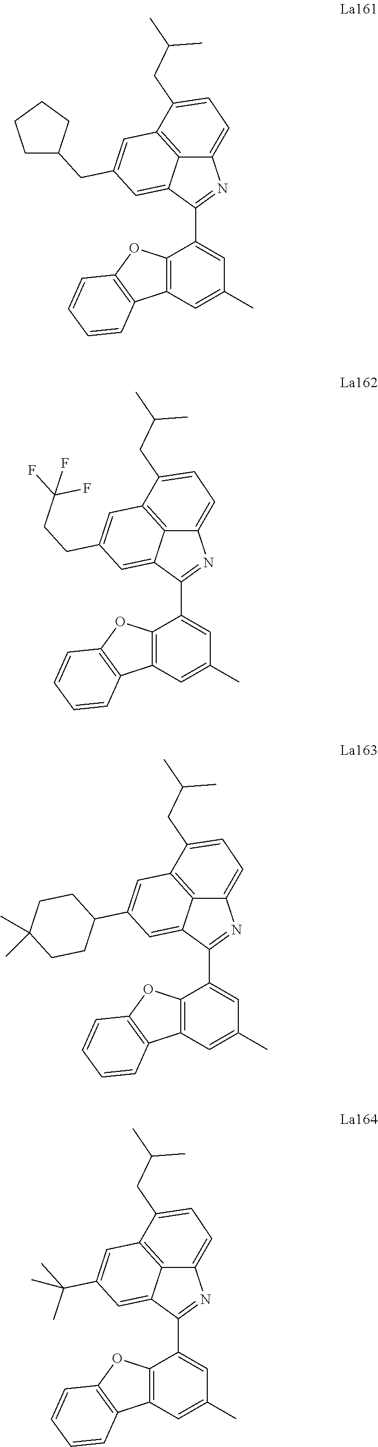

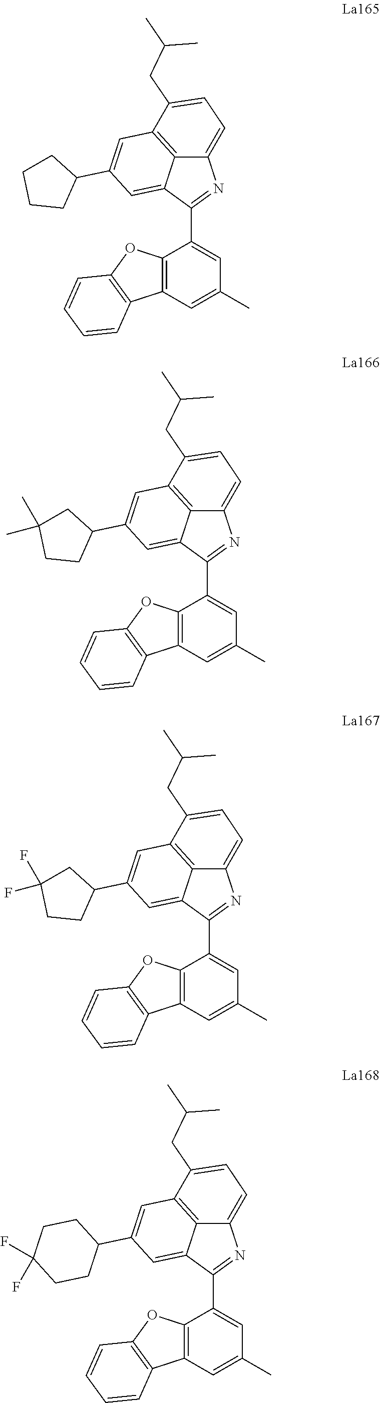

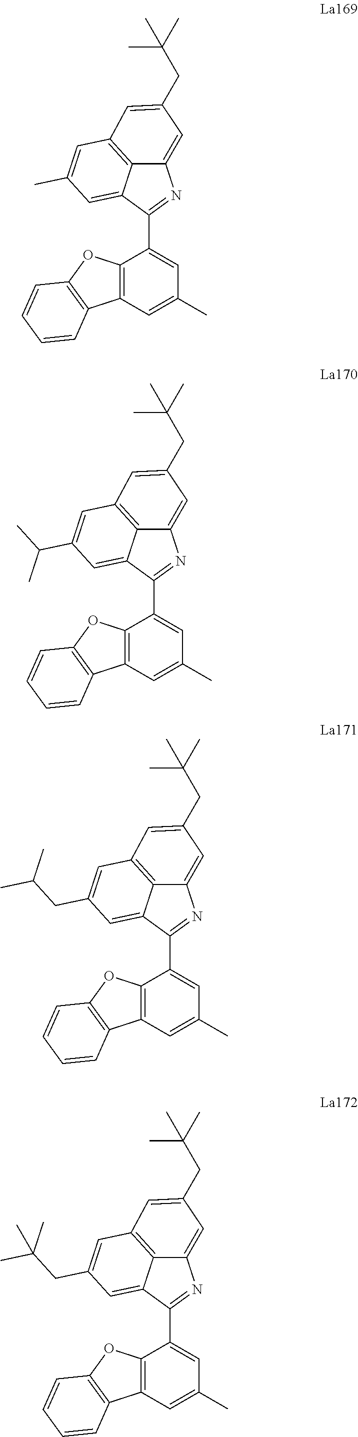

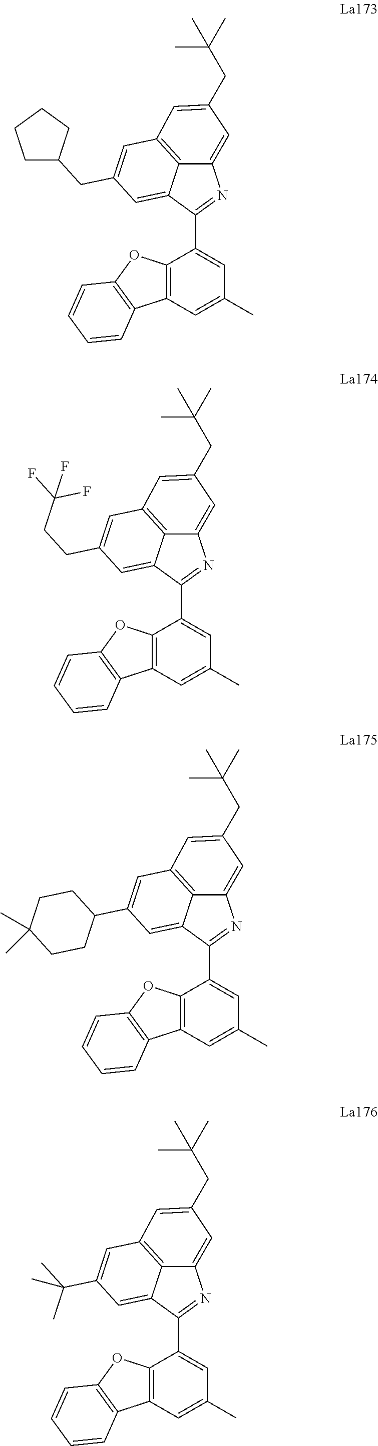

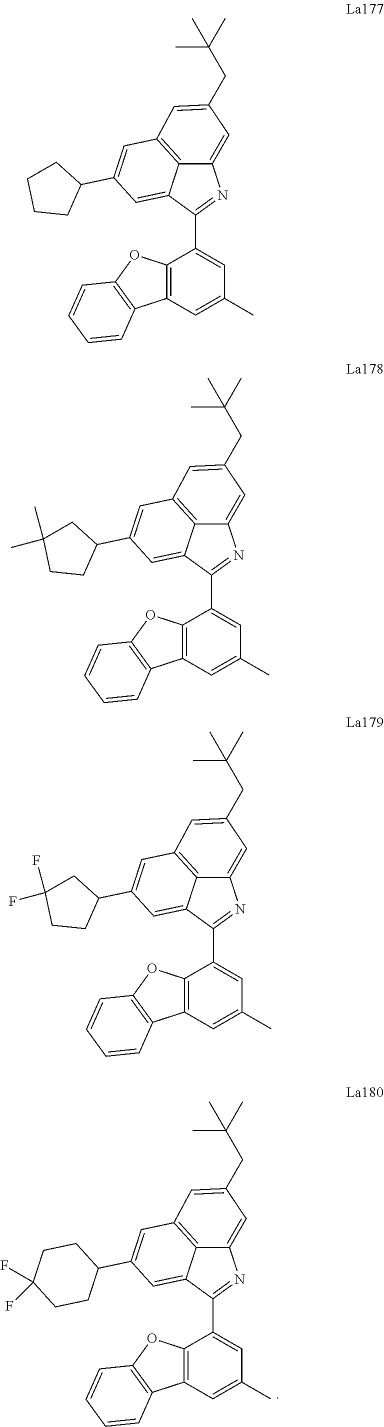

14. The organometallic iridium compound according to claim 2, wherein the Lb has one of the following structural formulas, or is partially or completely deuterated or fluorinated correspondingly,

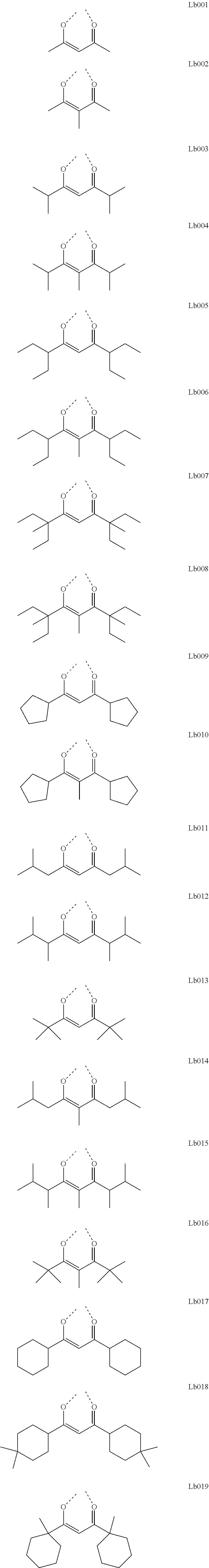

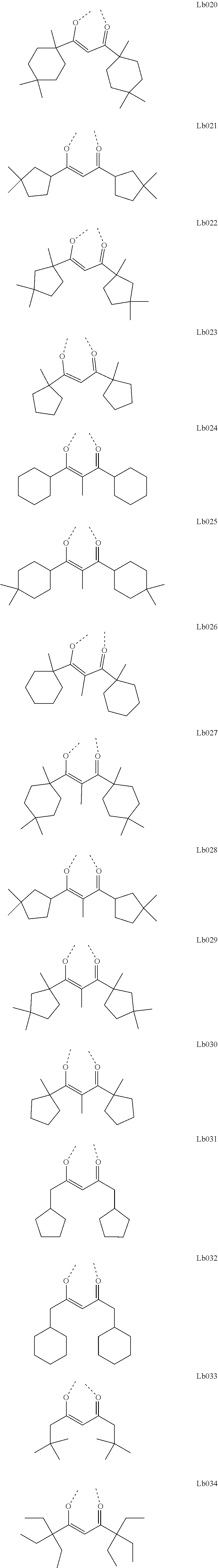

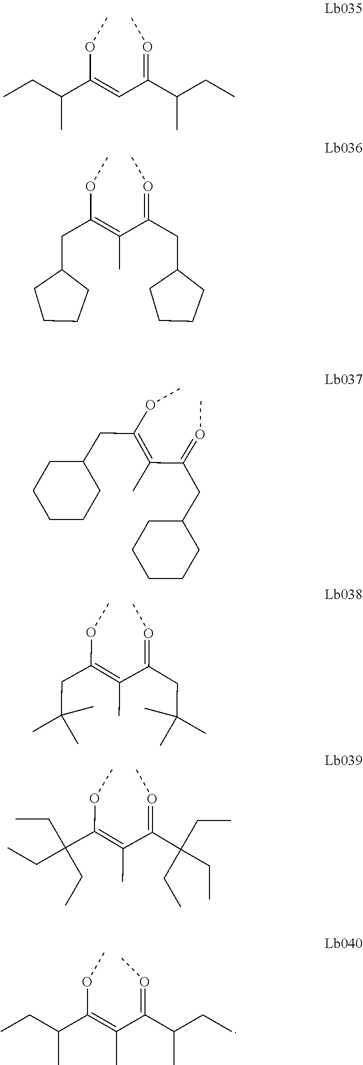

15. The organometallic iridium compound according to claim 12, wherein the Lc has one of the following structural formulas, or is partially or completely deuterated or fluorinated correspondingly,

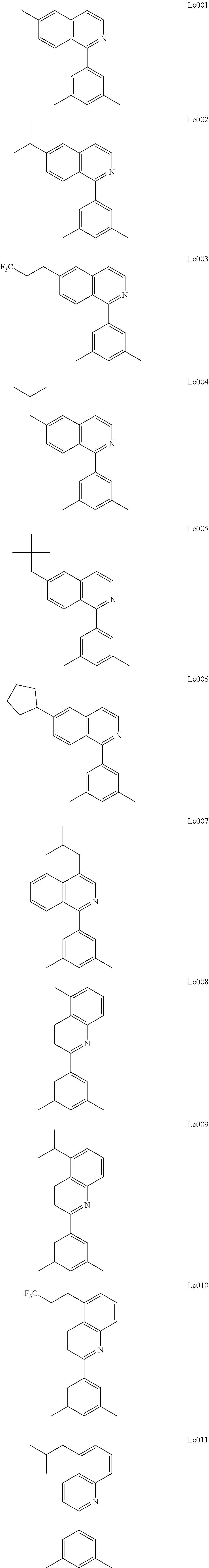

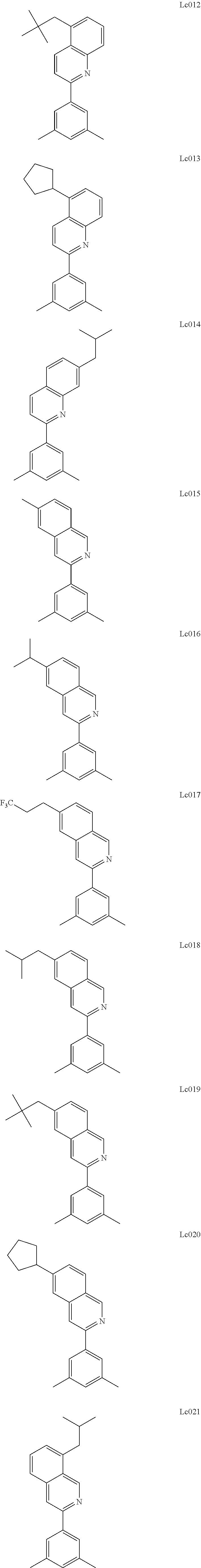

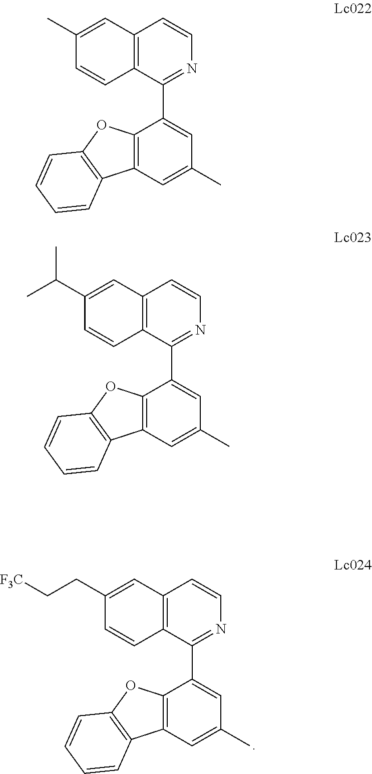

16. Application of the organometallic iridium compound according to claim 1 in an organic electroluminescent device.

17. The application according to claim 16, wherein the organometallic iridium compound is used as a red light-emitting doping material for a light-emitting layer in the organic electroluminescent device.
